(19) United States
(12) Patent Application Publication
(10) Pub. No.: US 2026/0104642 A1
(43) Pub. Date: Apr. 16, 2026

(54) RADIATION-SENSITIVE COMPOSITION, METHOD FOR FORMING PATTERN, AND RADIATION-SENSITIVE ACID GENERATOR

(71) Applicant: JSR CORPORATION, Tokyo (JP)

(72) Inventors: Katsuaki NISHIKORI, Tokyo (JP); Takuhiro TANIGUCHI, Tokyo (JP); Kazuya KIRIYAMA, Tokyo (JP)

(73) Assignee: JSR CORPORATION, Tokyo (JP)

(21) Appl. No.: 19/422,540

(22) Filed: Dec. 17, 2025

Related U.S. Application Data
(63) Continuation-in-part of application No. PCT/JP2024/022037, filed on Jun. 18, 2024.

(30) Foreign Application Priority Data
Jun. 29, 2023 (JP) 2023-107108

(51) Int. Cl. G03F 7/039; G03F 7/00; G03F 7/004

(52) U.S. Cl. CPC G03F 7/039; G03F 7/0045; G03F 7/70033

(57) ABSTRACT

A radiation-sensitive composition includes: a polymer (A) including a structural unit (I) which includes an acid-dissociable group; and a solvent (C). The radiation-sensitive composition satisfies (i) and/or (ii). (i) The radiation-sensitive composition includes a radiation-sensitive acid generator (B) including a first organic acid anion and a first onium cation. The first onium cation is an onium cation including a halogen-free electron withdrawing group containing no halogen atom, and the first organic acid anion is a sulfonic acid anion including an iodine atom. (ii) The polymer (A) is a radiation-sensitive acid-generating polymer (A1) further including a structural unit (IV) which includes a second organic acid anion and a second onium cation. The second onium cation is an onium cation including a halogen-free electron withdrawing group containing no halogen atom, and the second organic acid anion is a sulfonic acid anion including an iodine atom.

### CROSS-REFERENCE TO RELATED APPLICATIONS

The present application is a continuation-in-part application of International Patent Application No. PCT/JP2024/022037 filed Jun. 18, 2024, which claims priority to Japanese Patent Application No. 2023-107108 filed Jun. 29, 2023. The contents of these applications are incorporated herein by reference in their entirety.

### BACKGROUND OF THE DISCLOSURE

### Technical Field

The present disclosure relates to a radiation-sensitive composition, a method for forming a pattern and a radiation-sensitive acid generator.

### Background Art

A photolithography technique performed using a resist composition has been utilized for formation of a fine circuit on a semiconductor device. As the representative procedure, for example, a resist pattern is formed on a substrate by generating an acid by irradiating the coating of the resist composition with radioactive ray through a mask pattern, and then generate a difference in solubility of resin into an alkaline or organic developer between an exposed part and a non-exposed part through a reaction in the presence of the acid as a catalyst.

In the photolithography technique, pattern miniaturization is promoted by using short-wavelength radiation such as ArF excimer laser, or by combining such radiation with an immersion exposure method (liquid immersion lithography). As a next-generation technology, further short-wavelength radiation, such as an electron beam, an X-ray, and an extreme ultraviolet ray (EUV) is being utilized, and a resist material containing a compound that generates an acid with a structure having an enhanced efficiency of absorbing such radiation is also being studied (JP-B-4701231).

### SUMMARY

According to an aspect of the present disclosure,
a radiation-sensitive composition includes:
a polymer (A) including a structural unit (I) having an acid-dissociable group; and
a solvent (C),
wherein the radiation-sensitive composition satisfies at least one of a following (i) or (ii):
(i) the radiation-sensitive composition includes a radiation-sensitive acid generator (B) including a first organic acid anion and a first onium cation, in which the first onium cation is an onium cation including a halogen-free electron withdrawing group containing no halogen atom, and the first organic acid anion is a sulfonic acid anion including an iodine atom,
(ii) the polymer (A) is a radiation-sensitive acid-generating polymer (A1) further including a structural unit (IV) having a second organic acid anion and a second onium cation, in which the second onium cation is an onium cation including a halogen-free electron withdrawing group containing no halogen atom, and the second organic acid anion is a sulfonic acid anion including an iodine atom.

According to another aspect of the present disclosure,
a pattern forming method, includes:
directly or indirectly applying the above-described radiation-sensitive composition onto a substrate to form a resist film;
exposing the resist film to light; and
developing the exposed resist film with a developer.

According to a further aspect of the present disclosure,
a radiation-sensitive acid generator, includes:
an onium cation containing an electron withdrawing group containing no halogen atom; and
a sulfonic acid anion containing an iodine atom.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed.

Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

Even in the above-described next-generation technology, various resist performances equivalent to or higher than conventional performances are required in sensitivity and critical dimension uniformity (CDU), which is an index of uniformity of a line width and a hole diameter, development defects, and the like.

According to the radiation-sensitive composition of the present disclosure, a resist film that satisfies sensitivity and CDU and in which the occurrence of development defects is suppressed can be constructed when a next-generation technology is applied. The reason for this is not clear, but is presumed as follows. It is considered that the first onium cation of the radiation-sensitive acid generator (B) or the second onium cation of the radiation-sensitive acid-generating polymer (A1) has an electron withdrawing group, thereby efficiently reacting with electrons, so that sensitivity and lithographic performance are improved. In addition, since the electron withdrawing group of the onium cation does not contain a halogen atom, the onium cation has so high hydrophilicity that the affinity with an alkaline developer increases. As a result, the occurrence of development defects is suppressed. In addition, the first organic acid anion of the radiation-sensitive acid generator (B) or the second organic acid anion of the radiation-sensitive acid-generating polymer (A1) is a sulfonic acid anion containing an iodine atom, whereby the electron yield is increased so that the sensitivity of the radiation-sensitive composition is increased. In addition, when the first organic acid anion or the second organic acid anion contains an iodine atom, acid diffusion can be controlled by the size of the molecular weight of the iodine atom, so that CDU can be improved. It is presumed that due to these combined actions, resist performances and development defect-suppressing properties as described above can be exerted.

In the pattern forming method of the present disclosure, since the radiation-sensitive composition capable of forming a resist film having excellent sensitivity and CDU and suppressed occurrence of development defects is used, a high-quality resist pattern can be efficiently formed.

Using a radiation-sensitive composition containing the radiation-sensitive acid generator of the present disclosure, a resist film having excellent sensitivity and CDU and suppressed development defects can be formed.

Hereinafter, embodiments of the present invention will be described in detail, but the present invention is not limited to these embodiments. Combinations of suitable embodiments are also preferable.

### <<Radiation-Sensitive Composition>>

The radiation-sensitive composition (hereinafter, also simply referred to as a “composition”) according to the present embodiment contains a polymer (A) and a solvent (C), and satisfies at least one of the above (i) or (ii) (that is, the radiation-sensitive composition contains a radiation-sensitive acid generator (B) having a specific structure, or the polymer (A) is a radiation-sensitive acid-generating polymer (A1) containing a specific structural unit, or both of them). The composition may contain another optional component as long as the effects of the present disclosure are not impaired. Since the radiation-sensitive composition contains a radiation-sensitive acid generator (B) having a specific structure or the polymer (A) is a radiation-sensitive acid-generating polymer (A1) containing a specific structural unit, the resist film obtained from the radiation-sensitive composition can exhibit sensitivity and CDU at a higher level, and the occurrence of development defects can be suppressed.

### <Polymer (A)>

The polymer (A) is an aggregate of polymer chains containing a structural unit (I) having an acid-dissociable group (hereinafter, this aggregate is also referred to as a “base polymer”). It is only required that the entire polymer constituting the polymer (A) contains the structural unit (I). The polymer (A) may also contain a structural unit other than the structural unit (I). The polymer (A) may be a polymer having an acid-generating structure that generates an acid through exposure to light (radiation-sensitive acid-generating polymer (A1)), or may be a polymer having no acid-generating structure.

The polymer (radiation-sensitive acid-generating polymer (A1)) is an aggregate of polymer chains containing a structural unit (I) having an acid-dissociable group and a structural unit (IV) having a second organic acid anion and a second onium cation, and is a component that generates an acid through exposure to light. The structural unit (I) and the structural unit (IV) may be contained in the same polymer chain, or alternatively, the structural unit (I) may be contained in one polymer chain and the structural unit (IV) may be contained in another polymer chain. It is merely required that the whole polymer constituting the radiation-sensitive acid-generating polymer (A1) contains the structural unit (I) and the structural unit (IV). The radiation-sensitive acid-generating polymer (A1) may contain a structural unit other than the structural unit (I) and the structural unit (IV).

In this specification, the onium salt structure is incorporated as a part of a polymer is referred to as a “radiation-sensitive acid-generating polymer”, and a low molecular weight form (released from a polymer) in which the onium salt structure is present alone as a compound is referred to as a “radiation-sensitive acid generator”.

The “acid-dissociable group” refers to a group that substitutes for a hydrogen atom of a carboxy group, a phenolic hydroxyl group, an alcoholic hydroxyl group, a sulfo group, or the like, and is dissociated by the action of an acid. The acid generated from the radiation-sensitive acid generator (B) or the radiation-sensitive acid-generating polymer (A1) through exposure to light dissociates the acid-dissociable group in the structural unit (I) to generate a carboxy group or the like. As a result, a difference in solubility into a developer arises between the exposed portion and the unexposed portion of a resist film, making it possible to achieve pattern formation.

From the viewpoint of sensitivity and CDU, the polymer (A) preferably contains an iodine atom, more preferably contains an iodine-substituted aromatic ring structure.

### (Structural Unit (I))

The structural unit (I) is a structural unit having an acid-dissociable group. The structural unit (I) is not particularly limited as long as the structural unit (I) has an acid-dissociable group, and examples thereof include a structural unit having a tertiary alkyl ester moiety, a structural unit having a structure in which a hydrogen atom of a phenolic hydroxy group is replaced by a tertiary alkyl group, and a structural unit having an acetal linkage. From the viewpoint of improving the patternability of the radiation-sensitive composition, a structural unit represented by the following formula (A1) (hereinafter also referred to as “structural unit (I-1)”) is preferable.

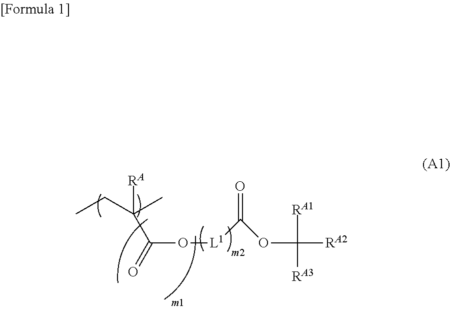

In the above formula (A1), R^{A1} is a hydrogen atom, a fluorine atom, an alkyl group having 1 to 10 carbon atoms, or a fluorinated alkyl group having 1 to 10 carbon atoms, and the above alkyl group and fluorinated alkyl group may each have a linking group containing one or more —O—, —CO—, or a combination thereof between carbon-carbon bonds. R^{A1} is a hydrogen atom or a monovalent hydrocarbon group having 1 to 20 carbon atoms. R^{A2} and R^{A3} each independently are a monovalent chain hydrocarbon group having 1 to 20 carbon atoms, or a monovalent alicyclic hydrocarbon group having 3 to 20 carbon atoms, or represent a divalent alicyclic group having 3 to 20 carbon atoms composed of these groups combined with each other together with a carbon atom to which these groups are bonded. m1 and m2 are each independently 0 or 1, provided that when m1 is 1, m2 is 1. When m1 is 0, L¹ represents a single bond or a divalent linking group, and when m1 is 1, L¹ represents a divalent linking group. In the above hydrocarbon group, chain hydrocarbon group, and alicyclic hydrocarbon group, some or all of the hydrogen atoms on the carbon atom may be substituted with a substituent such as a halogen atom.

Examples of the divalent linking group represented by L¹ include alkanediyl groups, cycloalkanediyl groups, alkene diyl groups, cycloalkene diyl groups, arenediyl group, a group containing, between adjacent carbon atoms of these groups, —CO—, —CS—, —O—, —S—, —SO₂—, —NR′—, or a combination of two or more thereof, or a group obtained by combining these groups. R′ is a hydrogen atom or a monovalent hydrocarbon group having 1 to 10 carbon atoms. Some or all of hydrogen atoms of these groups may be substituted with, for example, a substituent such as a halogen atom such as a fluorine atom, a chlorine atom, a bromine atom, or an iodine atom; a hydroxy group; a carboxy group; a cyano group; a nitro group; an alkyl group; an alkoxy group; an alkoxycarbonyl group; an alkoxycarbonyloxy group; an acyl group; an acyloxy group, or a group obtained by substituting a hydrogen atom of such a group with a halogen atom.

Examples of the alkanediyl group include: alkanediyl groups having 1 to 8 carbon atoms such as a methanediyl group, an ethanediyl group, a 1,3-propanediyl group, and a 2,2-propanediyl group.

Examples of the cycloalkanediyl group include: monocyclic cycloalkanediyl groups such as a cyclopentanediyl group, and a cyclohexanediyl group; polycyclic cycloalkanediyl groups such as a norbornanediyl group and an adamantanediyl group. A cycloalkanediyl group having 5 to 12 carbon atoms is preferable as the cycloalkanediyl group.

Examples of the alkenediyl groups include: an ethenediyl group, a propenediyl group, and a butenediyl group. An alkenediyl group having 2 to 6 carbon atoms is preferable as the alkenediyl groups.

Examples of the arenediyl groups include: a benzenediyl group, a toluenediyl group, and naphthalenediyl group. An arenediyl group having 6 to 15 carbon atoms is preferable as the arenediyl groups.

Examples of the monovalent hydrocarbon group having 1 to 20 carbon atoms represented by R^{A1} include a monovalent chain hydrocarbon group having 1 to 20 carbon atoms, a monovalent alicyclic hydrocarbon group having 3 to 20 carbon atoms, and a monovalent aromatic hydrocarbon group having 6 to 20 carbon atoms.

Examples of the monovalent chain hydrocarbon group having 1 to 20 carbon atoms represented by R^{A1} to R^{A3} include a linear or branched saturated hydrocarbon group having 1 to 20 carbon atoms and a linear or branched unsaturated hydrocarbon group having 2 to 20 carbon atoms.

Examples of the monovalent linear or branched saturated hydrocarbon groups having 1 to 20 carbon atoms include alkyl groups such as a methyl group, an ethyl group, an n-propyl group, an i-propyl group, an n-butyl group, a 2-methylpropyl group, a 1-methylpropyl group, a t-butyl group, an n-pentyl group, an isopentyl group, and a neopentyl group. Examples of the monovalent linear or branched unsaturated hydrocarbon groups having 2 to 20 carbon atoms include alkenyl groups such as an ethenyl group, a propenyl group, and a butenyl group; and alkynyl groups such as an ethynyl group, a propynyl group, and a butynyl group.

Examples of the monovalent alicyclic hydrocarbon group having 3 to 20 carbon atoms represented by R^{A1} to R^{A3} include monocyclic or polycyclic saturated hydrocarbon groups and monocyclic or polycyclic unsaturated hydrocarbon groups. Examples of the monocyclic saturated hydrocarbon group include a cycloalkyl group such as a cyclopentyl group, a cyclohexyl group, a cycloheptyl group, and a cyclooctyl group. Examples of the polycyclic saturated hydrocarbon group include bridged alicyclic hydrocarbon groups such as a norbornyl group, an adamantyl group, a tricyclodecyl group, and a tetracyclododecyl group. Examples of the monocyclic unsaturated hydrocarbon group include monocyclic cycloalkenyl groups such as a cyclopropenyl group, a cyclobutenyl group, a cyclopentenyl group, and a cyclohexenyl group. Examples of the polycyclic unsaturated hydrocarbon group include polycyclic cycloalkenyl groups such as a norbornenyl group, a tricyclodecenyl group, and a tetracyclododecenyl group. It is to be noted that the bridged alicyclic hydrocarbon group refers to a polycyclic alicyclic hydrocarbon group in which two carbon atoms that compose an alicyclic ring and are not adjacent to each other are bonded by a linking group containing one or more carbon atoms.

Examples of the monovalent aromatic hydrocarbon groups having 6 to 20 carbon atoms represented by R^{A1} include: aryl groups such as a phenyl group, a tolyl group, a xylyl group, a naphthyl group, and an anthryl group; and aralkyl groups such as a benzyl group, a phenethyl group, and a naphthylmethyl group.

The R^{A1} is preferably a hydrogen atom, a linear or branched saturated hydrocarbon group having 1 to 20 carbon atoms, an alicyclic hydrocarbon group having 3 to 20 carbon atoms, or a monovalent aromatic hydrocarbon group having 6 to 20 carbon atoms, more preferably a hydrogen atom, an alkyl group having 1 to 4 carbon atoms, or a substituted or unsubstituted phenyl group.

As the divalent alicyclic group having 3 to 20 carbon atoms composed of R^{A2} and R^{A3} together with the carbon atom to which R^{A2} and R^{A3} are bonded, groups obtained by removing one hydrogen atom from the monovalent alicyclic hydrocarbon group having 3 to 20 carbon atoms can be suitably employed.

R^{A2} and R^{A3} are each independently preferably a monovalent chain hydrocarbon group having 1 to 10 carbon atoms, or a divalent alicyclic group having 3 to 20 carbon atoms in which R^{A2} and R^{A3} are combined with each other and configured together with a carbon atom to which R^{A2} and R^{A3} are bonded, more preferably an alkyl group having 1 to 4 carbon atoms, or a cycloalkanediyl group or a cycloalkenediyl group in which R^{A2} and R^{A3} are combined with each other and configured together with a carbon atom to which R^{A2} and R^{A3} are bonded.

m1 is preferably 0, L¹ is preferably a single bond or an arylene group, and m2 is preferably 1.

Examples of the structural unit (I-1) include structural units represented by the following formulas (1-1) to (1-4).

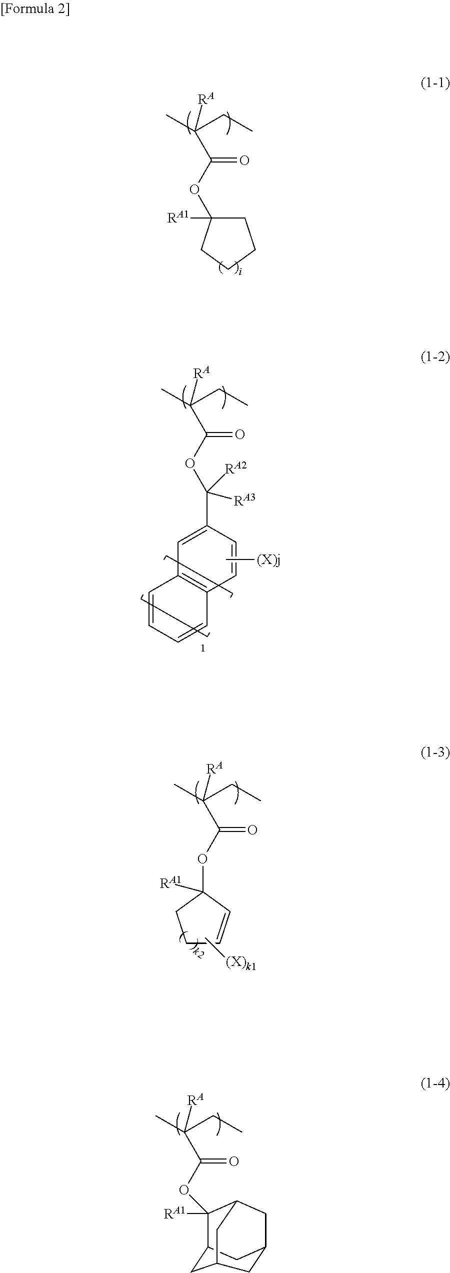

In the above formulas (1-1) to (1-4), R^{A} and R^{A1} to R^{A3} have the same meaning as in the above formula (A1). i is an integer of 1 to 4, and 1 is an integer of 0 to 2. j is an integer of 0 to 9 and satisfies 0≤j≤21+5. k is an integer of 0 to 7, and k2 is an integer of 1 to 3.

In the formulas (1-1) to (1-4), as X, substituents in L¹ of the formula (A1) can be suitably employed. Among them, a halogen atom and an alkyl group are preferable, and an iodine atom and a methyl group are more preferable. When j and k1 are 2 or more, a plurality of Xs may be the same as or different from each other.

As R^{A1}, a hydrogen atom, a methyl group, an ethyl group, an isopropyl group, and a t-butyl group are preferable. As R^{A2} and R^{A3}, a methyl group, an ethyl group, and a t-butyl group are preferable.

Specific examples of the structural unit (I) include, but are not particularly limited to, structures represented by the following formulas. Among those shown below, as the structure having an iodine-substituted aromatic ring structure, a structure in which an iodine atom in the following formulas is substituted by an atom or group other than an iodine atom such as a hydrogen atom or another substituent can also be suitably employed.

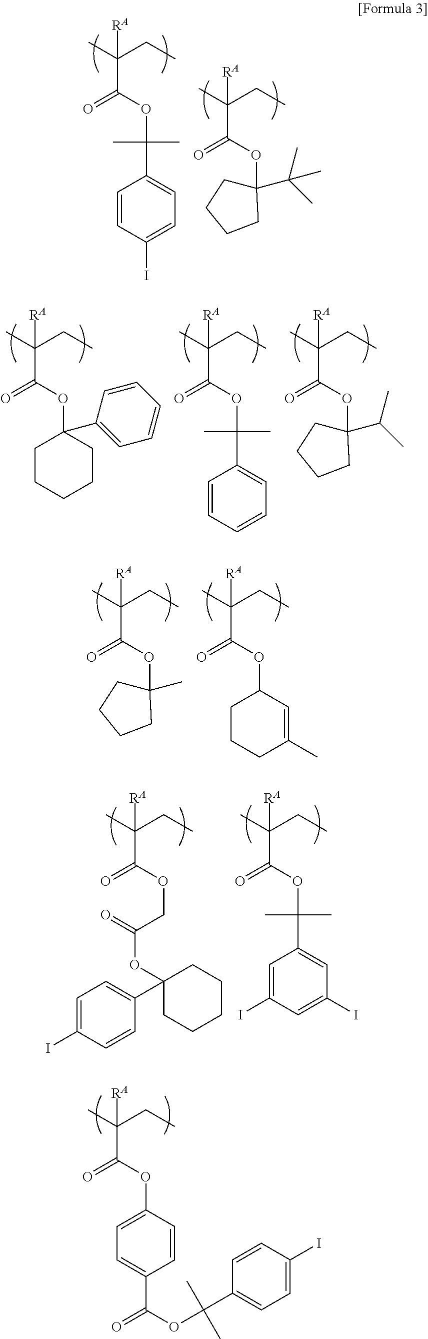

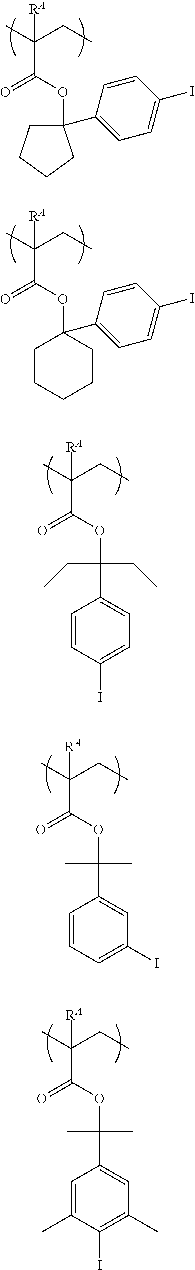

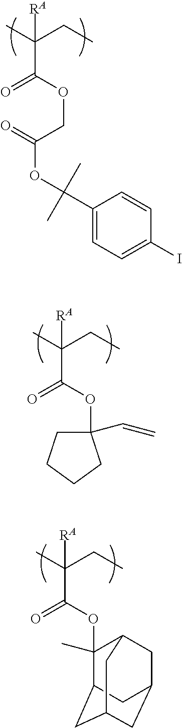

(In the formulas, R^{A} has the same meaning as in the formula (A1).)

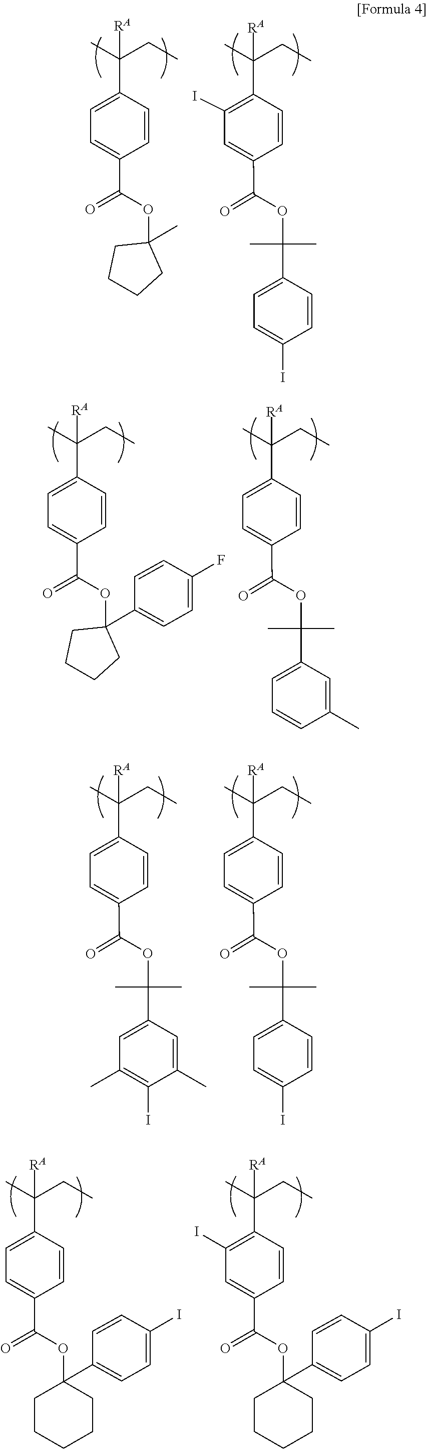

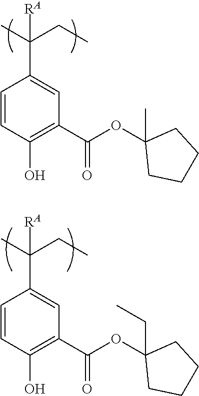

(In the formulas, R^{A} has the same meaning as in the formula (A1).)

The base polymer may contain one type or a combination of two or more types of the structural units (I).

The lower limit of the content of the structural unit (I) (when a plurality of types is contained, the total content thereof is taken) is preferably 10 mol %, more preferably 20 mol %, still more preferably 30 mol %, and particularly preferably 35 mol % based on all structural units composing the base polymer (or base polymer (A1)). The upper limit of the content is preferably 80 mol %, more preferably 70 mol %, and still more preferably 65 mol %. When the content of the structural unit (I) is adjusted to within the above range, the patternability of the radiation-sensitive composition can be further improved.

### (Structural Unit (II))

Preferably, the polymer (A) further contains a structural unit (II) having a phenolic hydroxy group. Examples of the monomer that affords the structural unit (II) include, but are not limited to, those shown below. In the following formulas, R^{A} is the same as described above.

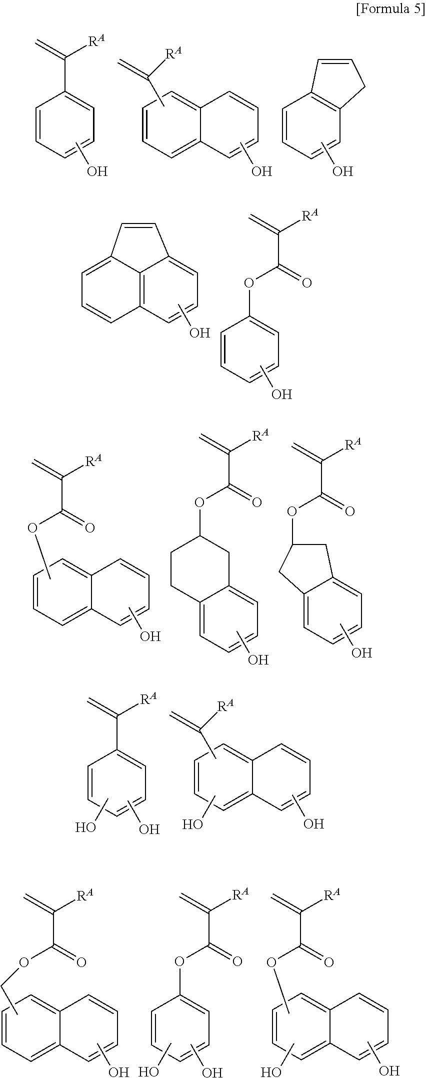

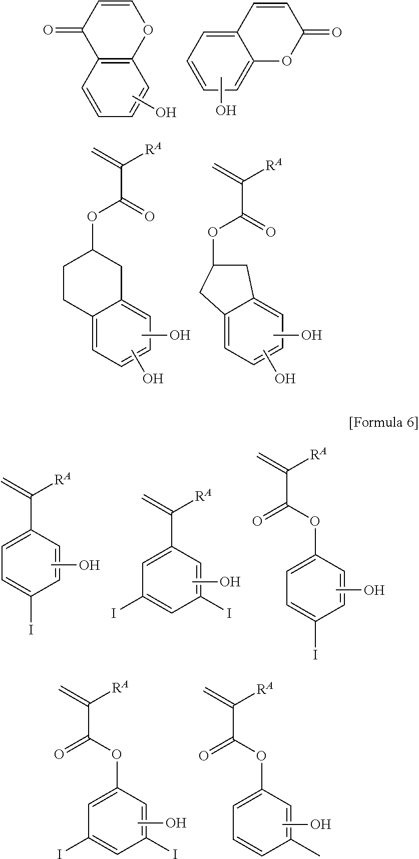

When the polymer (A) (or the radiation-sensitive acid-generating polymer (A1)) has the structural unit (II), the lower limit of the content of the structural unit (II) (when a plurality of types is contained, the total content thereof is taken) is preferably 15 mol %, more preferably 20 mol %, still more preferably 25 mol % and particularly preferably 30 mol % based on all structural units composing the base polymer (or base polymer (A1)). The upper limit of the content is preferably 70 mol %, more preferably 60 mol %, still more preferably 55 mol % and particularly preferably 50 mol %. When the content of the structural unit (II) is adjusted to within the above range, the patternability of the radiation-sensitive composition can be further improved.

### (Structural Unit (III))

The polymer (A) may further contain another structural unit (III) containing a polar group such as an alcoholic hydroxy group, a carboxy group, a lactone ring, a sultone ring, an ether group, an ester group, a carbonyl group, or a cyano group. Examples of the monomer that affords the structural unit (III) include, but are not limited to, those shown below. In the following formulas, R^{A} is the same as described above.

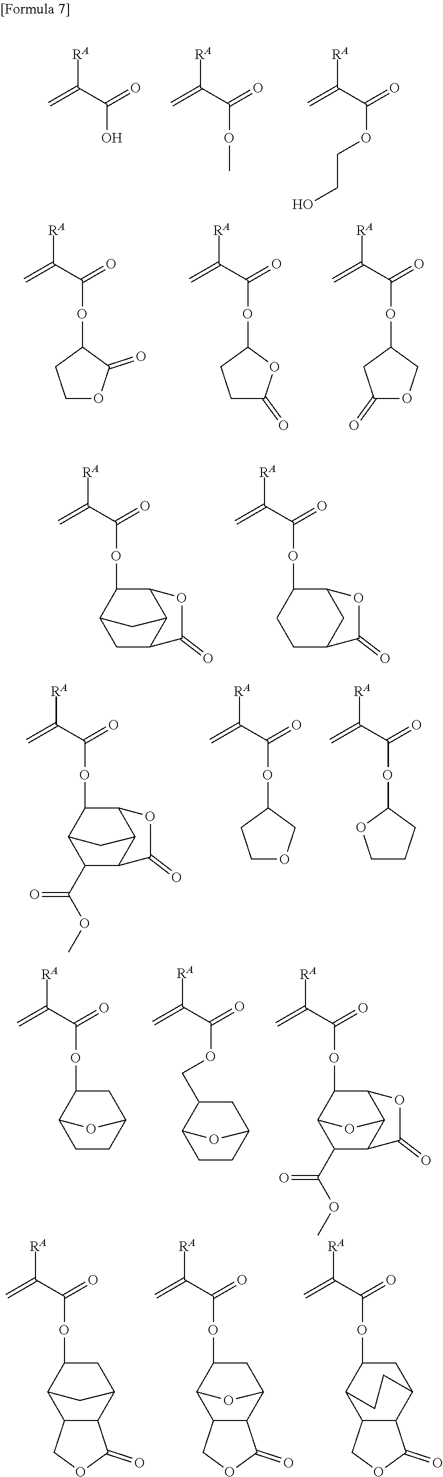

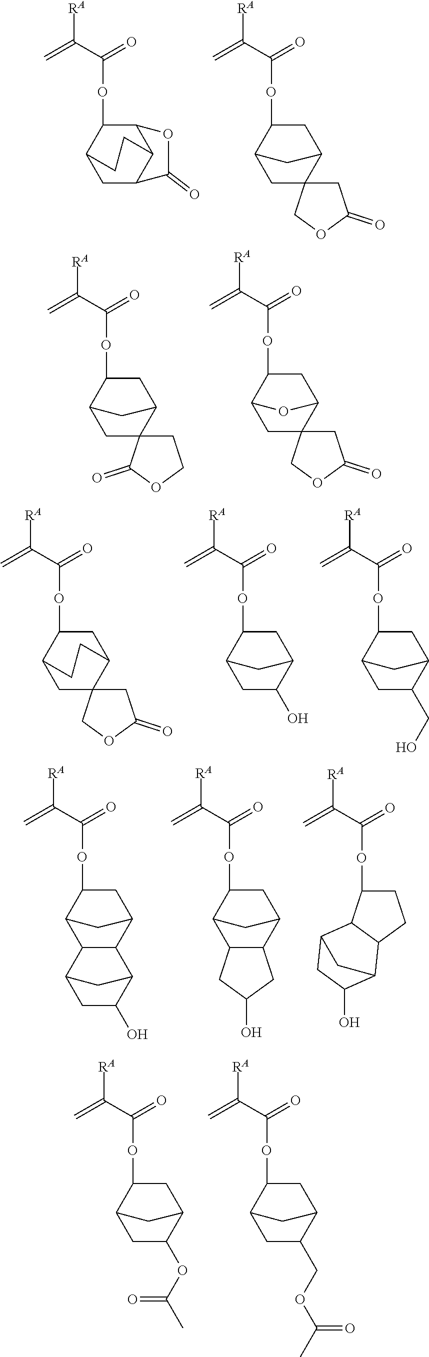

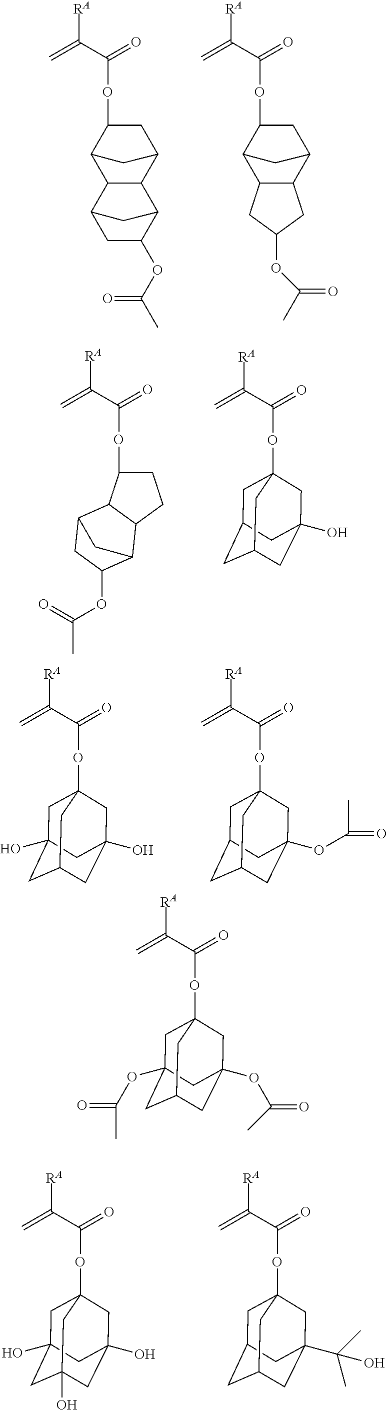

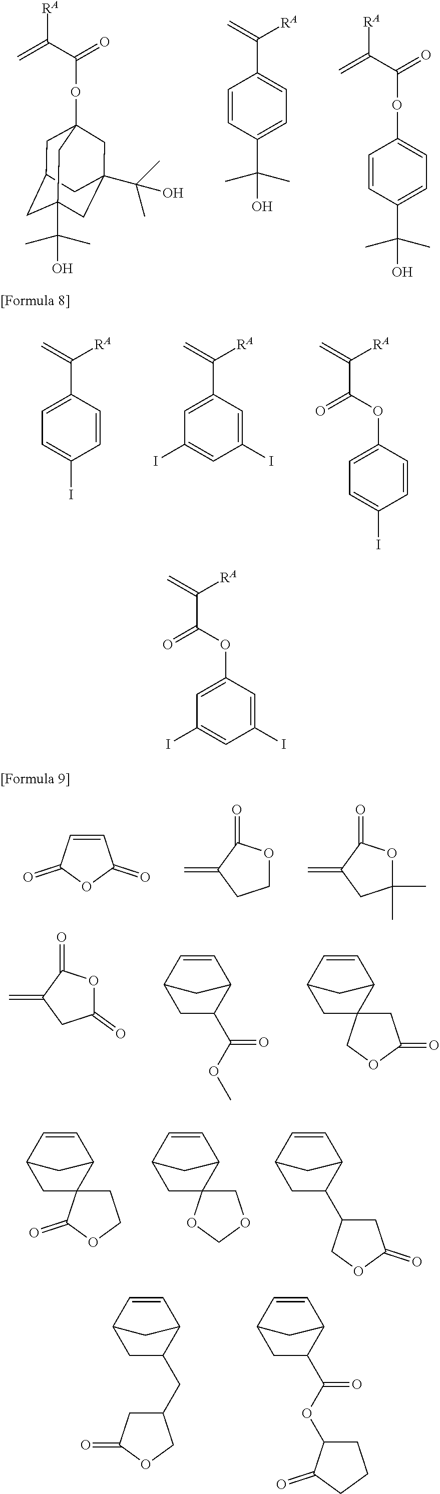

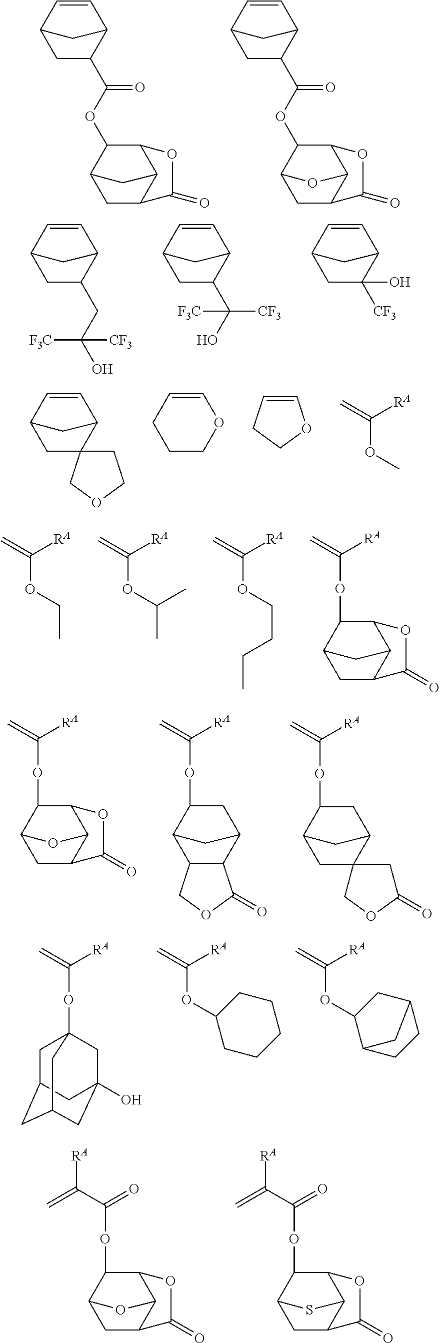

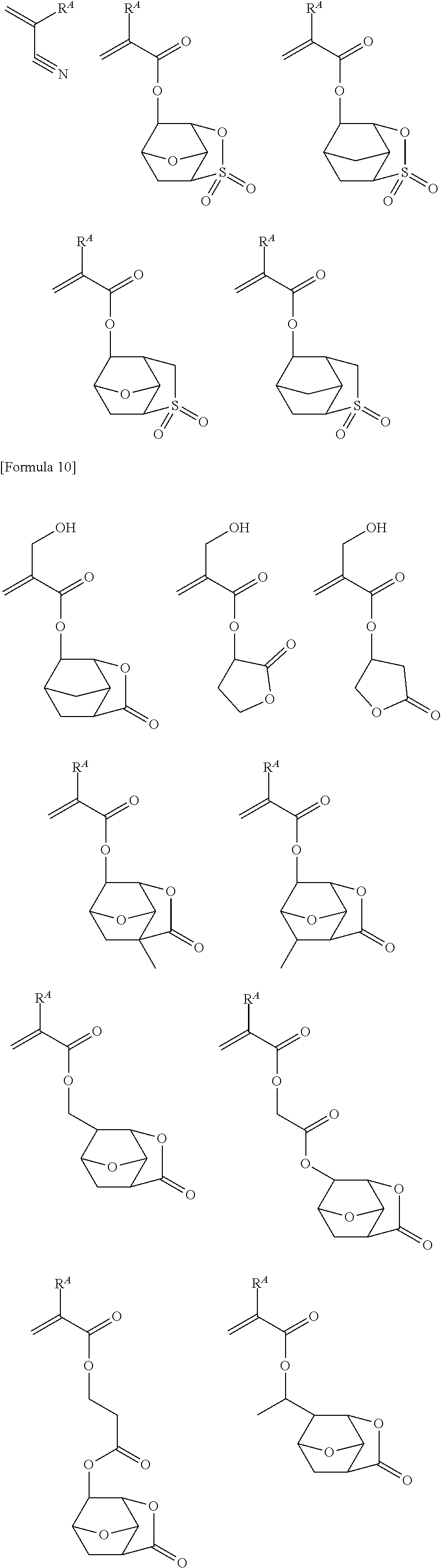

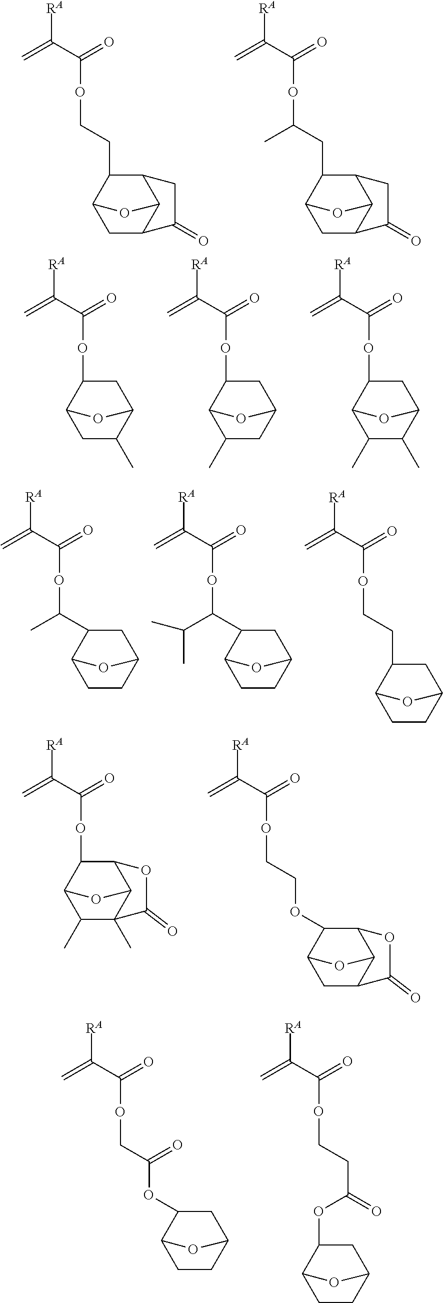

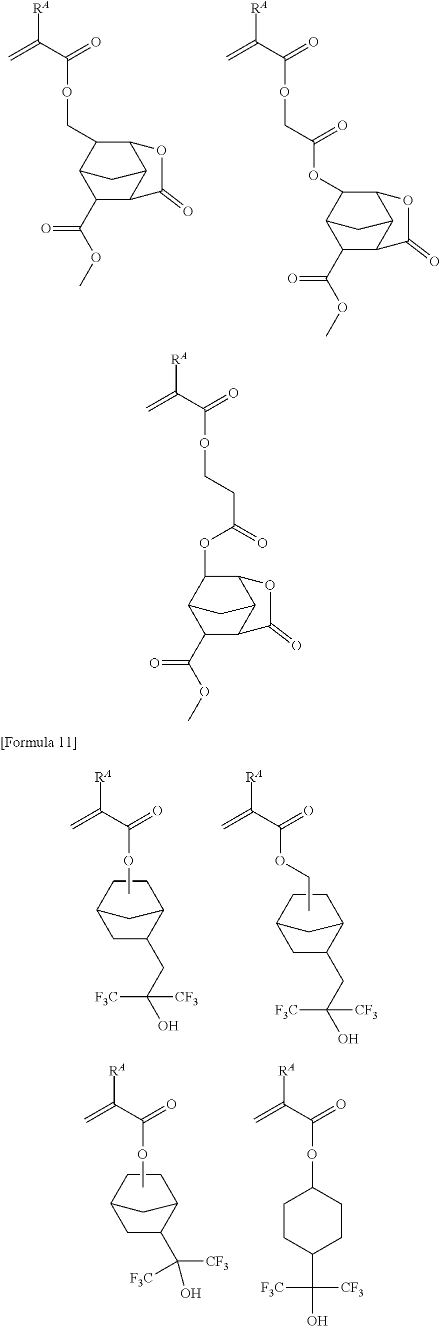

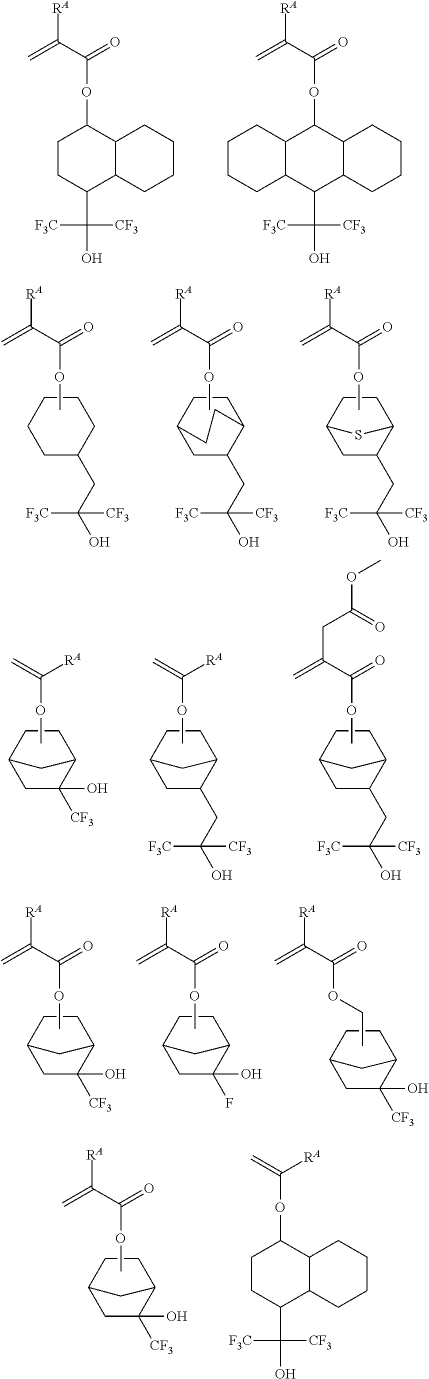

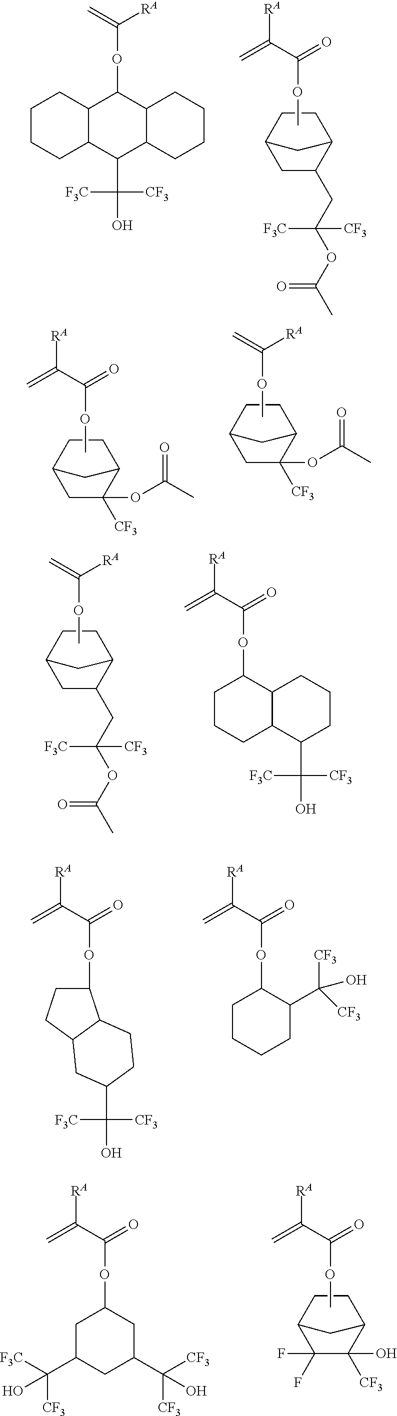

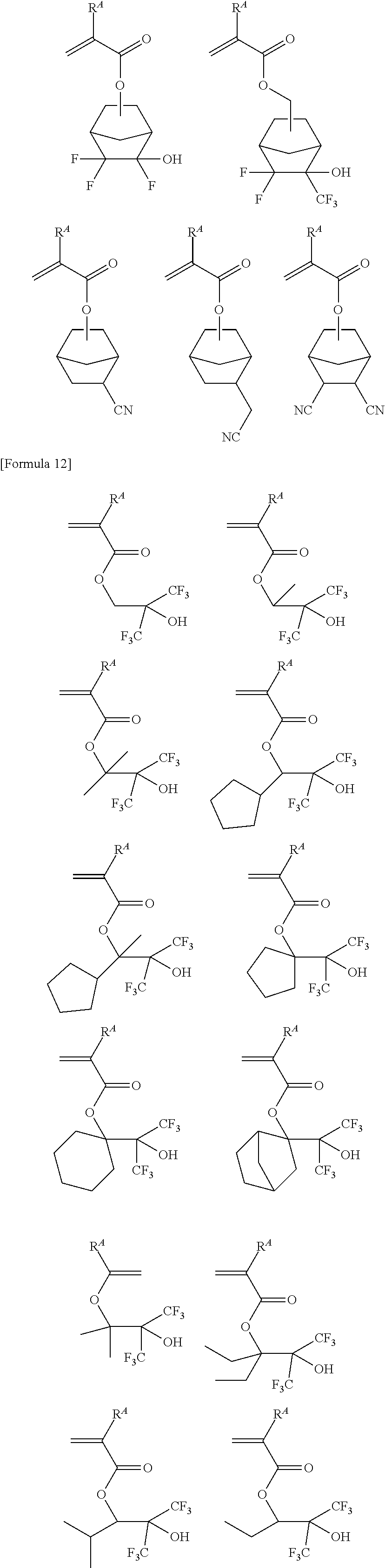

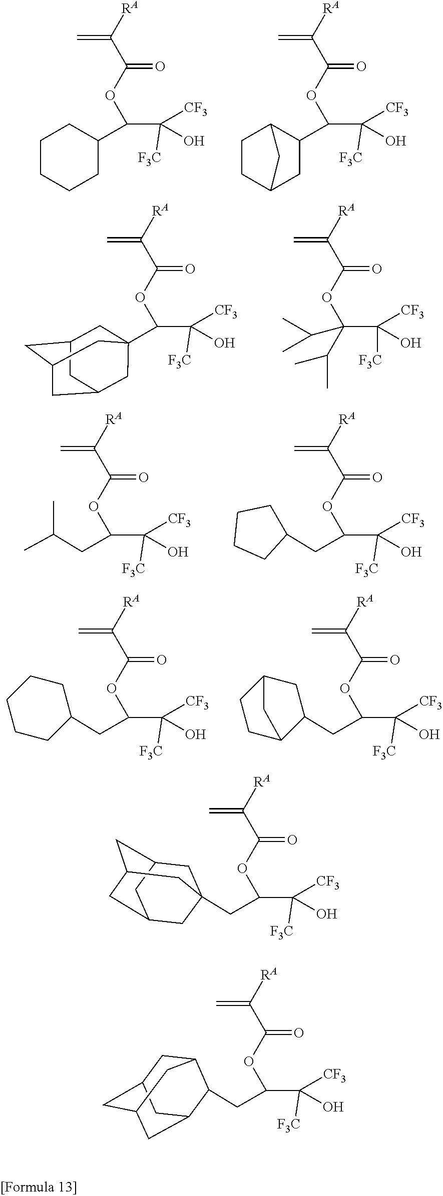

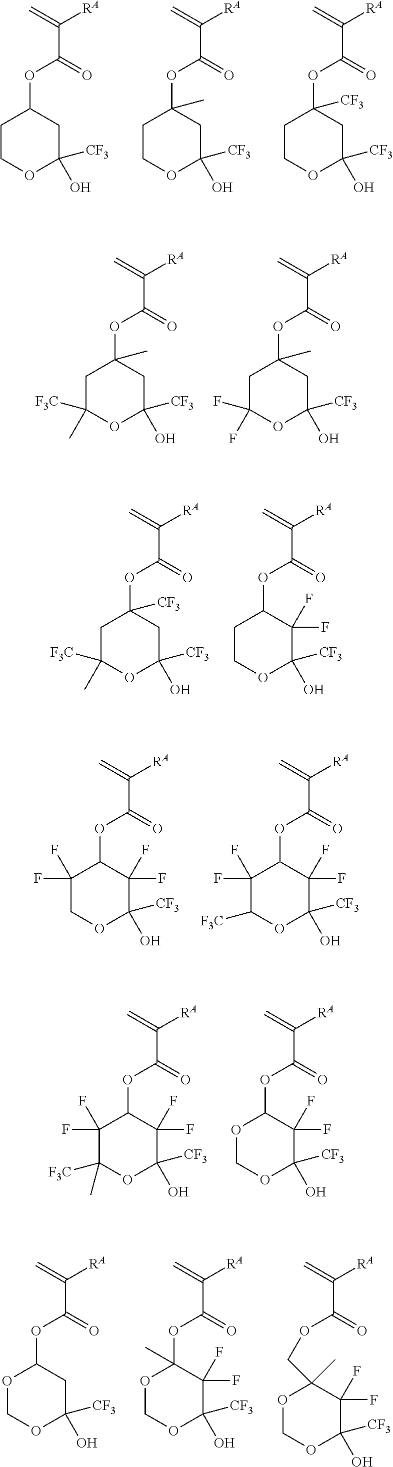

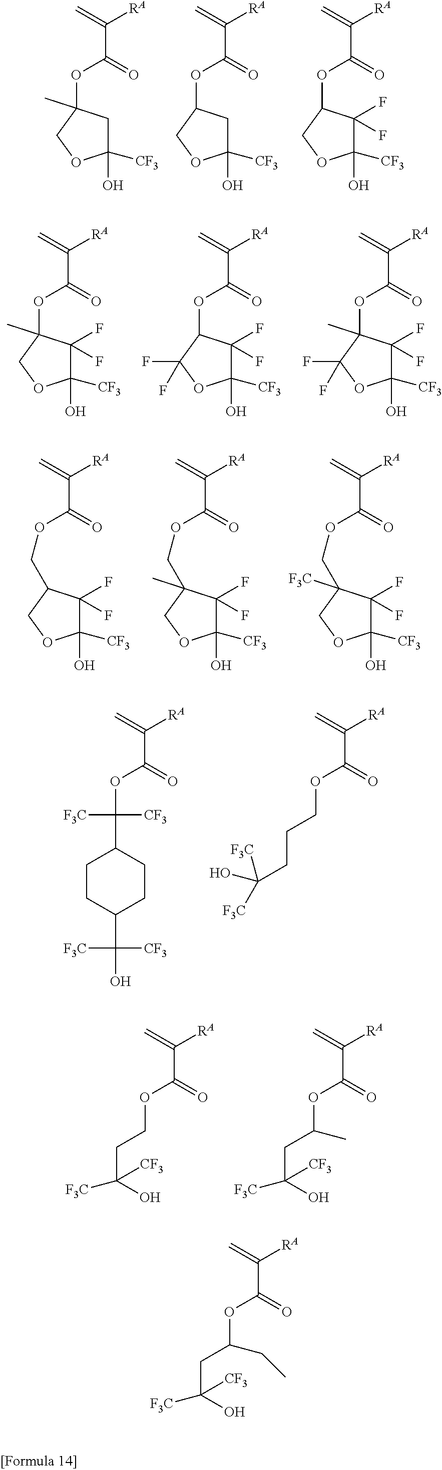

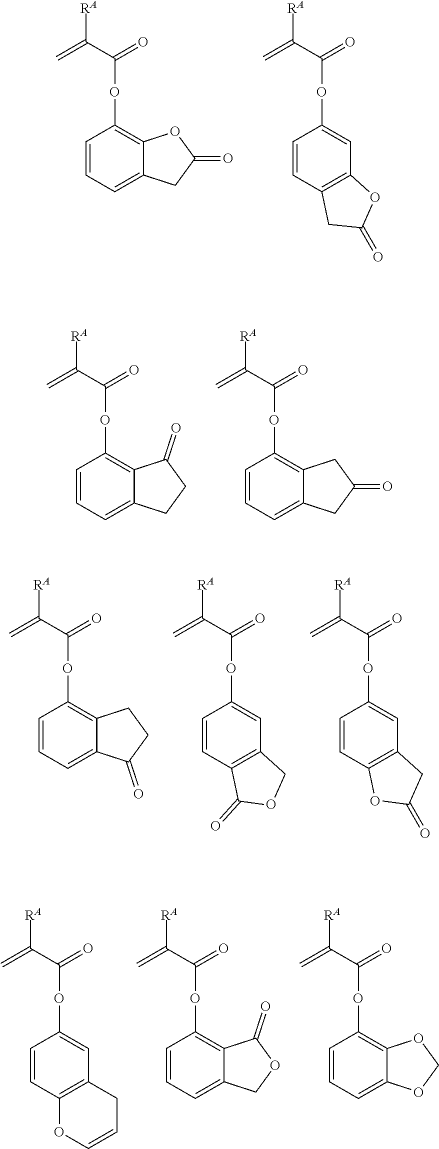

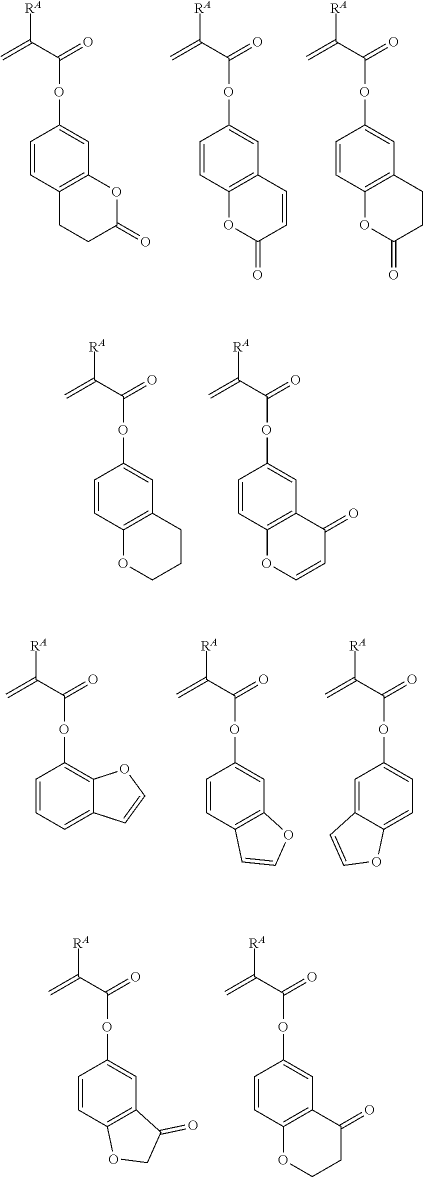

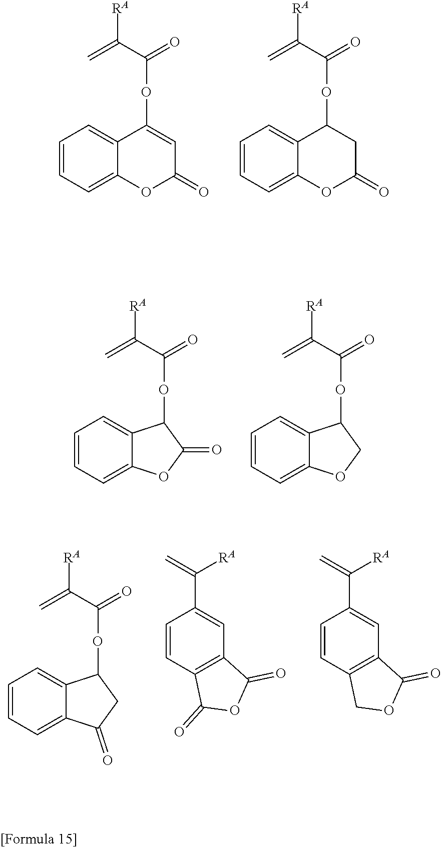

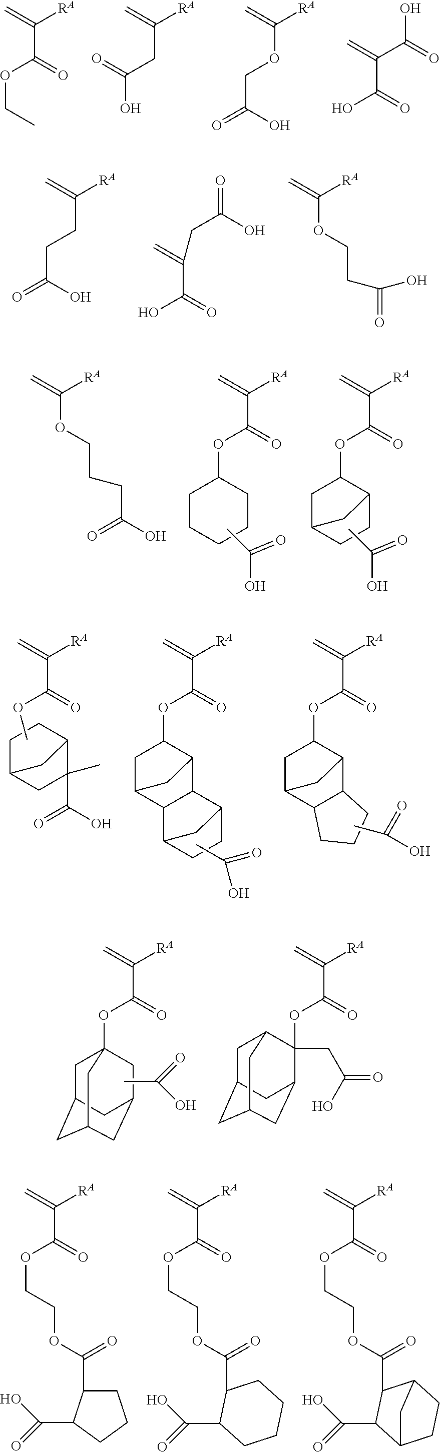

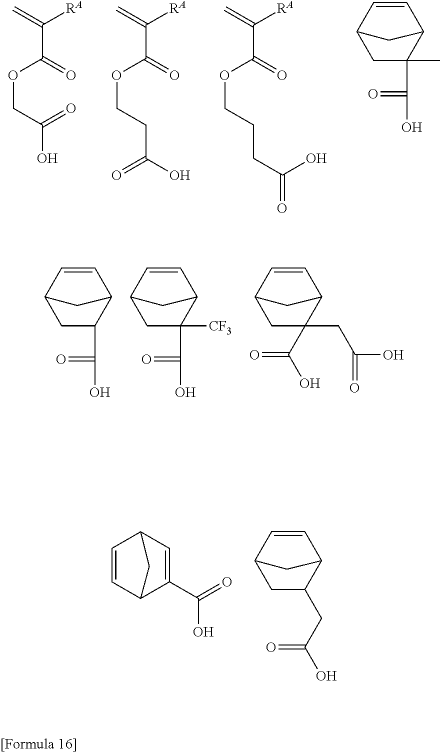

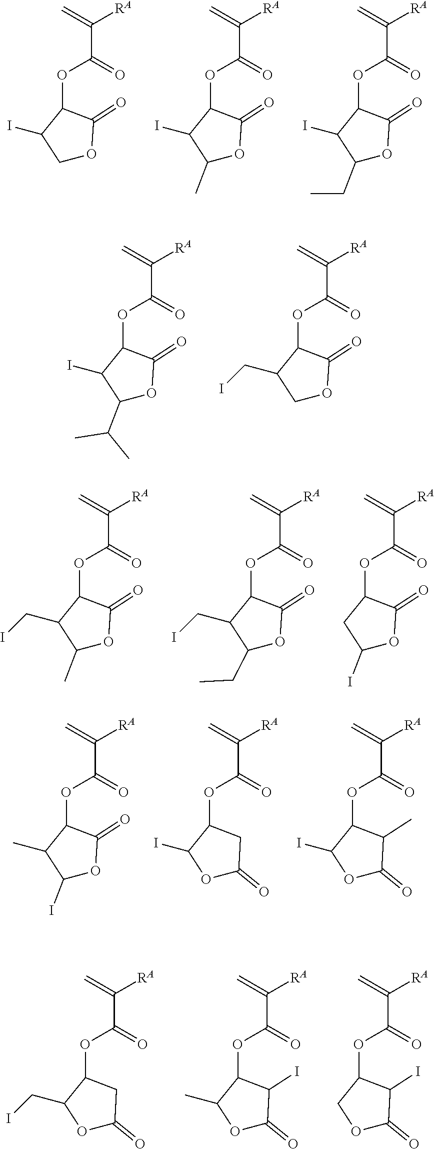

When the base polymer (A) (or the radiation-sensitive acid-generating polymer (A1)) has the structural unit (III), the lower limit of the content of the structural unit (III) (when a plurality of types is contained, the total content thereof is taken) is preferably 5 mol %, more preferably 8 mol %, and still more preferably 10 mol % based on all structural units composing the base polymer (or the base polymer (A1)). The upper limit of the content is preferably 40 mol % and more preferably 30 mol %. When the content of the structural unit (III) is adjusted to within the above range, the pattern adhesiveness can be further improved.

### (Structural Unit (IV))

The polymer (A) may contain a structural unit (IV) having a second organic acid anion and a second onium cation. By incorporating the structural unit (IV) having an onium salt structure as a part of the polymer (A), the polymer (A) can be used as the “radiation-sensitive acid-generating polymer (A1)”

The form of the organic acid anion and the onium cation contained in the structural unit (IV) of the base polymer is not particularly limited, and the base polymer may have the organic acid anion as a side chain portion or may have the onium cation as a side chain portion. Having as a side chain portion means that the corresponding organic acid anion or onium cation is bonded (covalently bonded) to the main chain as a side chain structure of the base polymer. When the organic acid anion is bonded to the main chain as a side chain structure of the base polymer, the onium cation is ionically bonded to the organic acid anion as a counter ion of the organic acid anion. On the other hand, when the onium cation is bonded to the main chain as a side chain structure of the base polymer, the organic acid anion is ionically bonded to the onium cation as a counter ion of the onium cation. From the viewpoint of controlling the acid diffusion length, the base polymer preferably has the organic acid anion as a side chain portion.

The second organic acid anion is a sulfonic acid anion containing an iodine atom, and is preferably a sulfonic acid anion containing an iodine-substituted aromatic ring structure.

Preferably, the second organic acid anion has a sulfonic acid anion, and has an electron withdrawing group such as a fluorine atom or a fluorinated hydrocarbon group bonded to a carbon atom adjacent to the sulfonic acid anion. As a result, the strength of the acid generated through exposure to light can be sufficiently enhanced to a level required for dissociation of the acid-dissociable group.

The structure of the second organic acid anion may be any sulfonic acid anion as long as the sulfonic acid anion contains an iodine atom, and other structures are not particularly limited, but for example, preferably include —O—, —CO—, a cyclic structure, or a combination thereof. The combination also includes a structure (heterocyclic structure) in which —O— or —CO— is incorporated as a moiety for forming a ring in a cyclic structure.

The cyclic structure may be any of a monocyclic ring, a polycyclic ring, or a combination thereof. The cyclic structure may be any of an alicyclic structure, an aromatic ring structure, a heterocyclic structure, or a combination thereof. In the case of the combination, the ring structure may be a structure in which ring structures are bonded through a chain structure, or two or more ring structures may form a condensed ring structure, or a bridged ring structure. A divalent heteroatom-containing group may be present between carbons forming the skeleton of the cyclic structure or the chain structure, and some or all of hydrogen atoms on carbon atoms of the cyclic structure or the chain structure may be substituted with another substituent. The second organic acid anion preferably has at least one cyclic structure selected from the group consisting of an alicyclic structure and an aromatic ring structure.

As the alicyclic structure, a structure corresponding to the monovalent alicyclic hydrocarbon group having 3 to 20 carbon atoms in R^{A2} and R^{A3} in the formula (A1) can be suitably employed.

The aromatic ring structure is not particularly limited as long as the ring forms a ring structure having aromaticity. Examples of the aromatic ring include aromatic hydrocarbon rings such as a benzene ring, a naphthalene ring, an anthracene ring, a phenalene ring, a phenanthrene ring, a pyrene ring, a fluorene ring, a perylene ring, and a coronene ring; aromatic heterocycles such as a furan ring, a pyrrole ring, a thiophene ring, a phosphole ring, a pyrazole ring, an oxazole ring, an isoxazole ring, a thiazole ring, a pyridine ring, a pyrazine ring, a pyrimidine ring, a pyridazine ring, a triazine ring, a carbazole ring, and a dibenzofuran ring, or combinations thereof. Among them, a benzene ring is preferable as the aromatic ring.

Examples of the heterocyclic structure include:
oxygen atom-containing alicyclic heterocyclic structures such as oxirane, tetrahydrofuran, tetrahydropyran, dioxolane, and dioxane;
nitrogen atom-containing alicyclic heterocyclic structures such as aziridine, pyrrolidine, piperidine, and piperazine;
sulfur atom-containing alicyclic heterocyclic structures such as thietane, thiolane, and thiane;
alicyclic heterocyclic structures containing two or more kinds of heteroatoms such as morpholine, 1,2-oxathiolane, and 1,3-oxathiolane;
oxygen atom-containing aromatic heterocyclic structures such as furan and benzofuran;
nitrogen atom-containing aromatic heterocyclic structures such as pyrrole, pyrazole, and triazine;
sulfur atom-containing aromatic heterocyclic structures such as thiophene; and
aromatic heterocyclic structures containing two or more kinds of heteroatoms such as oxazole, isothiazole, and thiazine.

The heterocyclic structures include lactone structures, cyclic carbonate structures, sultone structures, cyclic acetal structures, and a combination thereof.

As the chain structure, monovalent chain hydrocarbon groups having 1 to 20 carbon atoms represented by R^{A2} and R^{A3} in the above formula (A1) can be suitably employed.

Examples of the heteroatom constituting the above divalent heteroatom-containing group include an oxygen atom, a nitrogen atom, a sulfur atom, a phosphorus atom, a silicon atom, a halogen atom, and the like. Examples of the halogen atom include a fluorine atom, a chlorine atom, a bromine atom, and an iodine atom.

Examples of divalent heteroatom-containing groups include —CO—, —C(═O)O—, —CS—, —NH—, —O—, —S—, —SO—, —SO₂—, or a group obtained by combining these groups.

As the substituent with which some or all of hydrogen atoms on carbon atoms of the cyclic structure or the chain structure are substituted, a substituent of L¹ in the formula (A1) can be suitably employed.

As the structural unit that afford the above second organic acid anion, a structural unit represented by the following formula (a1) is preferable.

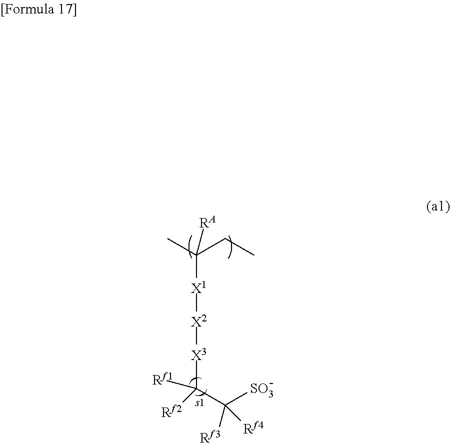

In the formulas, R^{A} is a hydrogen atom or a methyl group. X¹ is a single bond or an ester group. X² is a linear, branched or cyclic alkylene group, having 1 to 12 carbon atoms, a cycloalkylene group having 3 to 12 carbon atoms, an allylene group having 6 to 10 carbon atomes, or a combination thereof, and some of the methylene groups constituting the alkylene group may be replaced by an ether group, an ester group, or a lactone ring-containing group. X³ is a single bond, an ether group, an ester group, a linear or branched alkylene group having 1 to 12 carbon atoms, or a cyclic cycloalkylene group having 3 to 12 carbon atoms, and a part of a methylene group composing the alkylene group may be replaced by an ether group or an ester group. Some or all of the hydrogen atoms of X² and X³ may be replaced by a heteroatom or a monovalent hydrocarbon group having 1 to 20 carbon atoms and optionally containing a heteroatom. At least one of X² and X³ contains an iodine atom, and it is preferred that X² above contains an iodine-substituted aromatic ring structure.

Rf¹ to Rf⁴ are each independently a hydrogen atom, a fluorine atom, or a trifluoromethyl group, and at least one of Rf¹ to Rf⁴ is a fluorine atom or a trifluoromethyl group. s1 is 0 or 1.

As the monovalent hydrocarbon group having 1 to 20 carbon atoms in X² and X³, an alkyl group having 1 to 12 carbon atoms, a cycloalkyl group having 3 to 12 carbon atoms, or an aryl group having 6 to 20 carbon atoms is preferable, and some or all of hydrogen atoms of these groups may be substituted with a heteroatom-containing group such as a hydroxy group, a carboxy group, a halogen atom, an oxo group, a cyano group, an amide group, a nitro group, a sultone group, a sulfone group or a sulfonium salt-containing group, an alkoxy group, or an alkoxycarbonyl group, and a part of a methylene group composing these groups may be substituted with an ether group, an ester group, a carbonyl group, a carbonate group, or a sulfonate ester group.

Preferably, the structural unit that afford the second organic acid anion are each represented by the following formulas (a1-1), (a2-1) and (a3-1).

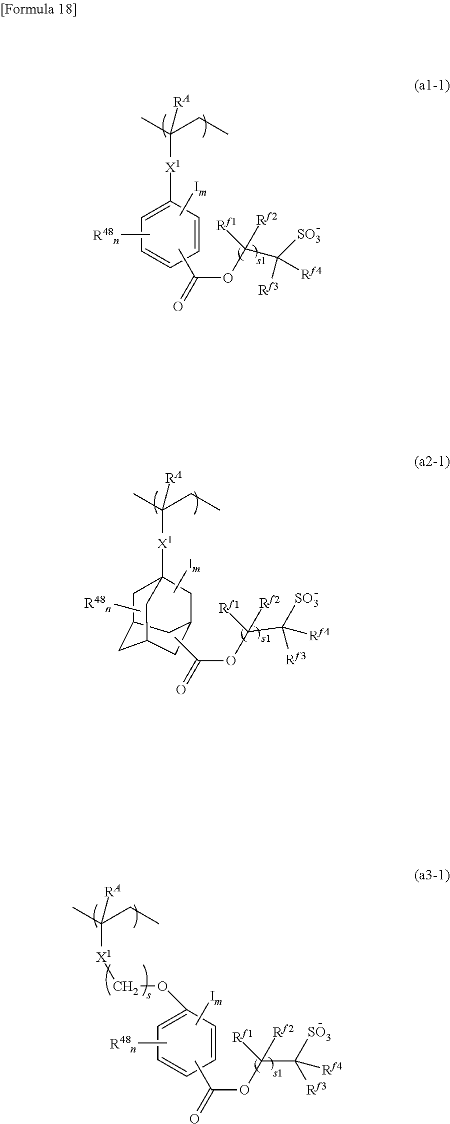

In the formulas, R^{A}, Rf¹ to Rf⁴, X¹, and s1 have the same meanings as in the formula (a1). R⁴⁸ is a linear, branched or cyclic alkyl group having 1 to 4 carbon atoms, a halogen atom other than iodine, a hydroxy group, a linear, branched or cyclic alkoxy group having 1 to 4 carbon atoms, or a linear, branched or cyclic alkoxycarbonyl group having 2 to 5 carbon atoms. m is an integer of 1 to 4. n is an integer of 0 to 3. It is to be noted 0≤m+n≤4. s is an integer of 1 to 5.

Examples of the monomers that afford the structural unit include, but are not limited to, those shown below.

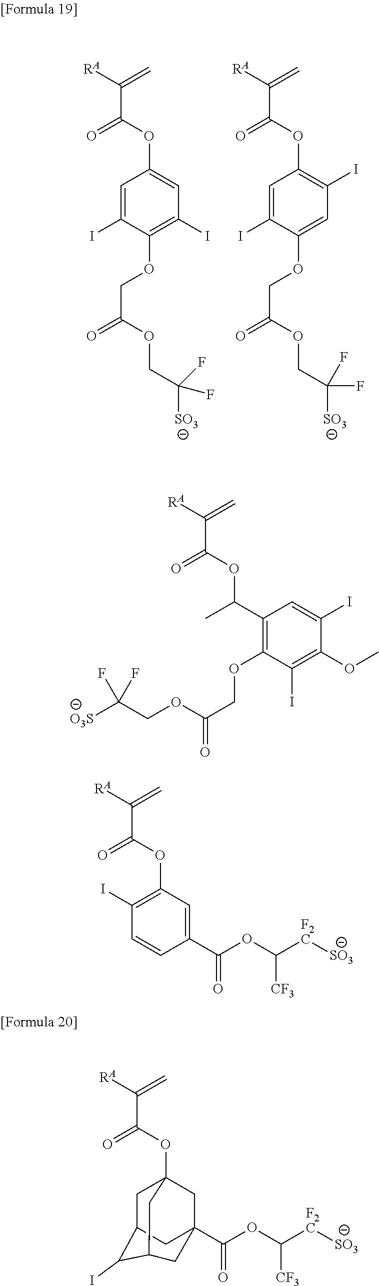

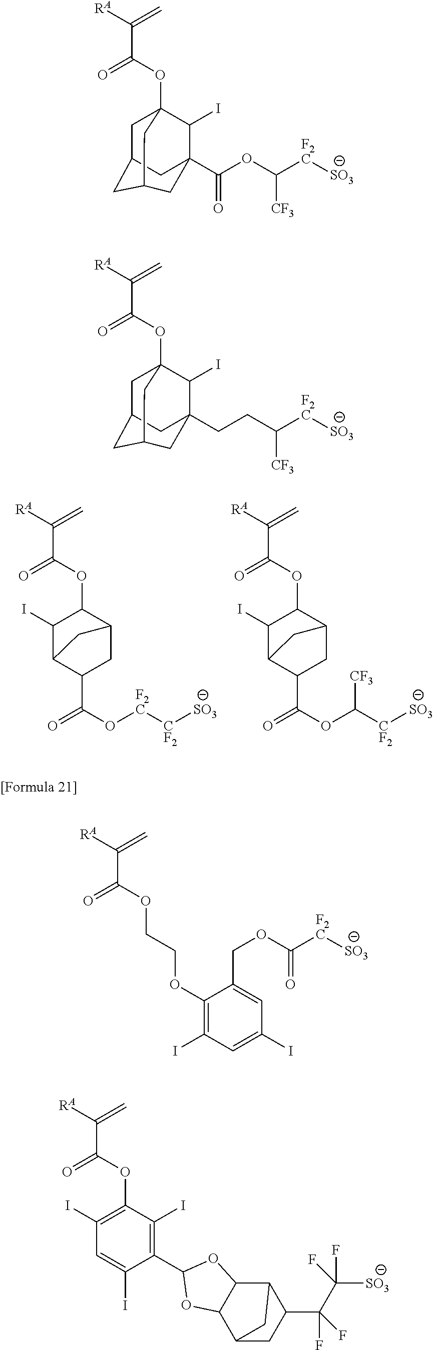

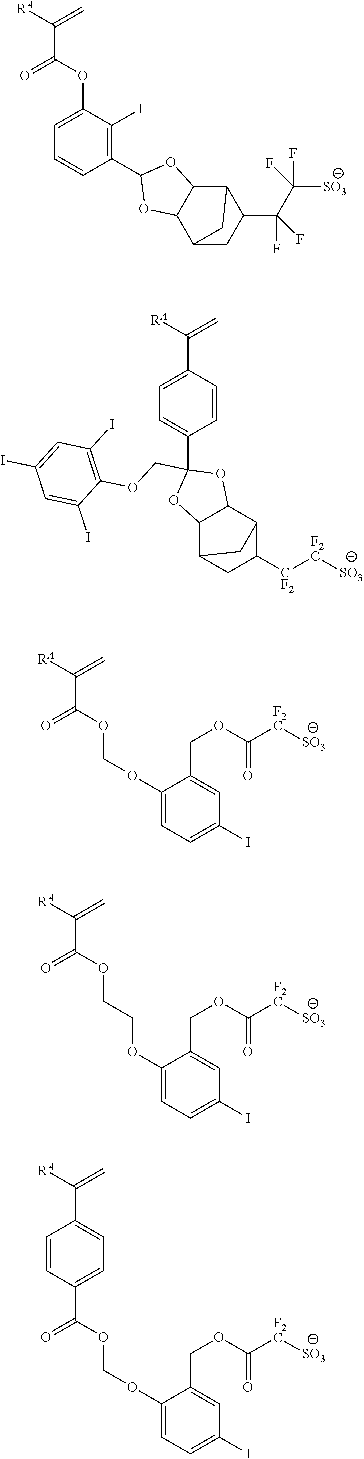

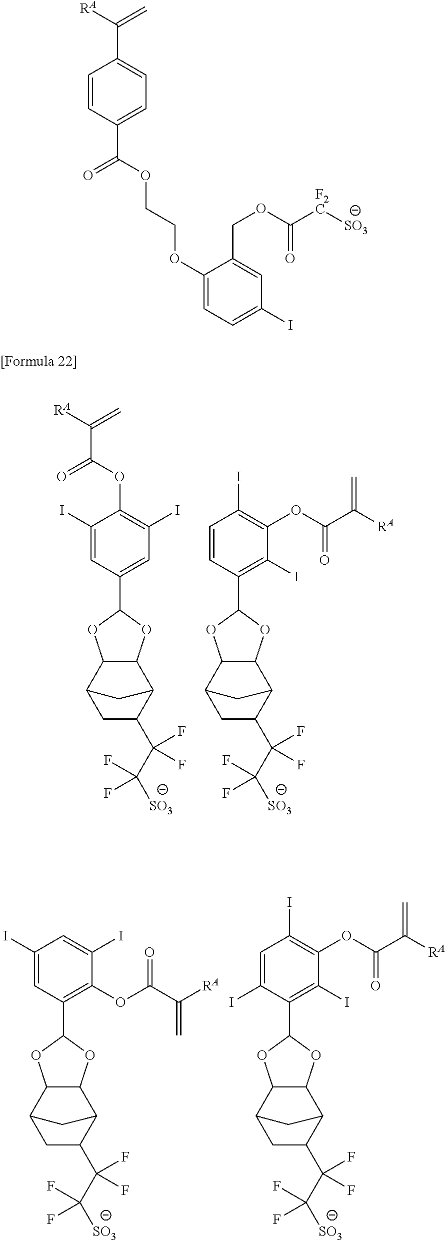

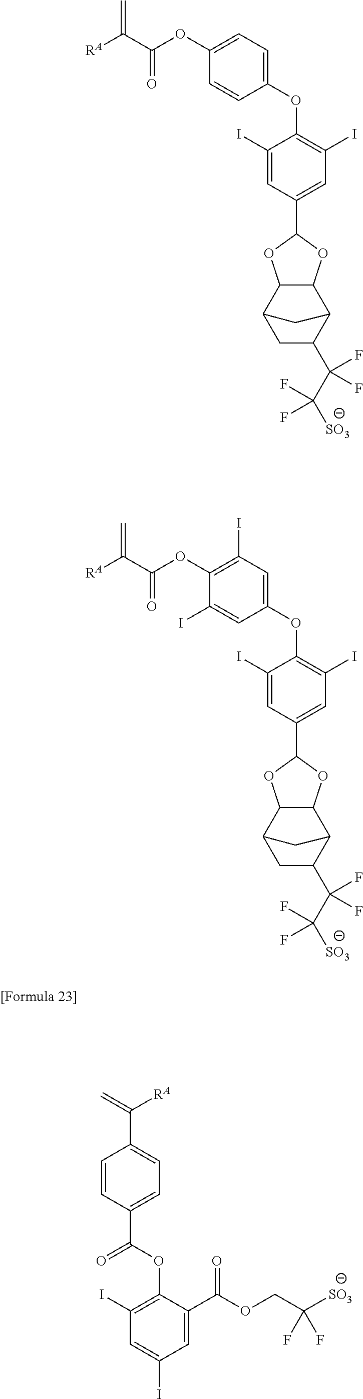

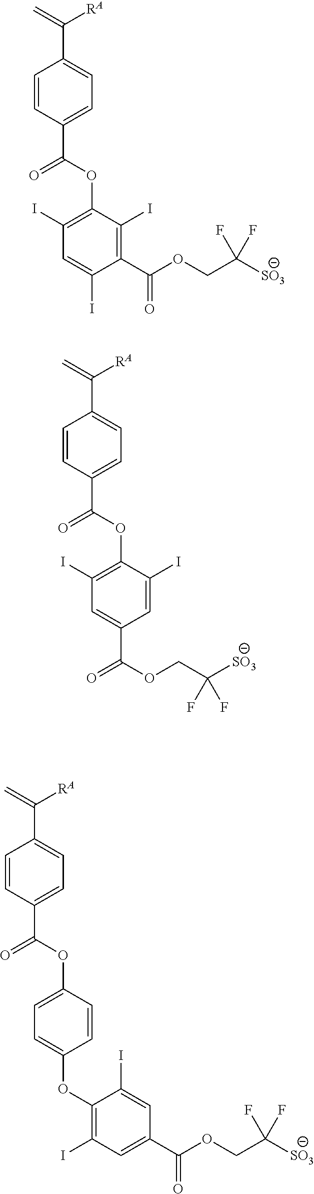

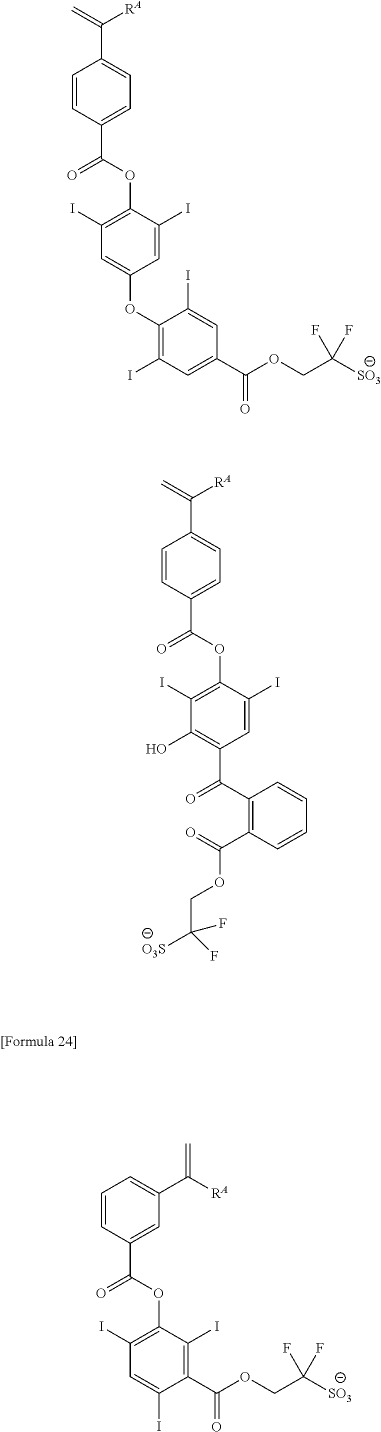

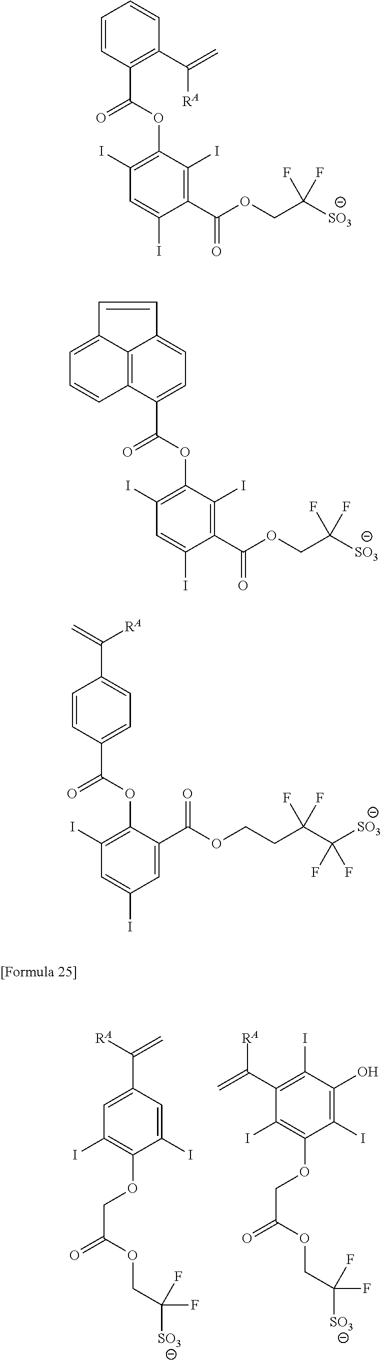

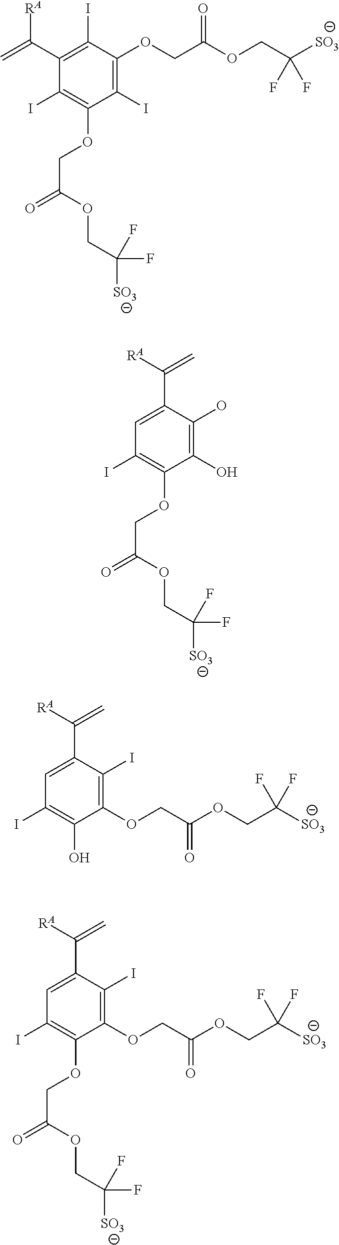

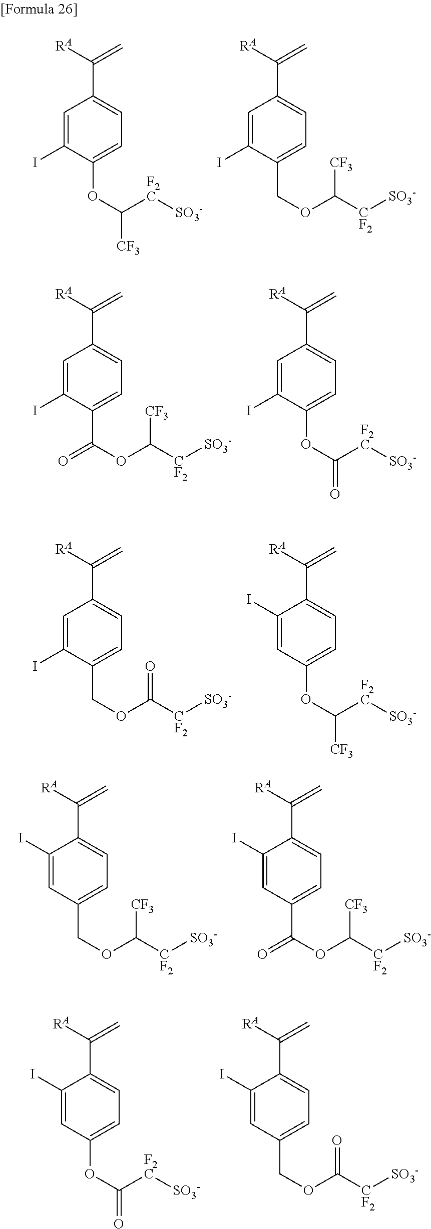

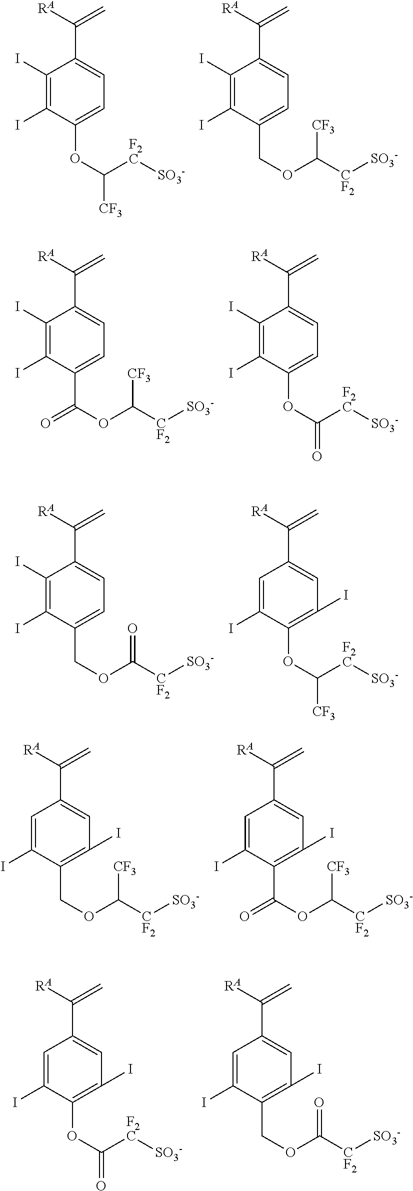

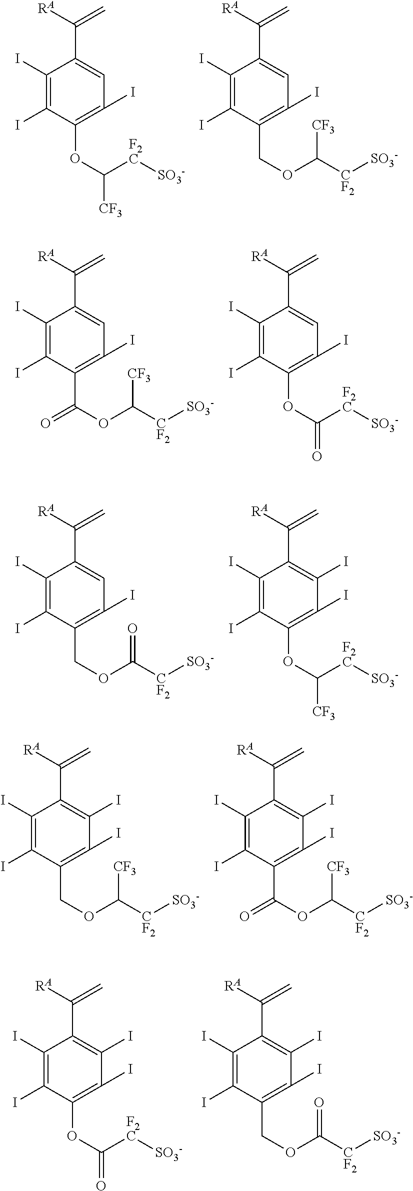

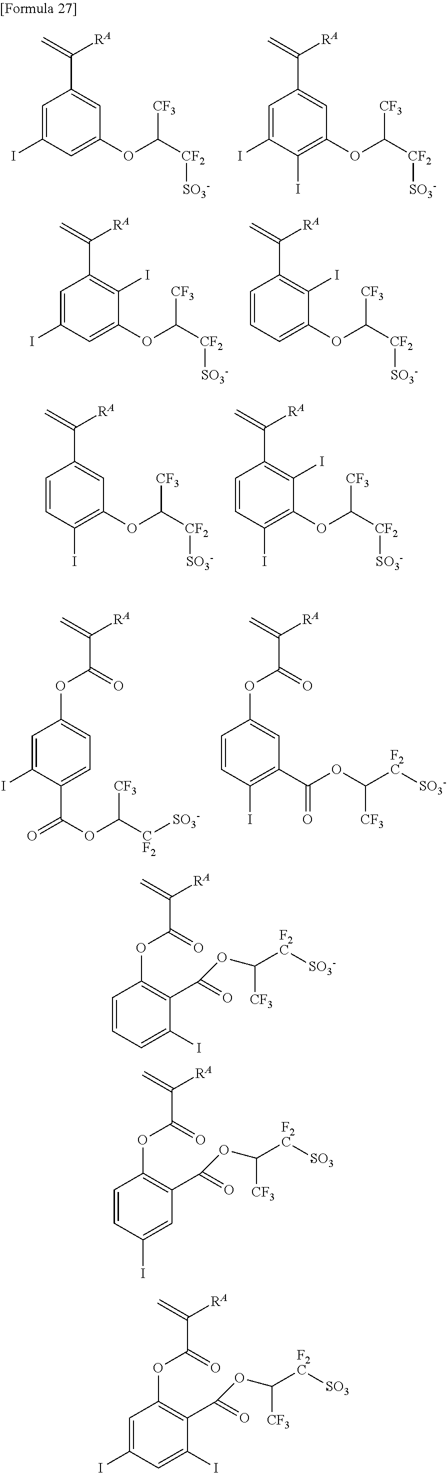

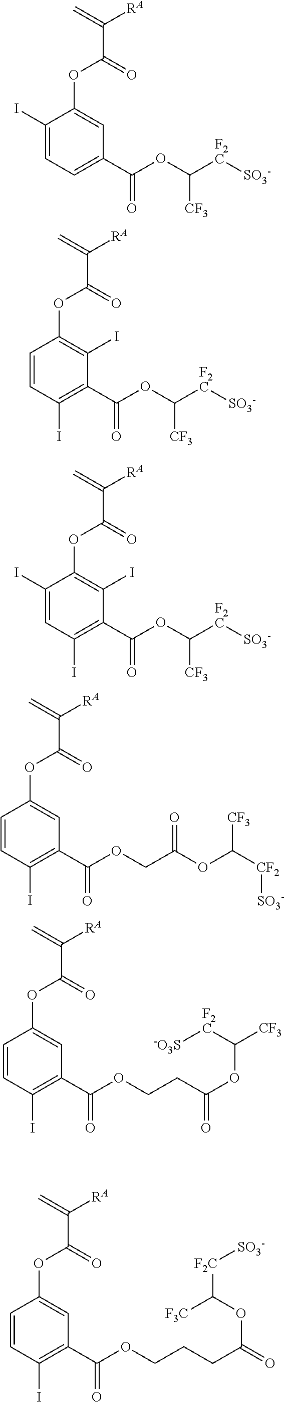

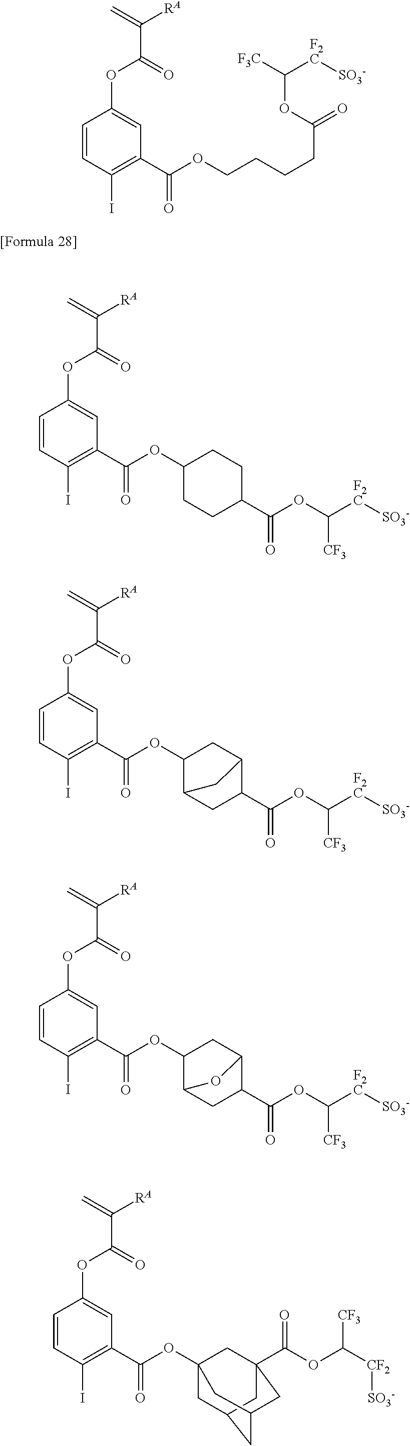

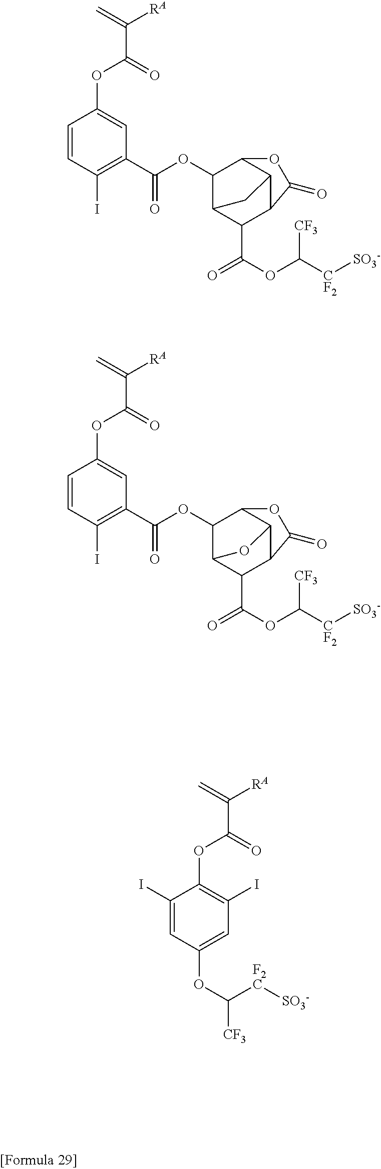

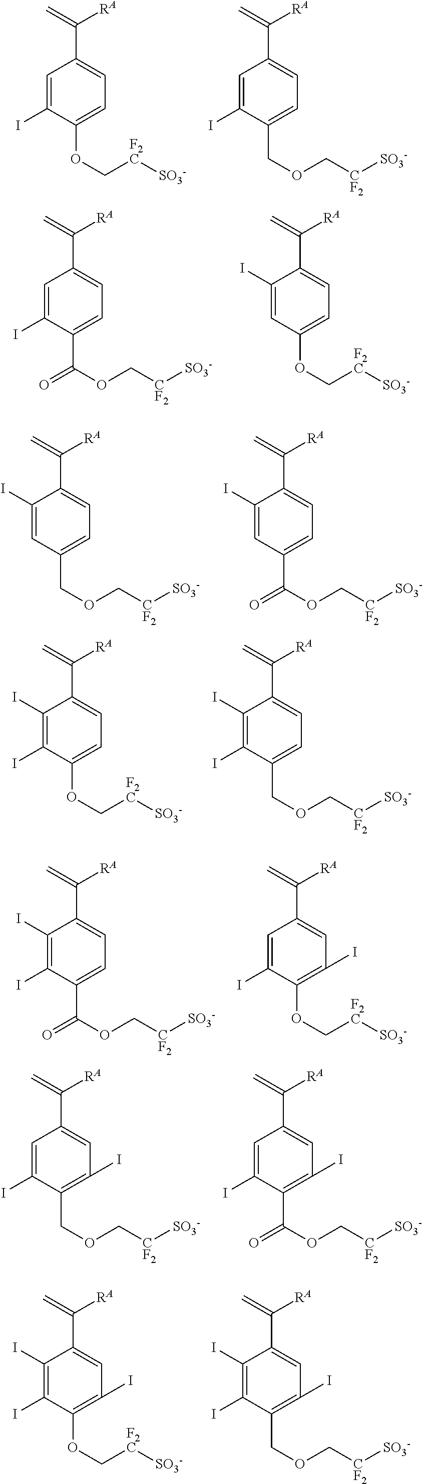

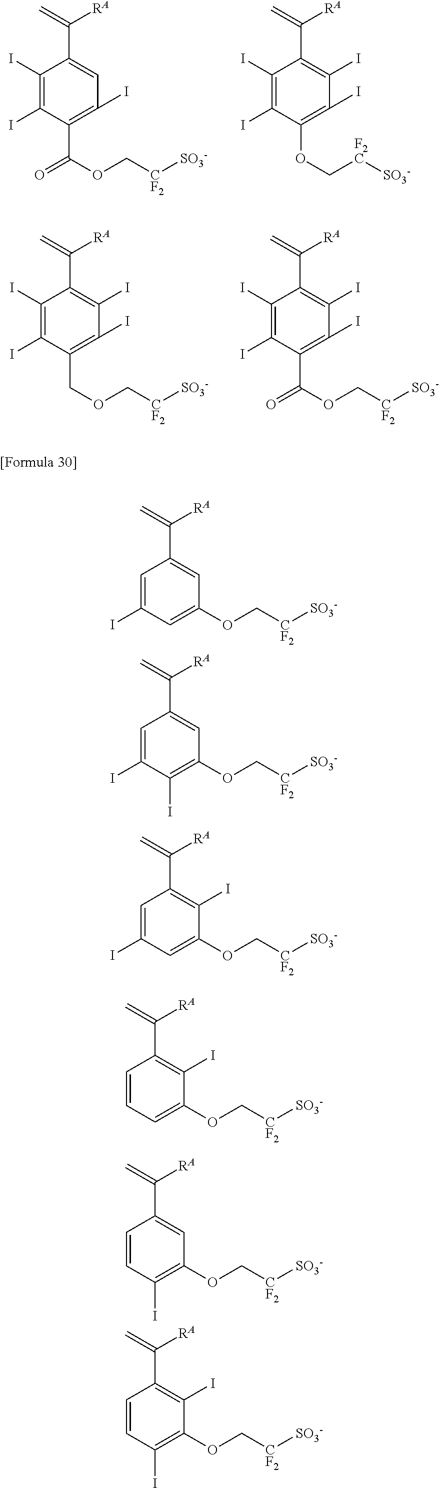

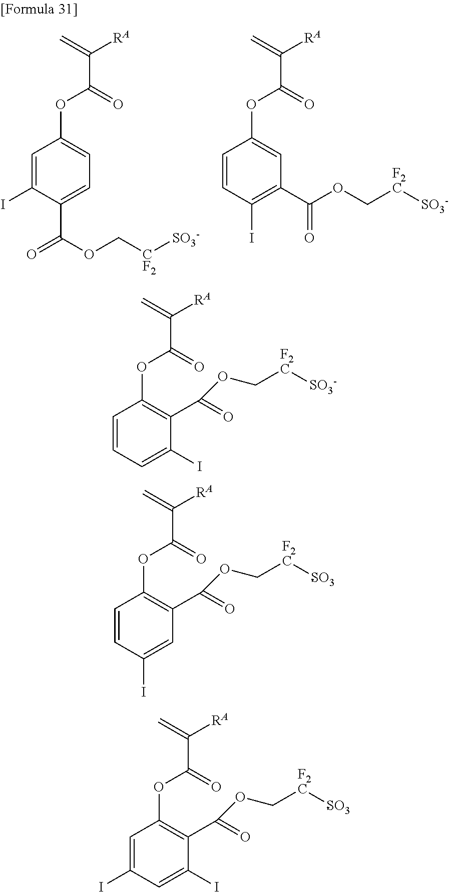

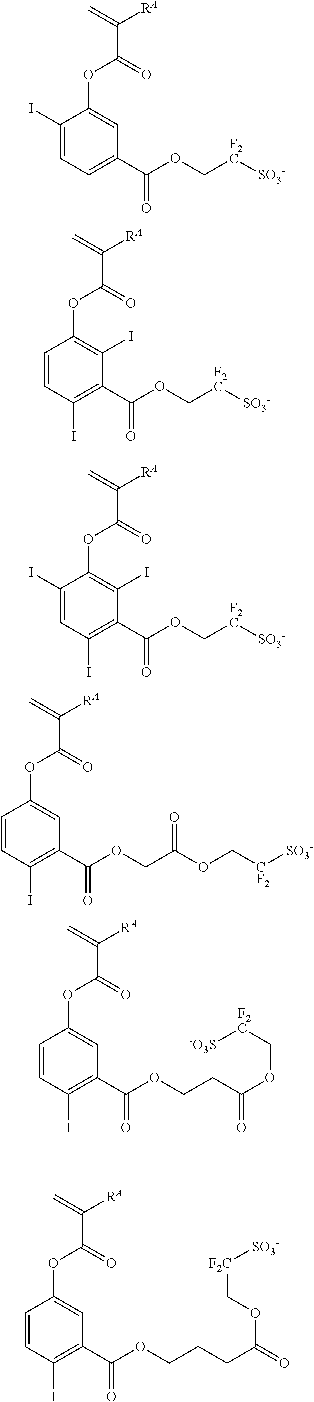

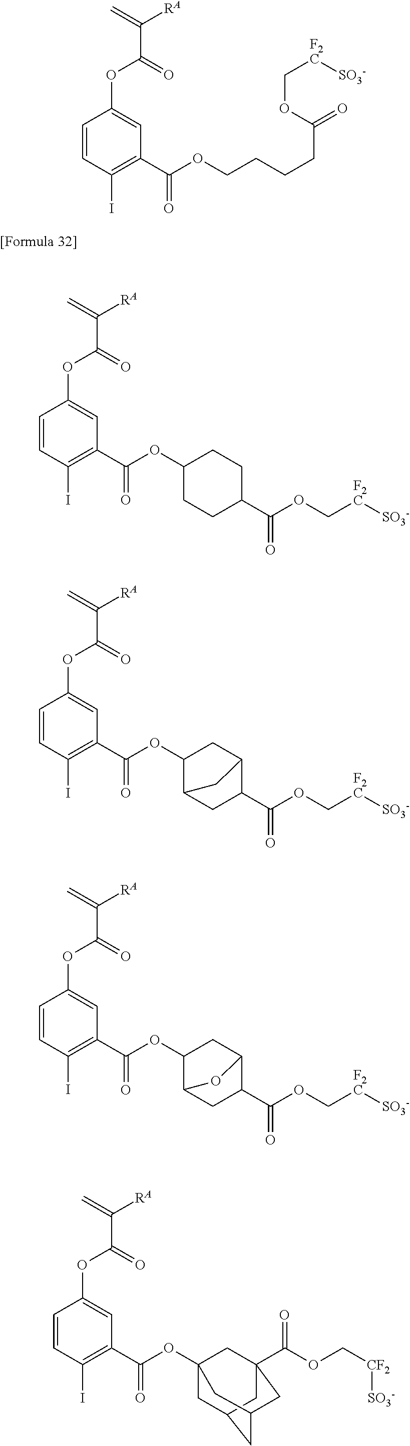

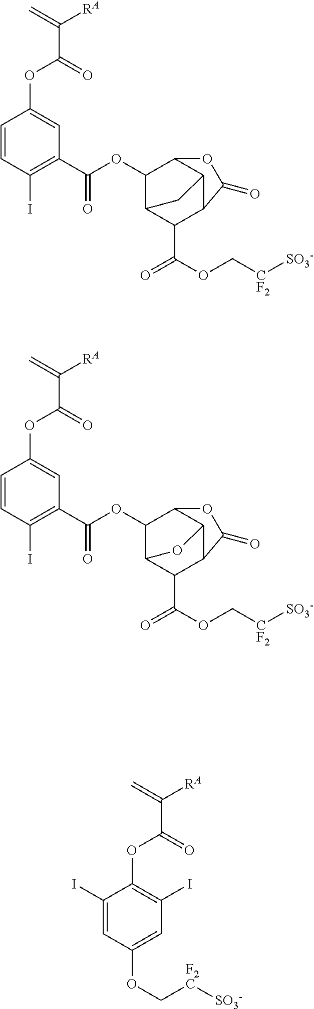

(In the formula, R^{A} has the same meanings as in the formula (a1).)

The second onium cation may be the same as the first onium cation of the radiation-sensitive acid generator (B) described later.

Examples of the structural unit (IV) include those having the second onium cation as a counter ion of an anion of the structural unit that provides the second organic acid anion.

When the polymer (A) has the structural unit (IV), the lower limit of the content of the structural unit (IV) (when a plurality of types is contained, the total content thereof is taken) is preferably 1 mol %, more preferably 3 mol %, and still more preferably 5 mol % based on all structural units composing the base polymer (A1). The upper limit of the content is preferably 30 mol %, more preferably 25 mol %, and still more preferably 20 mol %. When the contents of the structural unit (IV) are adjusted to within the above range, a function as an acid generator can be sufficiently exhibited.

### (Method for Synthesizing Polymer (A))

The polymer (A) can be synthesized, for example, by polymerizing monomers to afford the above-described structural units in an organic solvent by heating with addition of a radical polymerization initiator. In the polymerization, a known polymerization initiator can be used.

When hydroxystyrene or hydroxyvinylnaphthalene is copolymerized, acetoxystyrene or acetoxyvinylnaphthalene may be used instead of hydroxystyrene or hydroxyvinylnaphthalene, and an acetoxy group may be deprotected by the alkali hydrolysis after polymerization to form a hydroxystyrene unit or a hydroxyvinylnaphthalene unit. Polymerization may be performed as it is without protecting the hydroxyl group.

The lower limit of the polystyrene-equivalent weight average molecular weight (Mw) of the polymer (A) as measured by gel permeation chromatography (GPC) using THF as a solvent is preferably 2,000, and more preferably 4,000. The upper limit of the Mw is preferably 30,000, and more preferably 15,000. When the Mw is in the above range, the patternability and heat resistance of a resist material are good.

Furthermore, in a case where the polymer (A) has a wide molecular weight distribution (Mw/Mn), since a low molecular weight or high molecular weight polymer is present, there is a risk that foreign matters may be found on a pattern or the shape of the pattern may be deteriorated after exposure. Since the influence of Mw and molecular weight distribution tends to increase as the pattern rule becomes finer, in order to obtain a resist material suitably used for fine pattern dimensions, the molecular weight distribution of the polymer (A) is preferably a narrow dispersion of 1.0 to 2.0, particularly 1.0 to 1.8.

The polymer (A) may contain two or more polymers differing in composition ratio, Mw, and molecular weight distribution.

The lower limit of the content of the polymer (A) in the radiation-sensitive composition is preferably 40% by mass, more preferably 50% by mass, and still more preferably 60% by mass based on the amount of the radiation-sensitive composition excluding the solvent (C) contained therein. The upper limit of the content is preferably 99% by mass, and more preferably 95% by mass.

### <Radiation-Sensitive Acid Generator (B)>

The radiation-sensitive acid generator (B) contains a first organic acid anion and a first onium cation, in which the first onium cation is an onium cation containing a halogen-free electron withdrawing group containing no halogen atom, and the first organic acid anion is a sulfonic acid anion containing an iodine atom. The radiation-sensitive composition of the present disclosure contains at least one of the radiation-sensitive acid-generating polymer (A1) or the radiation-sensitive acid generator (B), and may contain both of them.

### (First Onium Cation)

The first onium cation includes a halogen-free electron withdrawing group containing no halogen atom. The halogen-free electron withdrawing group may be any group as long as the group has electron withdrawing properties and does not contain a halogen atom, and is preferably, for example, at least one electron withdrawing group selected from the group consisting of CN, COOR¹¹, NO₂, COR¹², SOR¹³, and SO₂R¹⁴, wherein R¹¹ to R¹⁴ are each independently a hydrogen atom or a monovalent hydrocarbon group having 1 to 12 carbon atoms.

The first onium cation may be any cation as long as the cation contains a halogen-free electron withdrawing group, and may contain a halogen-containing electron withdrawing group together with the halogen-free electron withdrawing group. Examples of such a halogen-containing electron withdrawing group include a halogen atom such as a fluorine atom or an iodine atom, and a halogen atom-containing group.

As the monovalent hydrocarbon group having 1 to 12 carbon atoms represented by R¹¹ to R¹⁴, a monovalent hydrocarbon group having 1 to 12 carbon atoms among specific examples of the monovalent hydrocarbon group having 1 to 20 carbon atoms in R^{A1} of the formula (A1) can be suitably employed. Among them, R¹¹ to R¹⁴ are preferably an alkyl group having 1 to 6 carbon atoms or a group having a divalent heteroatom-containing group between carbon atoms of the alkyl group from the viewpoint of development defects.

Among the halogen-free electron withdrawing groups, at least one electron withdrawing group selected from the group consisting of CN, COOR¹¹, NO₂, COR¹², SOR¹³, and SO₂R¹⁴ (wherein R¹¹ to R¹³ are each independently a hydrogen atom or a monovalent hydrocarbon group having 1 to 12 carbon atoms, and R¹⁴ is a chain hydrocarbon group having 1 to 12 carbon atoms) are preferable, at least one electron withdrawing group selected from the group consisting of CN, COOR¹¹ (R¹¹ is an alkyl group having 1 to 6 carbon atoms), NO₂, COR¹² (R¹² is an alkyl group having 1 to 6 carbon atoms), and SO₂R¹⁴ (R¹⁴ is an alkyl group having 1 to 6 carbon atoms) are more preferable.

The number of the halogen-free electron withdrawing groups in the onium cation is preferably 1 to 5, more preferably 1 to 4. It is preferable from the viewpoint of hydrophilicity that the number of halogen-free electron withdrawing groups is within the above range.

The above first onium cation is preferably a sulfonium cation or an iodonium cation, and more preferably a cation represented by following formula (1) or formula (2).

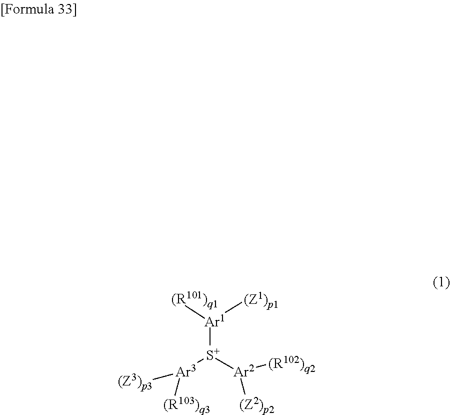

wherein in the formula (1),
Ar¹, Ar², and Ar³ are each independently a monovalent aromatic hydrocarbon group having 6 to 20 carbon atoms,
Z¹, Z², and Z³ are each independently the halogen-free electron withdrawing group, when there is a plurality of Z¹s, Z²s, and Z³s, the plurality of Z¹s, Z²s, and Z³s are the same as or different from each other,
R¹⁰¹, R¹⁰², and R¹⁰³ are each independently a monovalent organic group (provided that halogen-free electron withdrawing groups were excluded), a halogen atom, a hydroxy group, or an amino group, or two of R¹⁰¹, R¹⁰², and R¹⁰³ are linked to represent a ring structure, when there is a plurality of R¹⁰¹s, R¹⁰²s, and R¹⁰³s, the plurality of R¹⁰¹s, R¹⁰²s, and R¹⁰³s are the same as or different from each other,
p1, p2, and p3 are each independently an integer of 0 to 3, provided that p1+p2+p3 is 1 or more,
q1, q2, and q3 are each independently an integer of 0 to 2, and
p1+q1, p2+q2, and p3+q3 are each 5 or less,

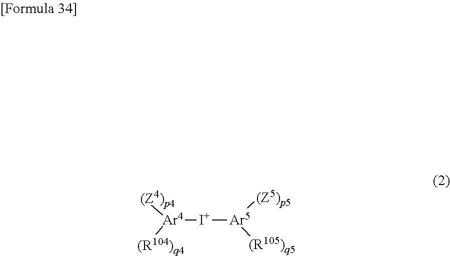

wherein in the formula (2),
Ar⁴ and Ar⁵ are each independently a monovalent aromatic hydrocarbon group having 6 to 20 carbon atoms,
Z⁴ and Z⁵ are each independently the halogen-free electron withdrawing group, when there is a plurality of Z⁴s and Z⁵s, the plurality of Z⁴s and Z⁵s are the same as or different from each other,
R¹⁰⁴ and R¹⁰⁵ are each independently a monovalent organic group, provided that halogen-free electron withdrawing groups were excluded, a halogen atom, a hydroxy group, or an amino group, when there is a plurality of R¹⁰⁴s and R¹⁰⁵s, the plurality of R¹⁰⁴s and R¹⁰⁵s are the same as or different from each other;
p4 and p5 are each independently an integer of 0 to 3; provided that p4+p5 is 1 or more,
q4 and q5 are each independently an integer of 0 to 2, and
p4+q4 and p5+q5 are each 5 or less.

As the monovalent aromatic hydrocarbon groups having 6 to 20 carbon atoms represented by Ar¹ to Ar⁵, a monovalent aromatic hydrocarbon groups having 6 to 20 carbon atoms of R^{A1} of the formula (A1) can be suitably employed.

Z¹ to Z⁵ are the halogen-free electron withdrawing group, and Z¹ to Z⁵ are preferably CN, COOR¹¹ (R¹¹ is an alkyl group having 1 to 6 carbon atoms), NO₂, COR¹² (R¹² is an alkyl group having 1 to 6 carbon atoms), or SO₂R¹⁴ (R¹⁴ is an alkyl group having 1 to 6 carbon atoms).

Examples of the monovalent organic group represented by R¹⁰¹ to R¹⁰⁵ include a monovalent hydrocarbon group having 1 to 20 carbon atoms, a group containing a divalent heteroatom-containing group between carbon atoms of this hydrocarbon group, a group obtained by substituting some or all of the hydrogen atoms of the hydrocarbon group with a monovalent substituent, and a combination thereof. Examples of the monovalent substituent include a substituent in L¹ of the formula (A1), —NR^{Y4}R^{Y5} (R^{Y4} and R^{Y5} are the same as or different from each other, and are a hydrogen atom or a monovalent hydrocarbon group), a group in which the hydrogen atom of these groups is substituted with a halogen atom, or the like.

As the monovalent hydrocarbon groups having 1 to 20 carbon atoms represented by R¹⁰¹ to R¹⁰⁵, and the monovalent hydrocarbon groups represented by R^{Y4} and R^{Y5}, a monovalent hydrocarbon groups having 1 to 20 carbon atoms of R^{A1} of the formula (A1) can be suitably employed.

As the heteroatom constituting the divalent heteroatom-containing group and the divalent heteroatom-containing group, those exemplified in the structural unit (IV) can be suitably employed.

Two of R¹⁰¹, R¹⁰², and R¹⁰³ may also be linked to form a ring (that is, a heterocyclic ring containing a sulfur atom). In this case, it is preferable that two of R¹⁰¹, R¹⁰², and R¹⁰³ are bonded to each other to form a single bond or a divalent linking group. Examples of the divalent linking group include —COO—, —OCO—, —CO—, —O—, —S—, —SO—, —SO₂—, an alkylene group, a cycloalkylene group, an alkenylene group, and combinations of two or more thereof, and those having 20 or less carbon atoms in total are preferable. When two of R¹⁰¹, R¹⁰², and R¹⁰³ are linked to each other to form a ring, it is preferable that two of R¹⁰¹, R¹⁰², and R¹⁰³ are linked to each other to form —COO—, —OCO—, —CO—, —O—, —S—, —SO—, —SO₂—, or a single bond. Among them, it is more preferable to form —O—, —S—, or a single bond, and it is particularly preferable to form a single bond. When q1 is 2 or more, a plurality of R¹⁰¹s may be linked to each other to form a ring. When q2 is 2 or more, a plurality of R¹⁰²s may be linked to each other to form a ring. When q3 is 2 or more, a plurality of R¹⁰³s may be linked to each other to form a ring. Examples thereof include an aspect in which two R¹⁰¹s are linked to each other to form a naphthalene ring together with a benzene ring to which two R¹⁰¹s are bonded.

p1, p2, and p3 are each independently an integer of 0 to 3, and p1+p2+p3 is 1 or more, preferably 2 or more. Furthermore, p1+p2+p3 is preferably 6 or less, more preferably 4 or less.

Specific examples of the sulfonium cation represented by the formula (1) include the following. The fluorine atom or the iodine atom in the following onium cation may be substituted with a hydrogen atom or another substituent, and the hydrogen atom on the aromatic ring may be substituted with an iodine atom, a fluorine atom, a group containing these atoms, another substituent, or the like.

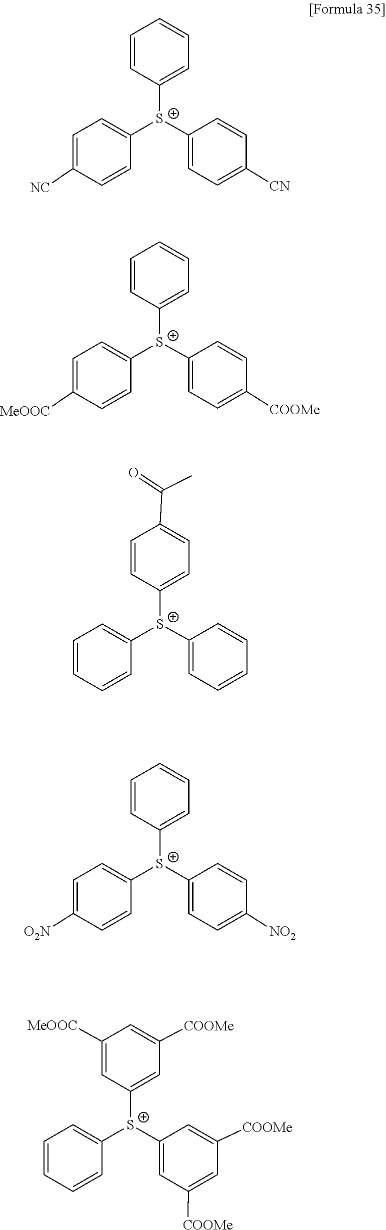

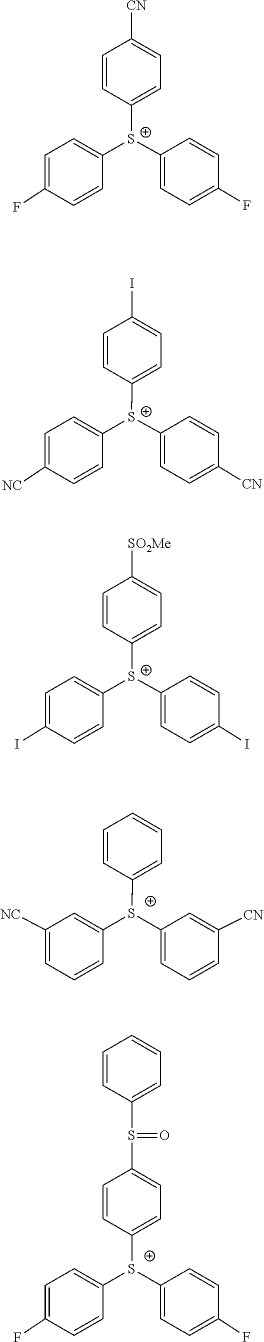

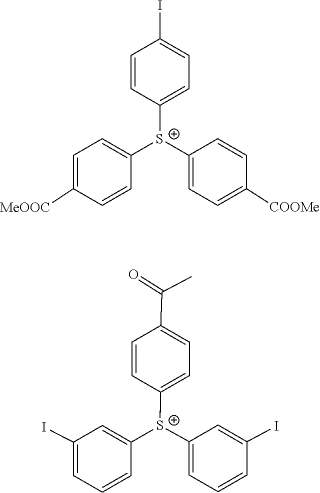

In the formula, Me represents a methyl group.

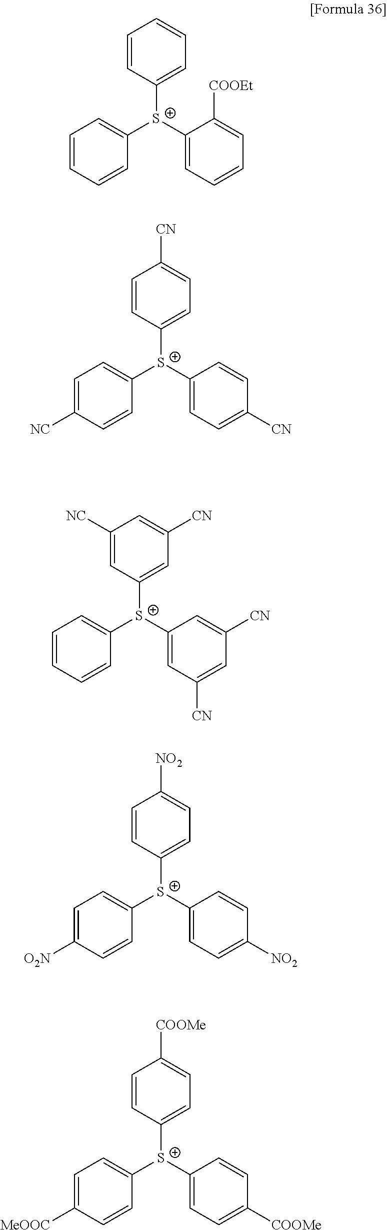

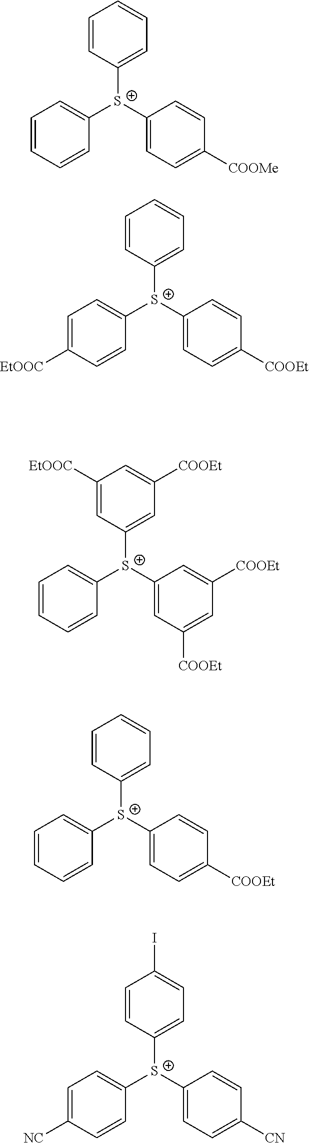

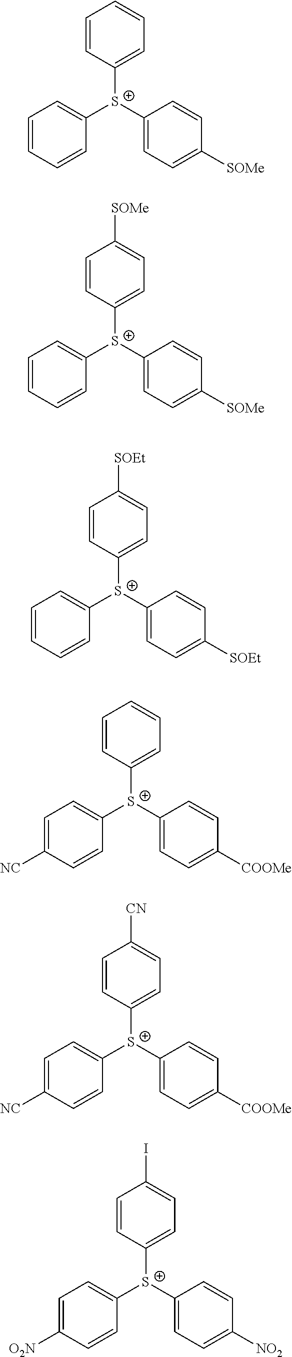

In the formula, Me represents a methyl group, and Et represents an ethyl group.

Specific examples of the iodonium cation include the following. The hydrogen atom on the aromatic ring in the following onium cation may be substituted with an iodine atom, a fluorine atom, a group containing these atoms, another substituent, or the like.

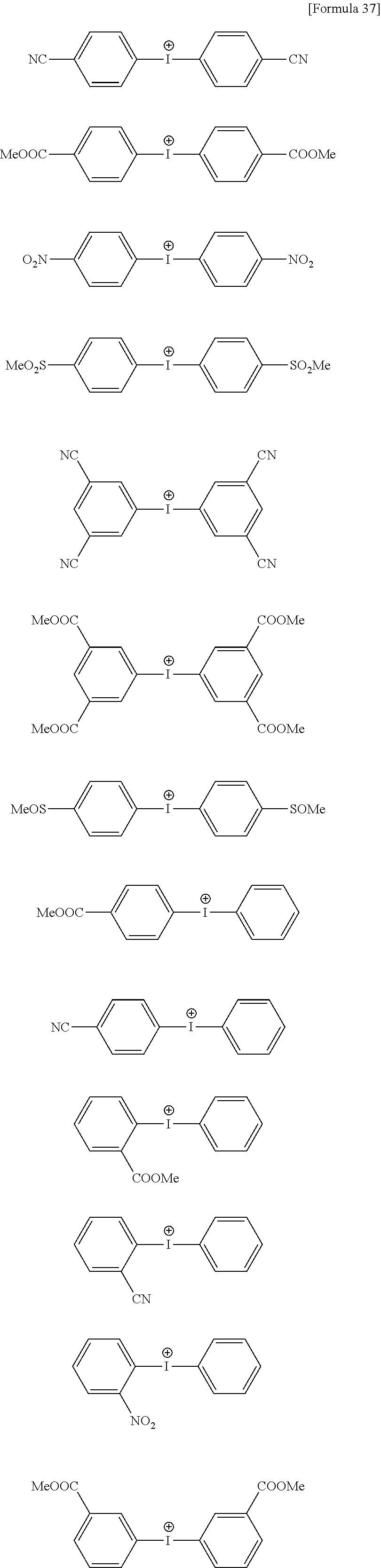

In the formula, Me represents a methyl group.

### (First Organic Acid Anion)

The first organic acid anion is a sulfonic acid anion containing an iodine atom, which is preferably represented by the following formula (A-1), for example.

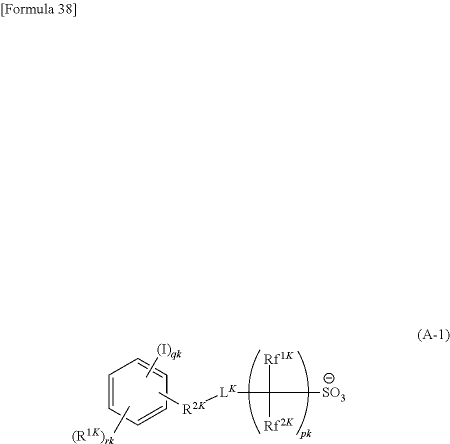

In the formula (A-1), RIK is a hydroxy group, a carboxy group, a fluorine atom, a chlorine atom, a bromine atom, or an amino group; or is an alkyl group having 1 to 20 carbon atoms, an alkoxy group having 1 to 20 carbon atoms, an alkoxycarbonyl group having 2 to 10 carbon atoms, an acyloxy group having 2 to 20 carbon atoms, or an alkylsulfonyloxy group having 1 to 20 carbon atoms, each optionally containing a fluorine atom, a chlorine atom, a bromine atom, a hydroxy group, an amino group, or an alkoxy group having 1 to 10 carbon atoms; or is —NR^{8K}—C(═O)—R^{9K} or —NR^{8K}—C(═O)—O—R^{9K}, wherein R^{8K} is a hydrogen atom or an alkyl group having 1 to 6 carbon atoms and optionally containing a halogen atom, a hydroxy group, an alkoxy group having 1 to 6 carbon atoms, an acyl group having 2 to 6 carbon atoms, or an acyloxy group having 2 to 6 carbon atoms, and R^{9K} is an alkyl group having 1 to 16 carbon atoms, an alkenyl group having 2 to 16 carbon atoms, or an aryl group having 6 to 12 carbon atoms, each optionally containing a halogen atom, a hydroxy group, an alkoxy group having 1 to 6 carbon atoms, an acyl group having 2 to 6 carbon atoms, or an acyloxy group having 2 to 6 carbon atoms. The alkyl group, alkoxy group, alkoxycarbonyl group, acyloxy group, acyl group, and alkenyl group may be linear, branched, or cyclic.

Among these, R^{1K} is preferably a hydroxyl group, a fluorine atom, a chlorine atom, a bromine atom, a methyl group, a methoxy group, an ethoxy group or the like, more preferably a hydroxyl group or an ethoxy group.

In the above formula (A-1), rk is an integer of 0 to 2, qk is an integer of 1 to 5, and qk and rk are preferably an integer satisfying 1≤qk+rk≤5.

In the formula (A-1), R^{2K} is a single bond, an ether linkage, an ester linkage, or an alkylene group having 1 to 6 carbon atoms optionally containing an ether linkage or an ester linkage. The alkylene group may be linear, branched, or cyclic.

In the formula (A-1), LK is a divalent linking group. As the divalent linking group, a divalent linking group in L¹ of the formula (A1) can be suitably employed.

Rf^{1K} and Rf^{2K} are each independently a hydrogen atom, a fluorine atom, or a trifluoromethyl group, preferably both of Rf^{1K} and Rf² being fluorine atoms.

pk is an integer of 0 to 5.

Examples of the first organic acid anion represented by the formula (A-1) include, but are not limited to, those shown below.

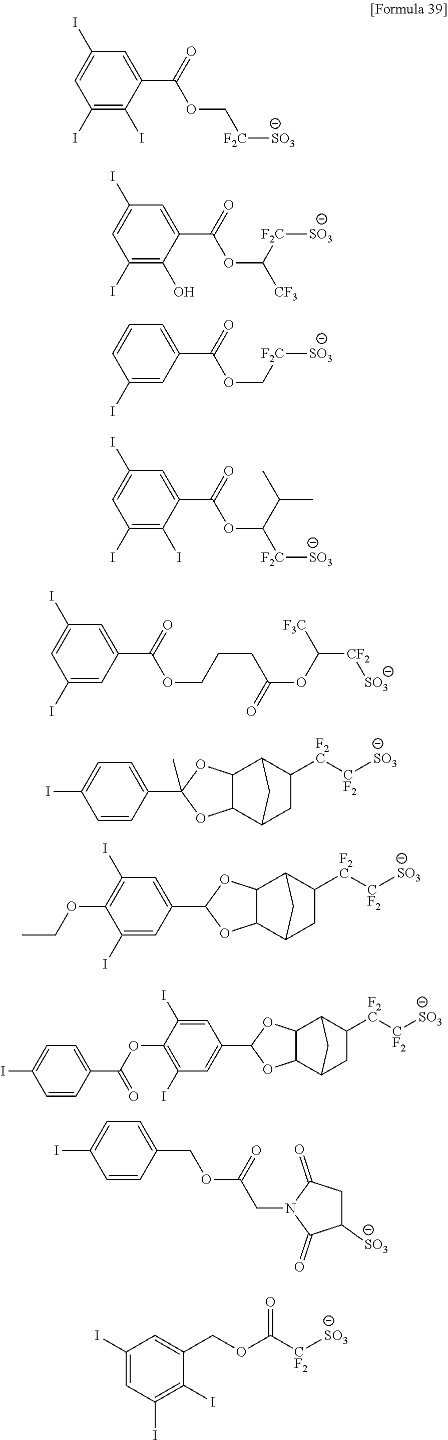

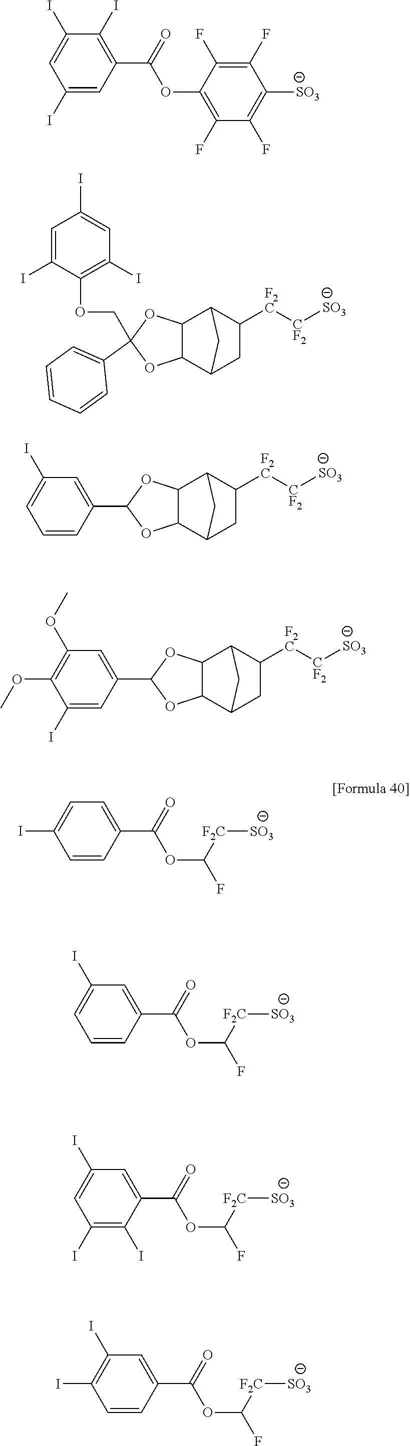

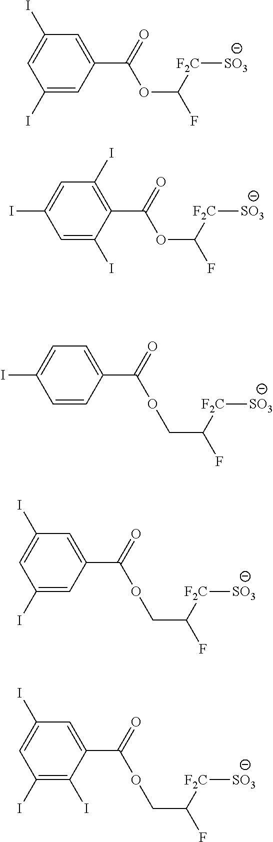

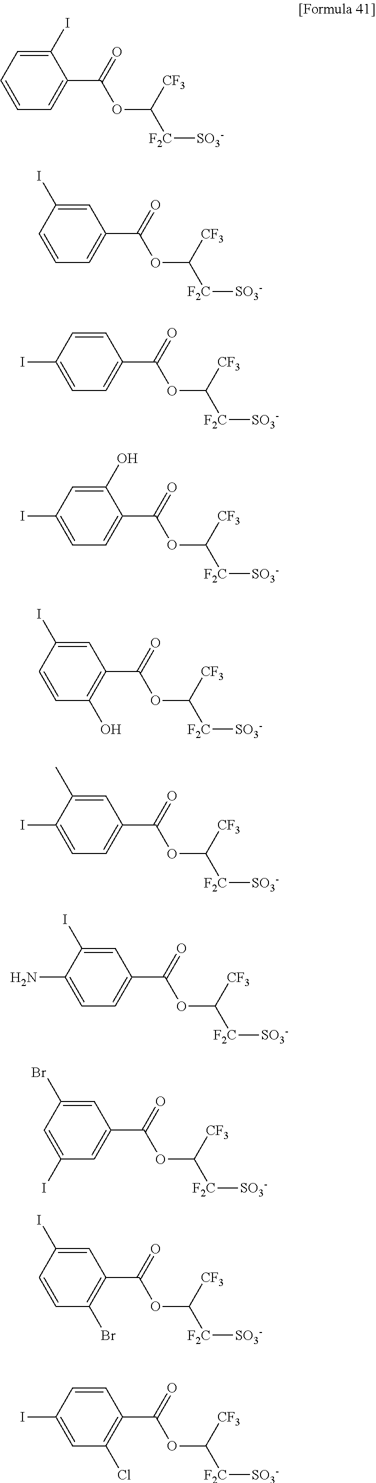

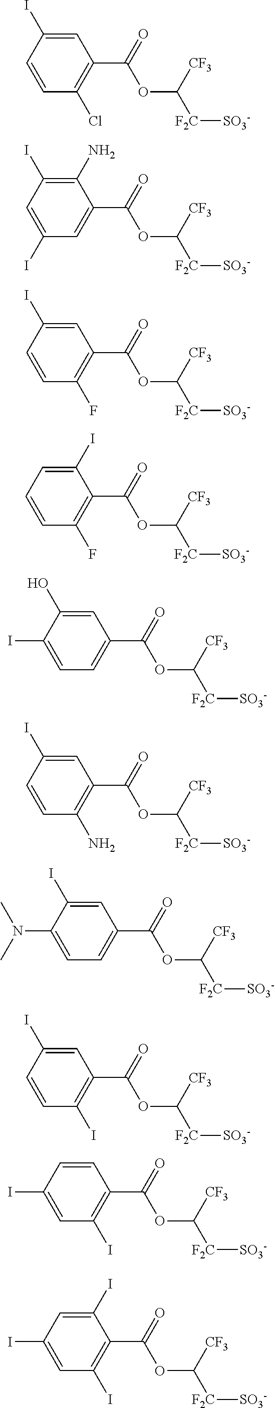

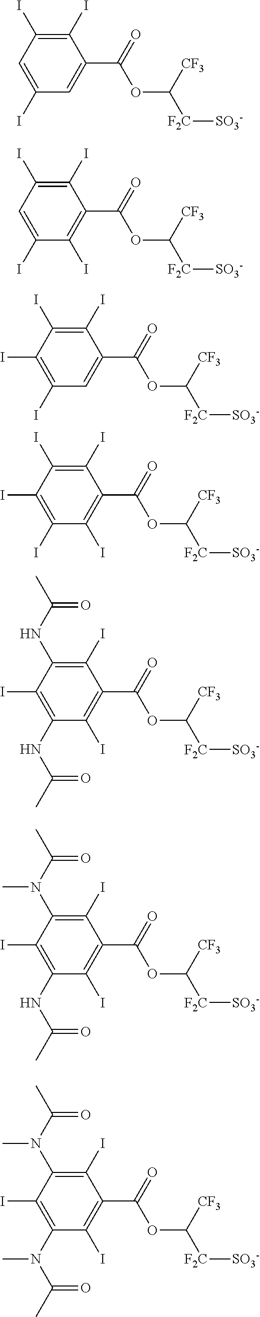

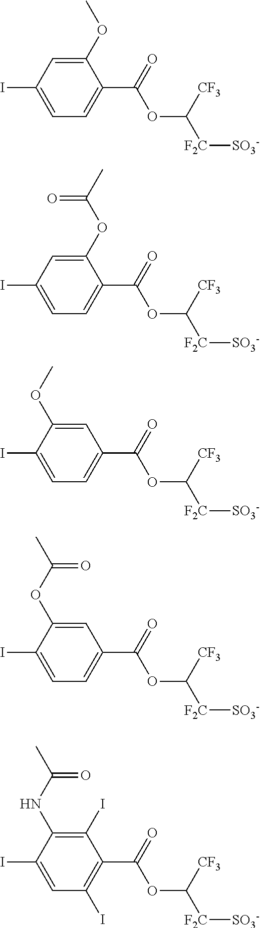

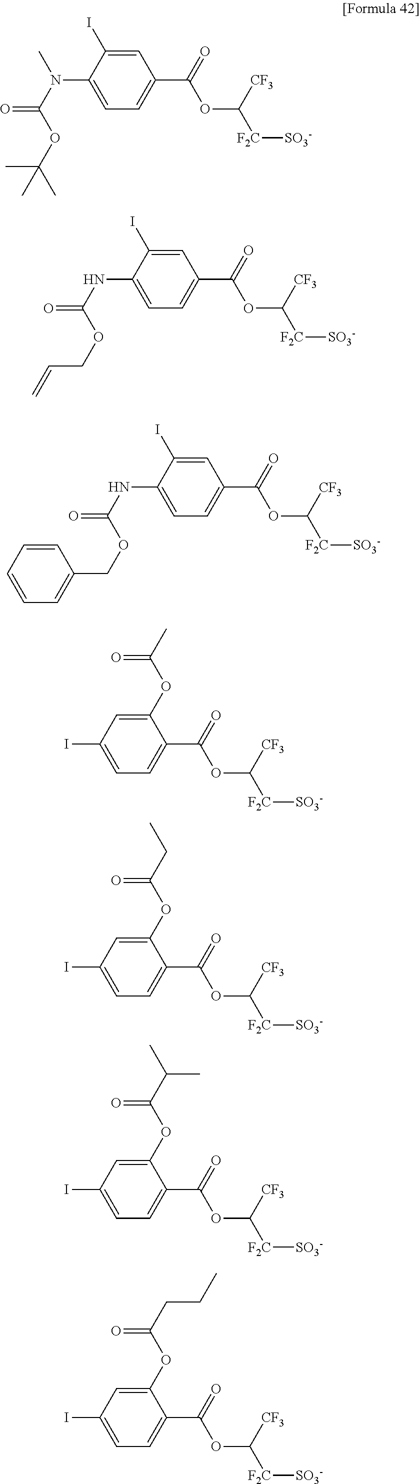

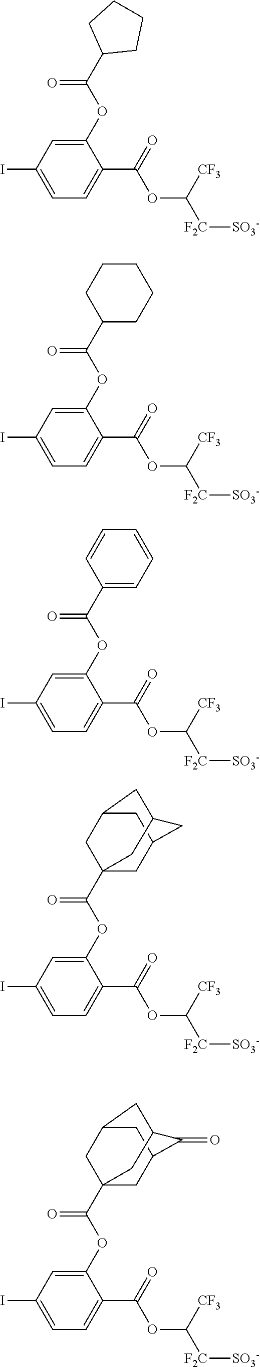

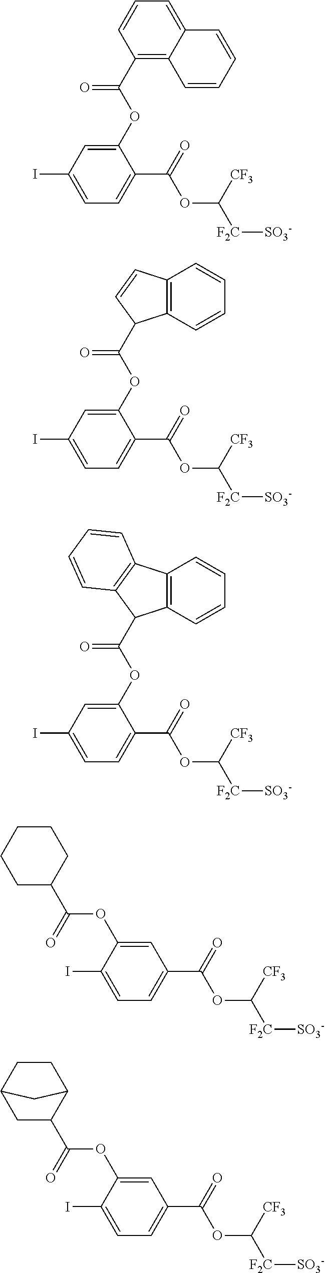

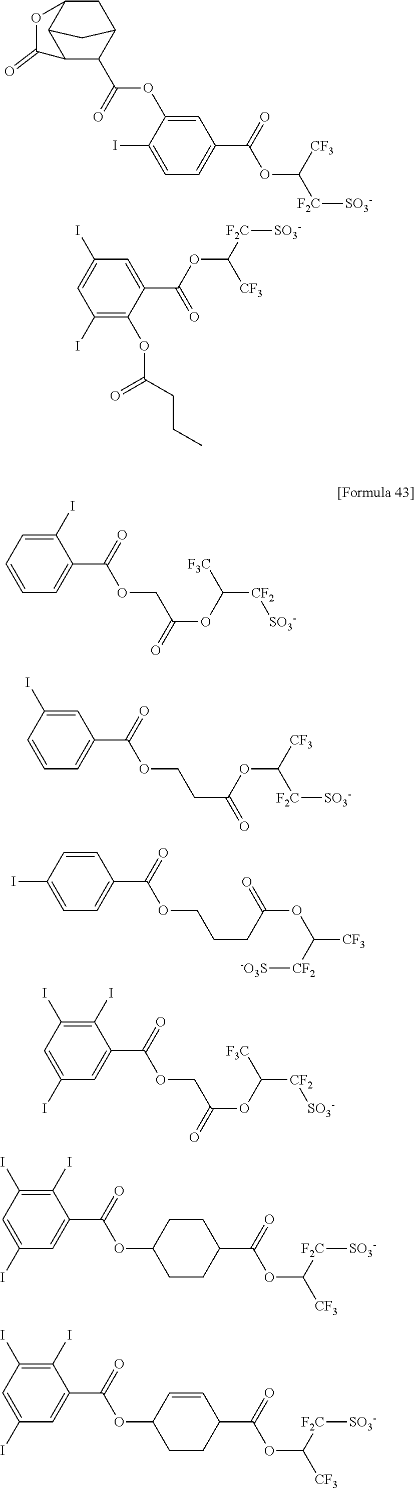

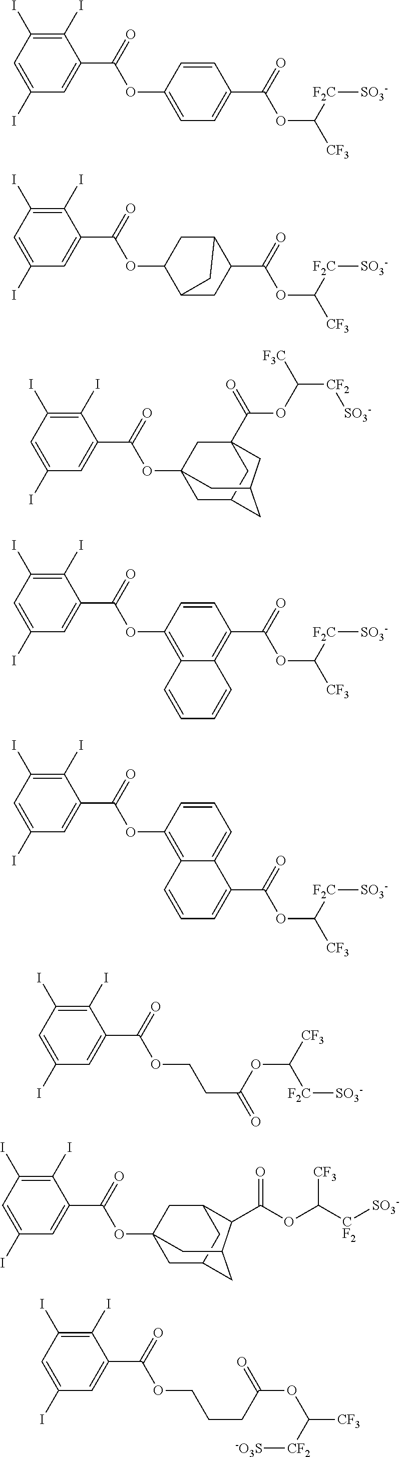

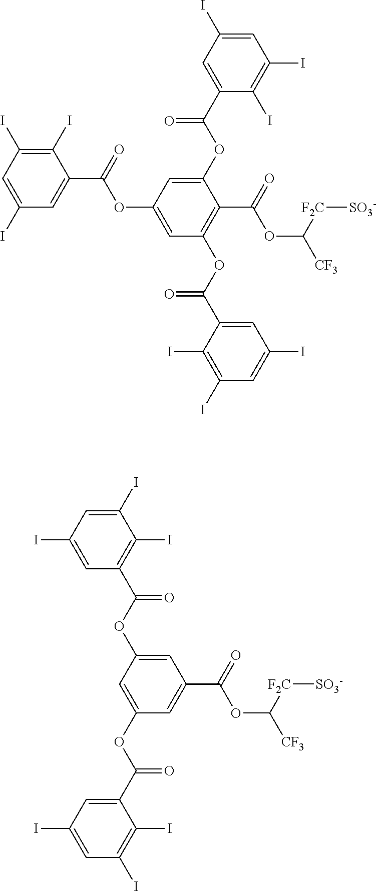

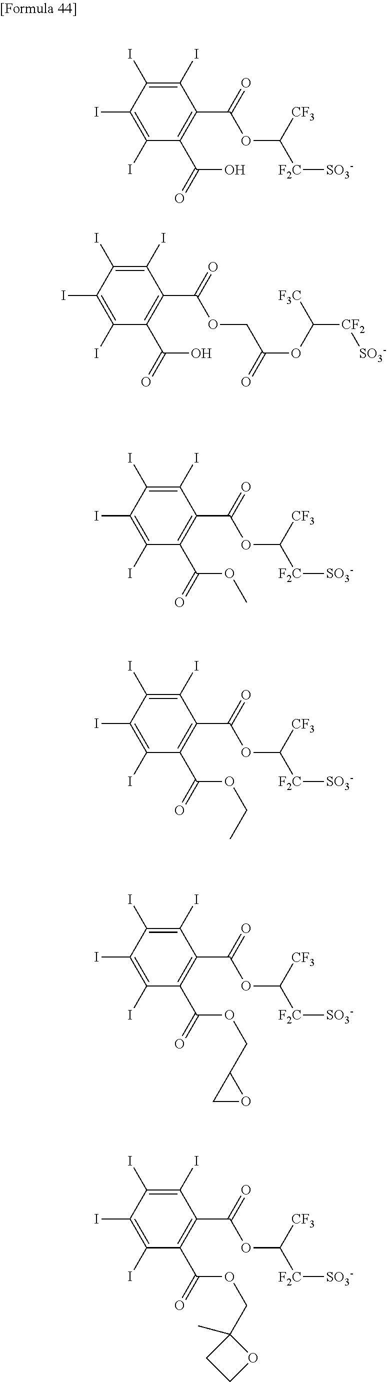

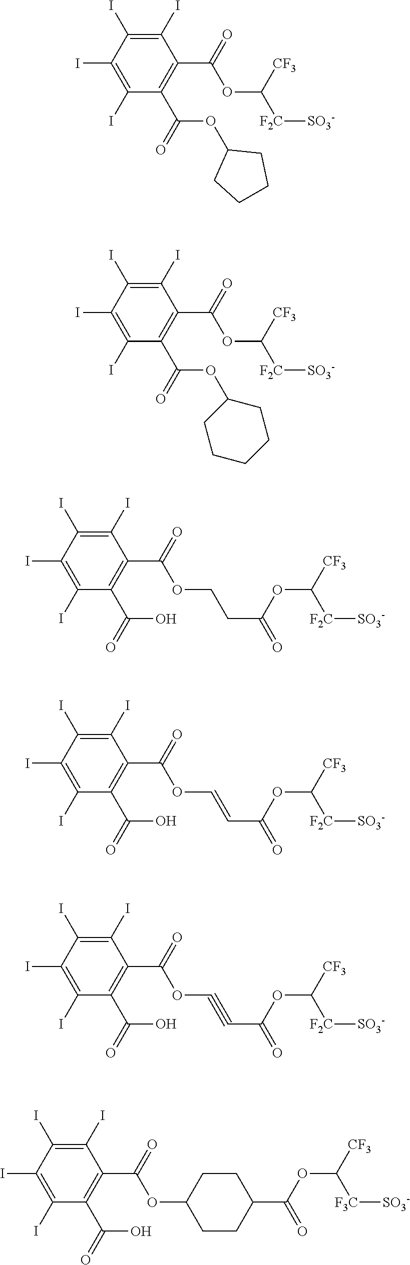

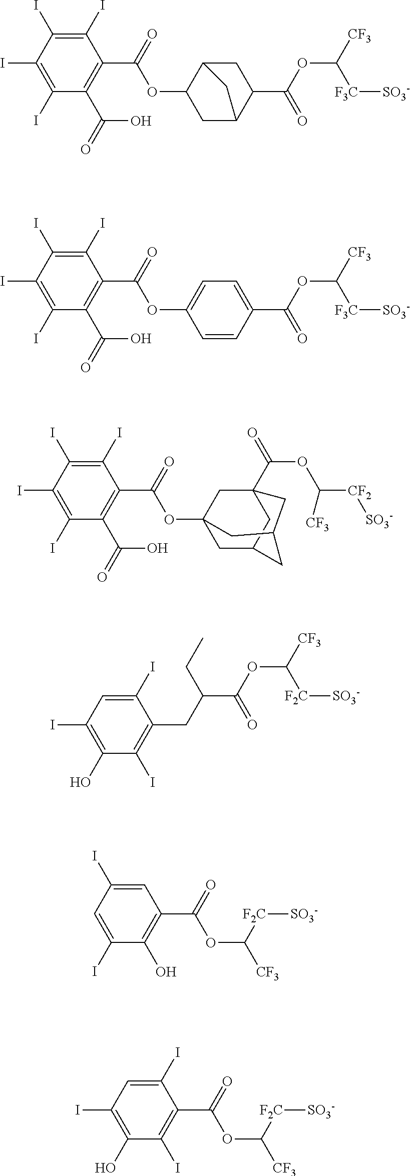

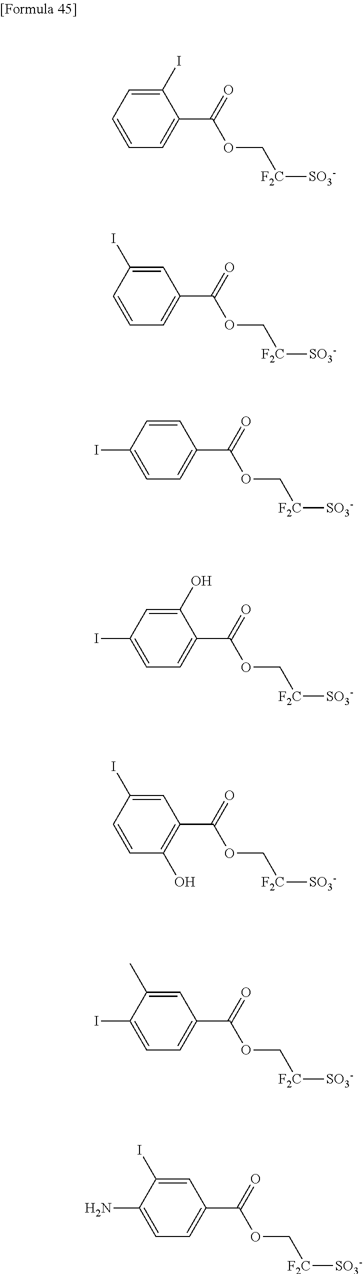

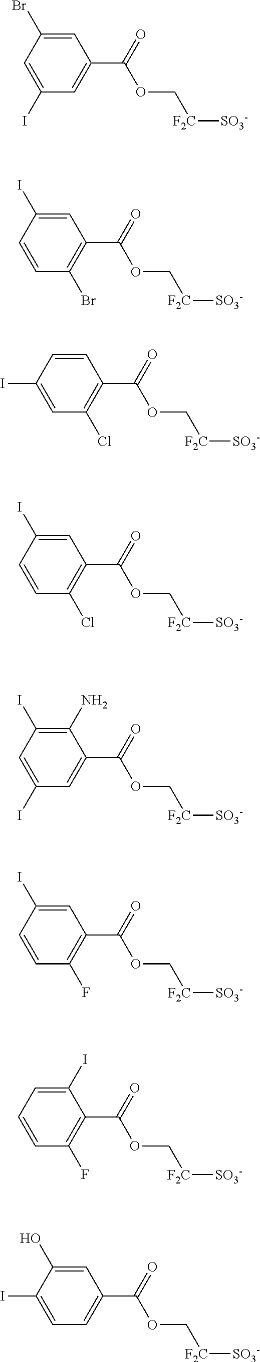

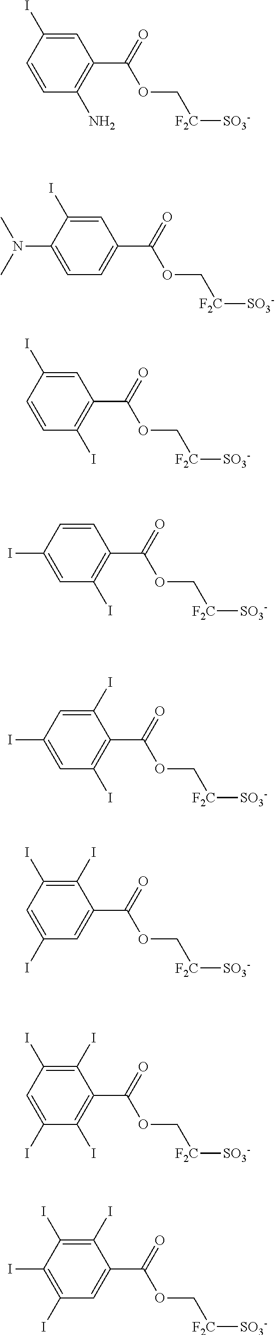

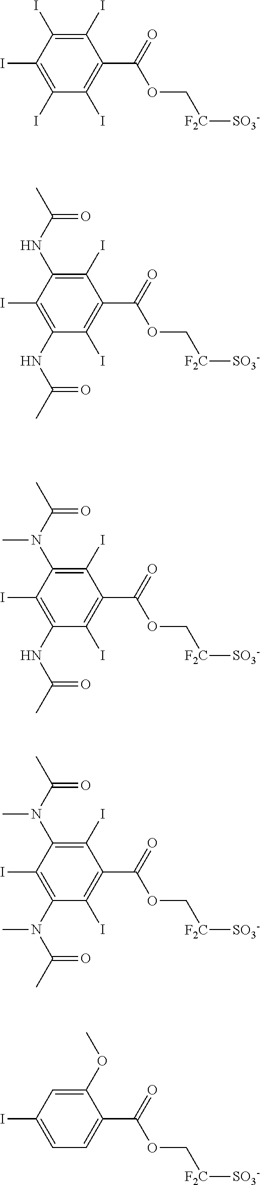

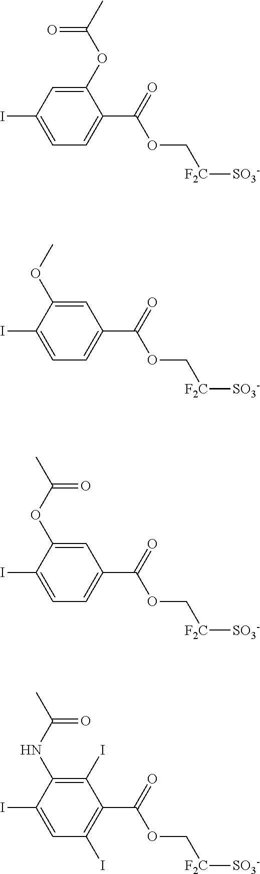

Any combination of the first organic acid anion and the first onium cation may be included in the radiation-sensitive acid generator (B). Among them, the following is preferable.

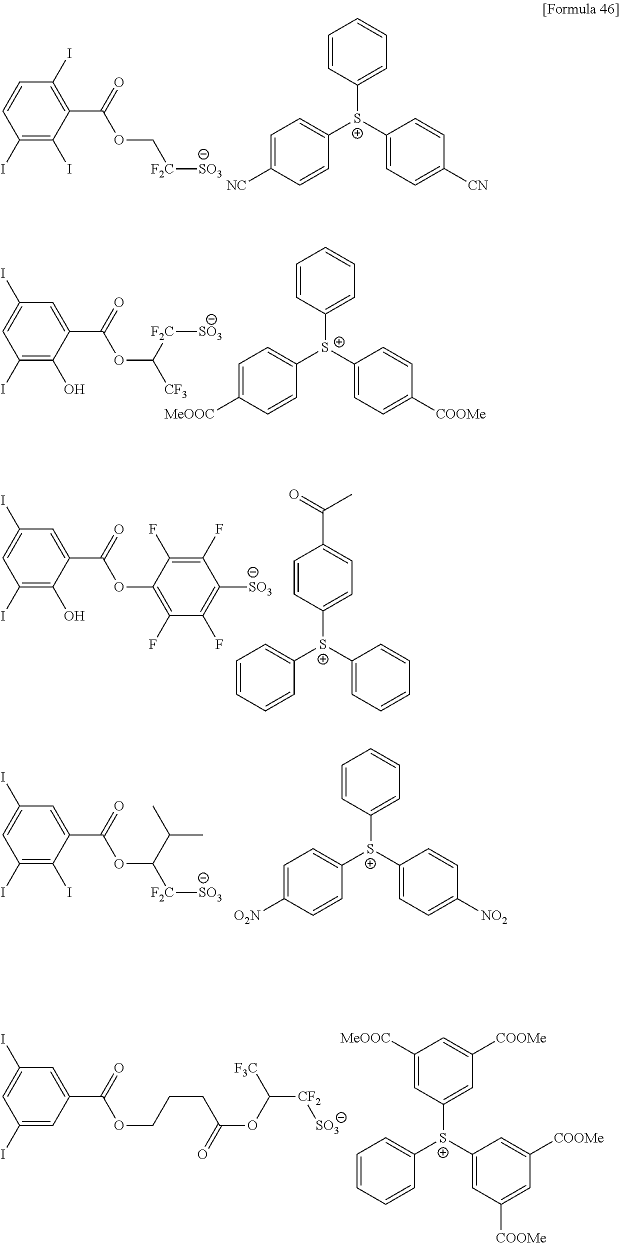

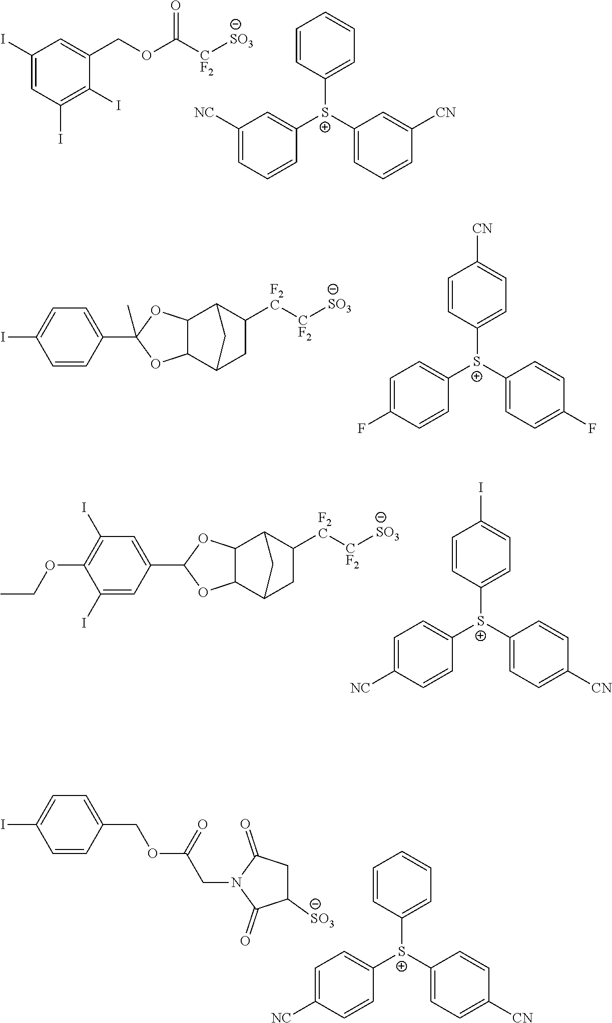

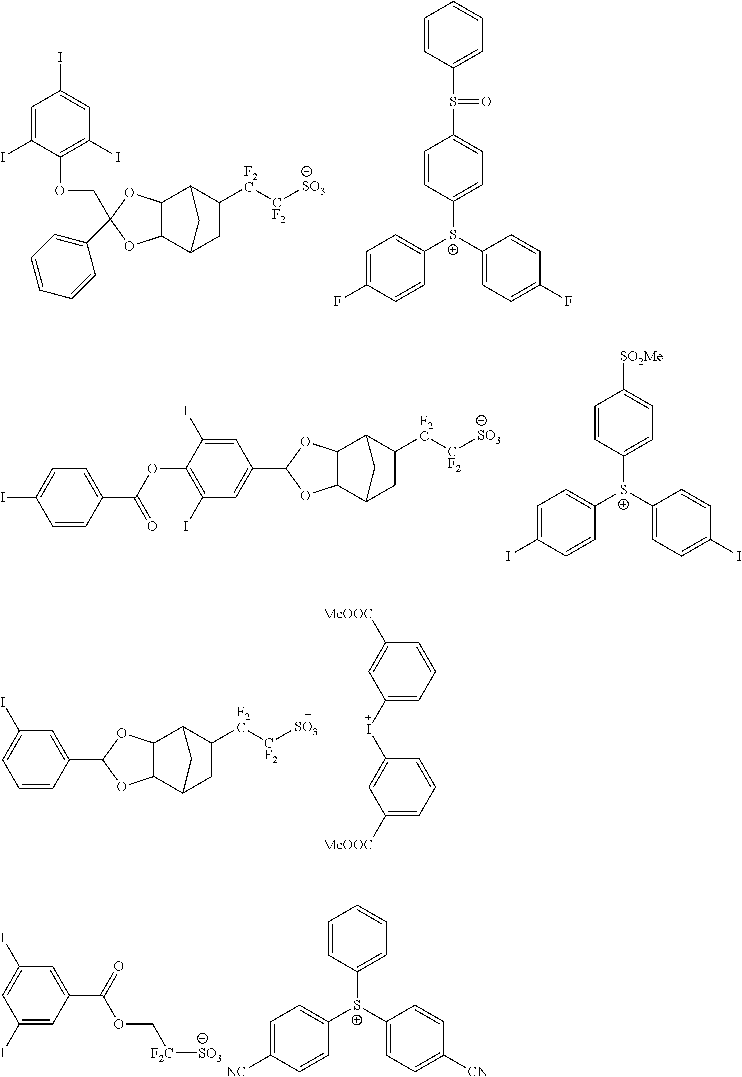

In the formula, Me represents a methyl group.

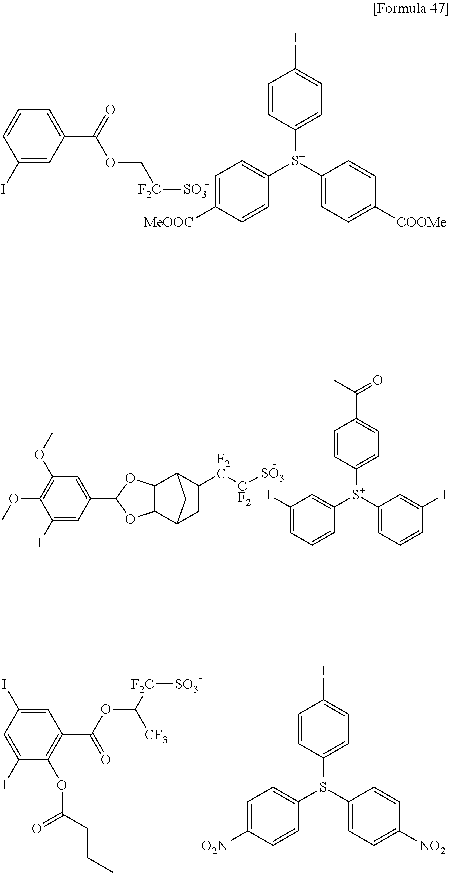

In the formula, Me represents a methyl group.

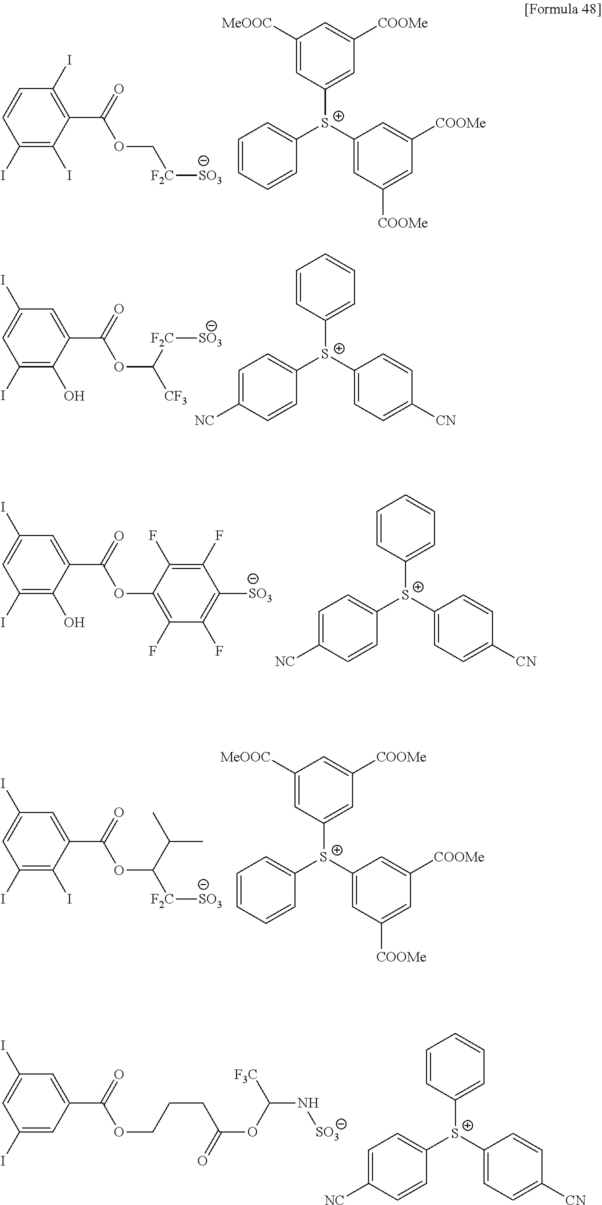

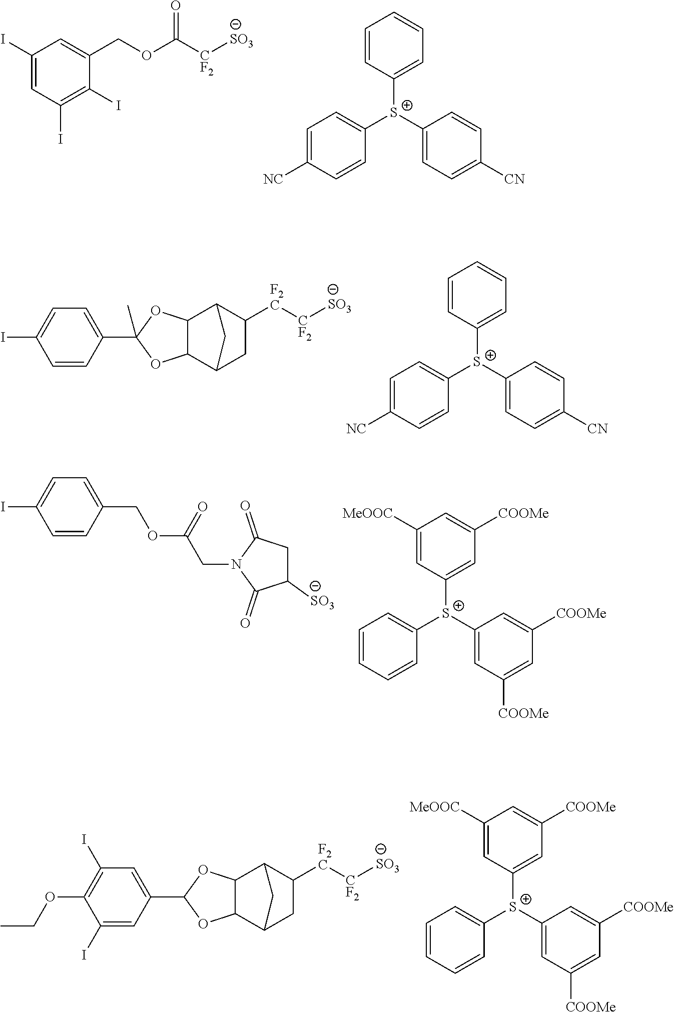

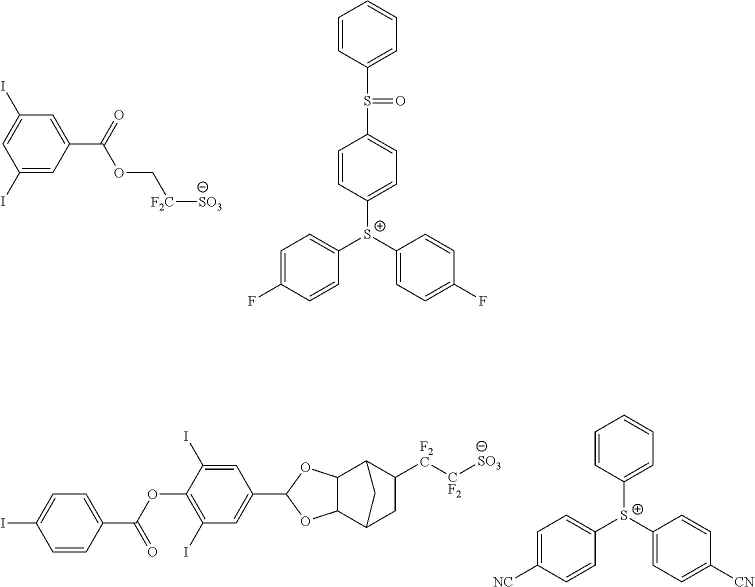

In the formula, Me represents a methyl group.

The radiation-sensitive acid generator (B) can also be synthesized by a known method, particularly by a salt exchange reaction. A known radiation-sensitive acid generator other than the radiation-sensitive acid generator (B) may also be used in combination, as long as the effect of the present invention is not impaired.

These radiation-sensitive acid generator (B) may be used singly, or two or more thereof may be used in combination. The lower limit of the content (when a plurality of types is contained, the total content thereof is taken) of the radiation-sensitive acid generator (B) is preferably 10 parts by mass, more preferably 20 parts by mass, and still more preferably 30 parts by mass based on 100 parts by mass of the polymer (A). The upper limit of the content is preferably 80 parts by mass, more preferably 75 parts by mass, and still more preferably 70 parts by mass based on 100 parts by mass of the polymer (A). This makes it possible to exhibit superior sensitivity or CDU when forming a resist pattern.

When the polymer (A) is the radiation-sensitive acid-generating polymer (A1), the radiation-sensitive composition may contain the radiation-sensitive acid generator (B).

### <Acid Diffusion Controlling Agent (D)>

The radiation-sensitive composition preferably contains an acid diffusion controlling agent (D) from the viewpoint of sensitivity and CDU. The acid diffusion controlling agent (D), which contains a third organic acid anion and a third onium cation, generates an acid having a pKa higher than that of the acid generated from the radiation-sensitive acid generator (B) or the radiation-sensitive acid-generating polymer (A1) through irradiation with radiation. The acid diffusion controlling agent (D) containing the third organic acid anion and the third onium cation is preferably represented by the following formula (8-1) to the following formula (8-4).

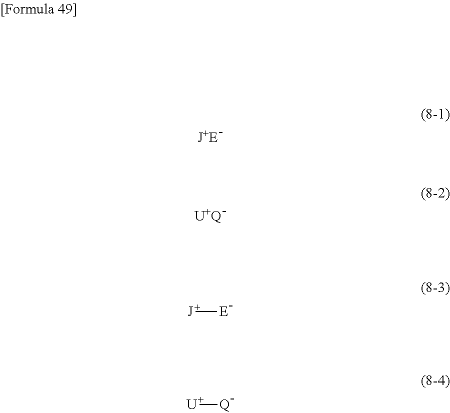

In the formulas (8-1) and (8-2), J⁺ is a sulfonium cation, and U⁺ is an iodonium cation. E⁻ and Q⁻ are each independently preferably at least one selected from the group consisting of R⁸SO₃⁻, R₈COO⁻, and (R₈SO₂)N⁻, more preferably R⁸COO⁻. In addition, a compound represented by the formula (8-3) containing a sulfonium cation and an anion in the same molecule and a compound represented by the formula (8-4) containing an iodonium cation and an anion in the same molecule are also included. The R⁸ is a monovalent organic group in the case of the formulas (8-1) and (8-2), and is a single bond or a divalent organic group in the case of the formulas (8-3) and (8-4).

The third organic acid anion is preferably an organic acid anion containing an iodine atom, and more preferably an organic acid anion having an iodine-substituted aromatic ring structure from the viewpoint of sensitivity.

Examples of the third organic acid anion include an anion represented by the following formulas. Among those shown below, as the structure having an iodine-substituted aromatic ring structure, a structure in which the iodine atom in the following formulas is substituted by an atom or a group other than an iodine atom such as a hydrogen atom or another substituent can also be suitably employed.

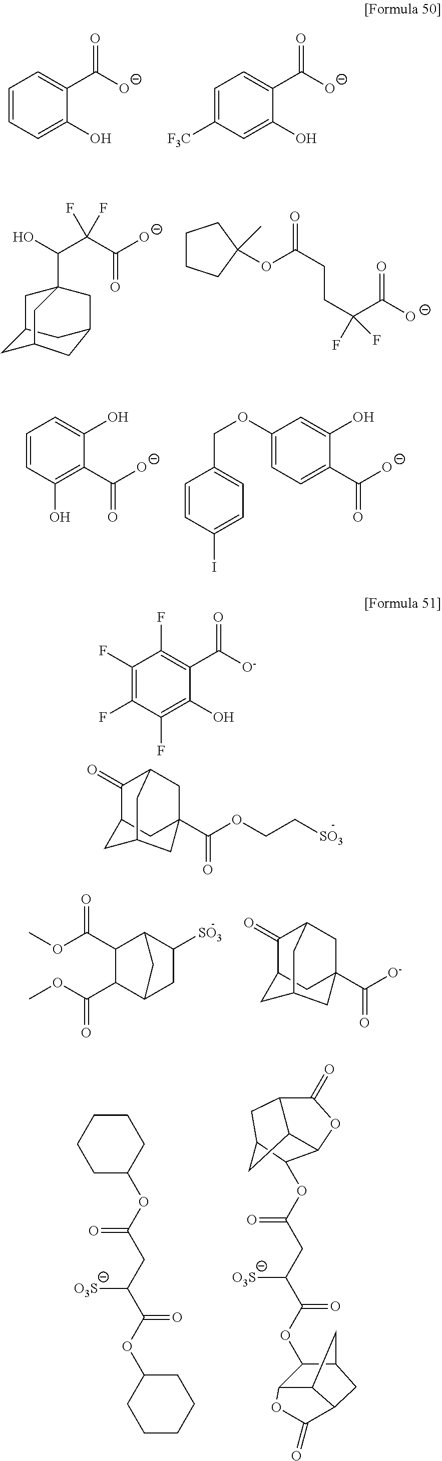

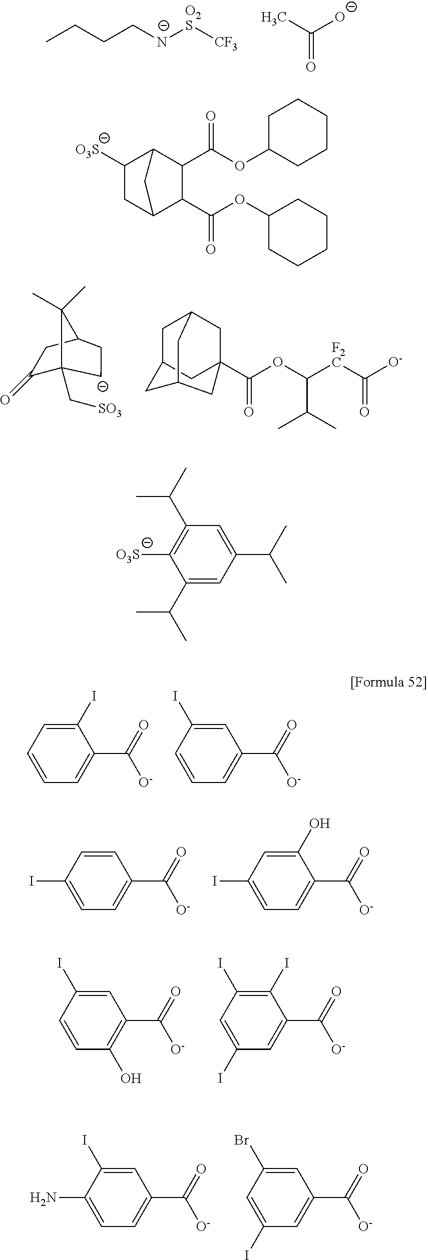

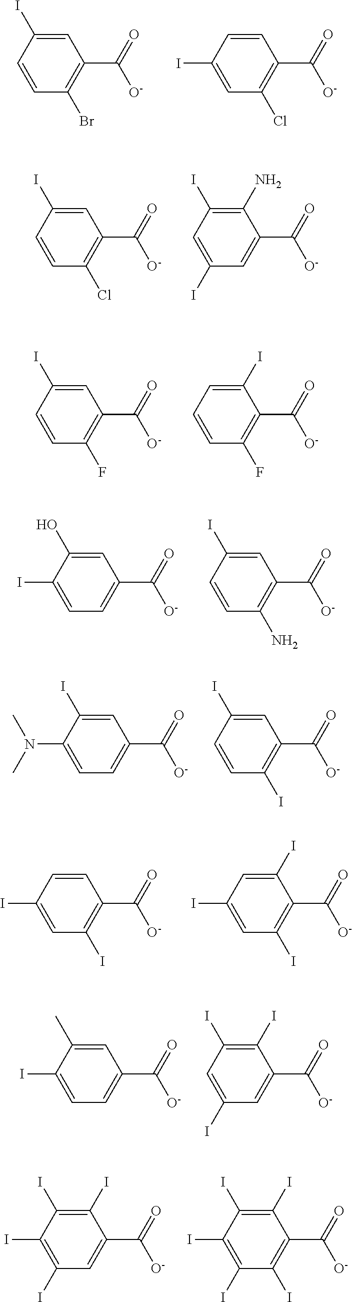

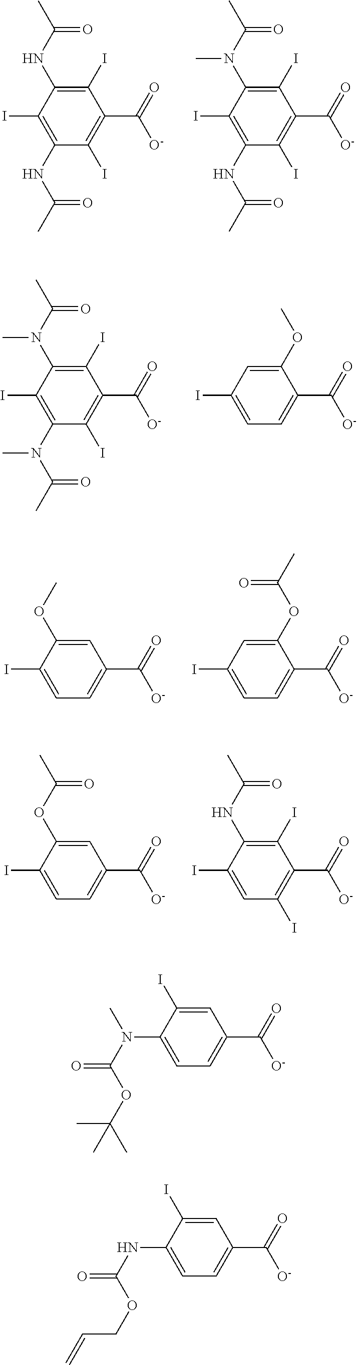

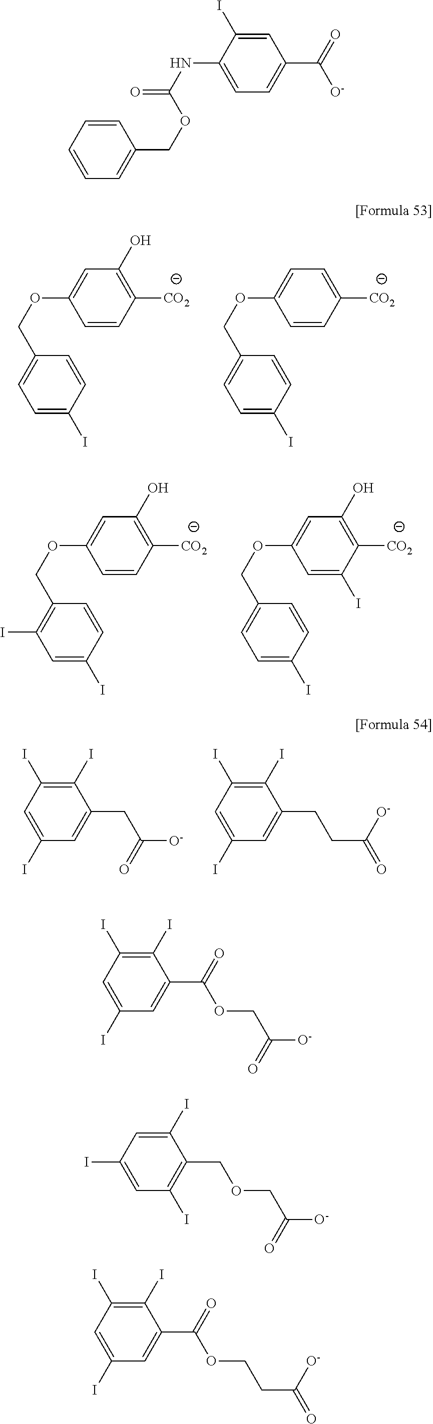

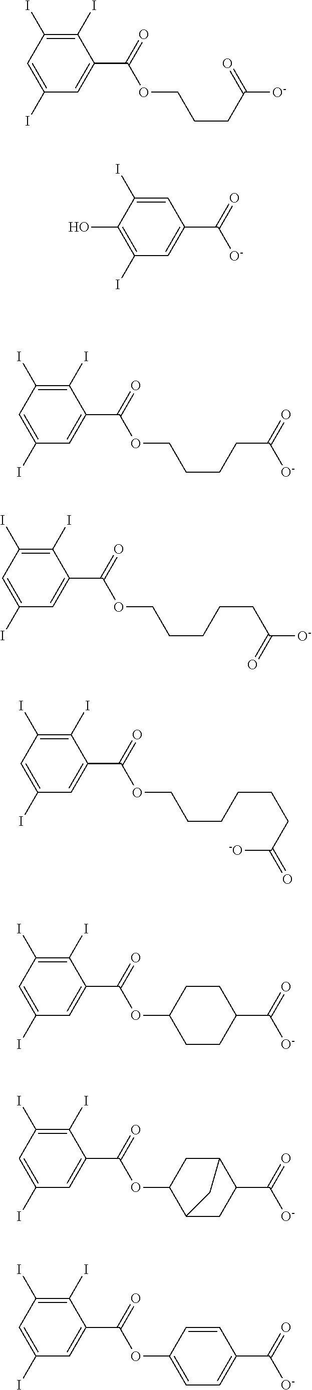

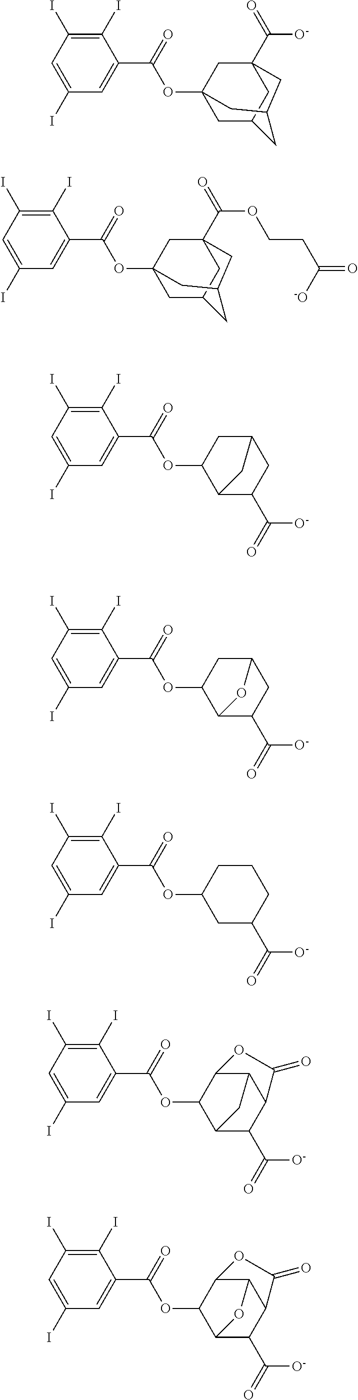

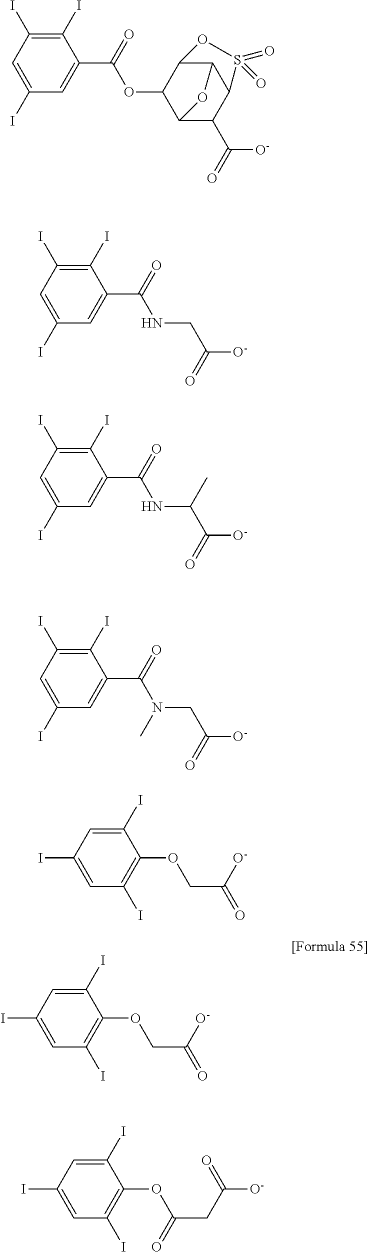

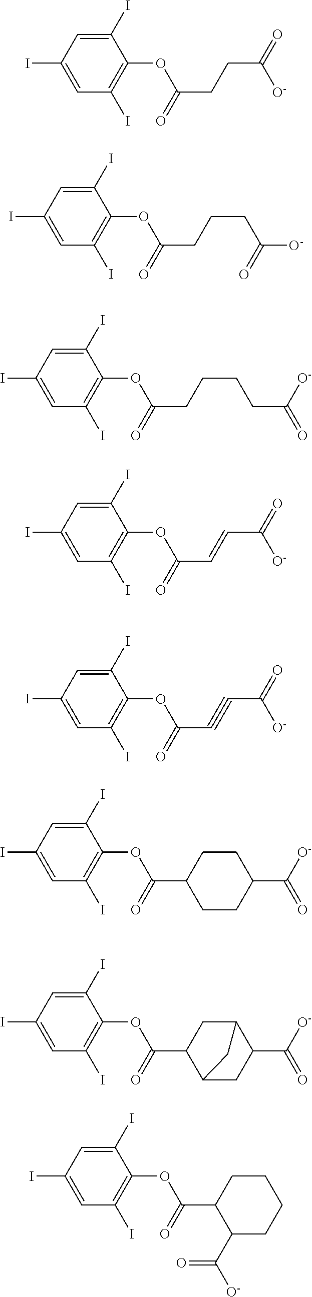

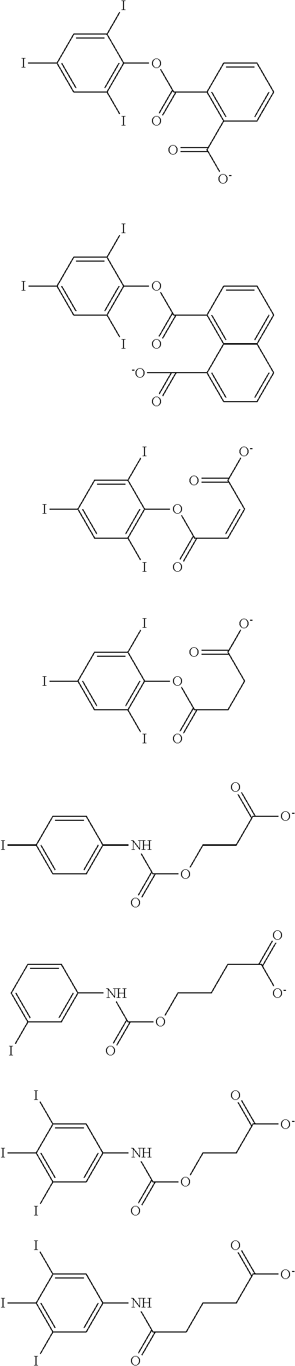

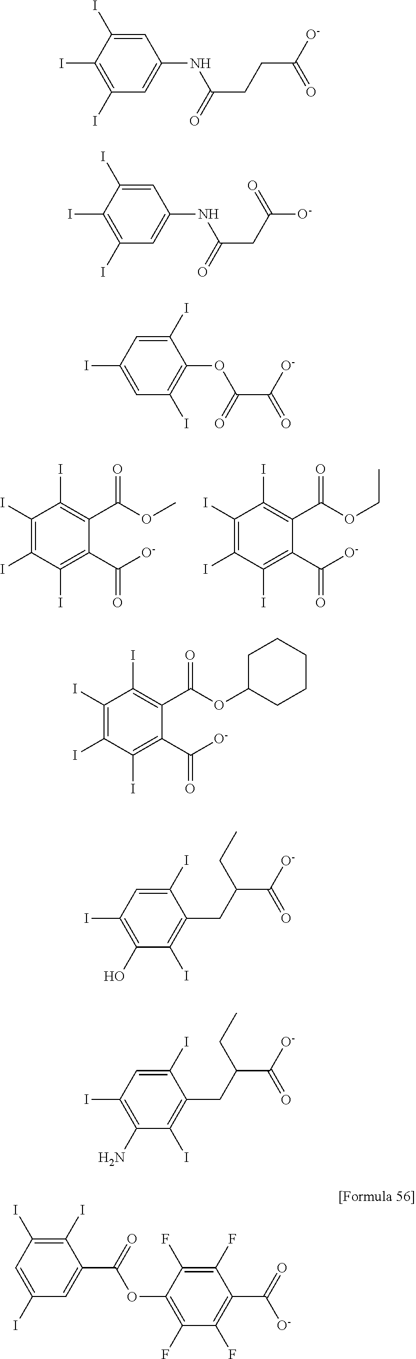

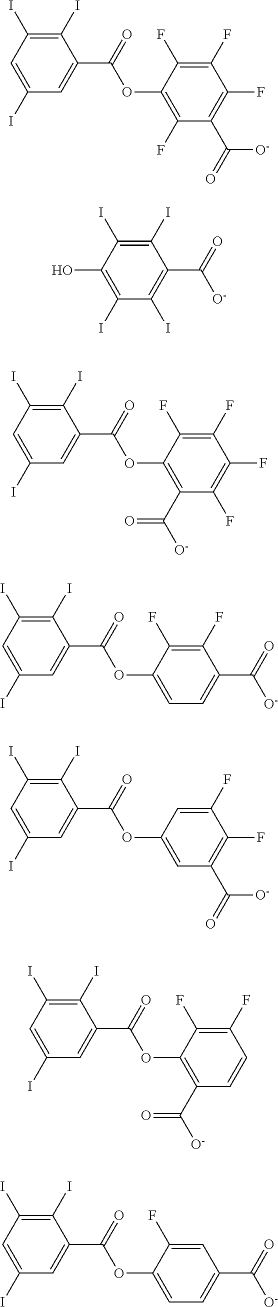

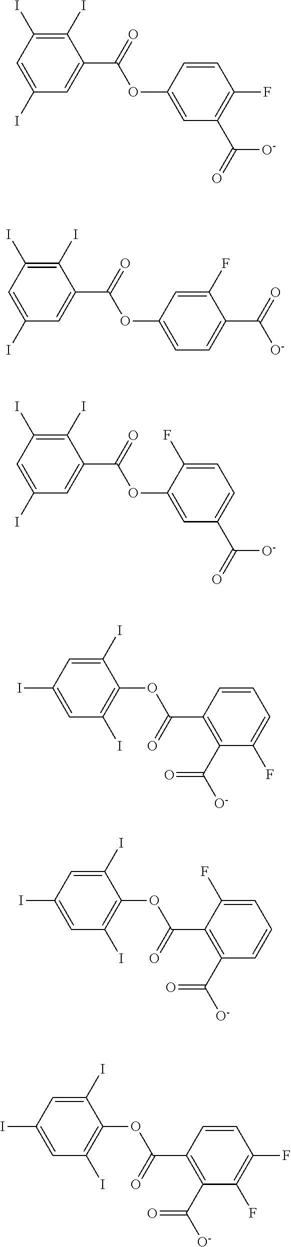 [SMILES: O=C([O-])c1cc(OC(=O)c2cc(I)cc(I)c2I)ccc1F ; O=C([O-])c1ccc(OC(=O)c2cc(I)cc(I)c2I)cc1F ; O=C([O-])c1ccc(F)c(OC(=O)c2cc(I)cc(I)c2I)c1 ; O=C(Oc1c(I)cc(I)cc1I)c1cccc(F)c1C(=O)[O-] ; O=C([O-])c1cccc(F)c1C(=O)Oc1c(I)cc(I)cc1I ; O=C(Oc1c(I)cc(I)cc1I)c1ccc(F)c(F)c1C(=O)[O-]]

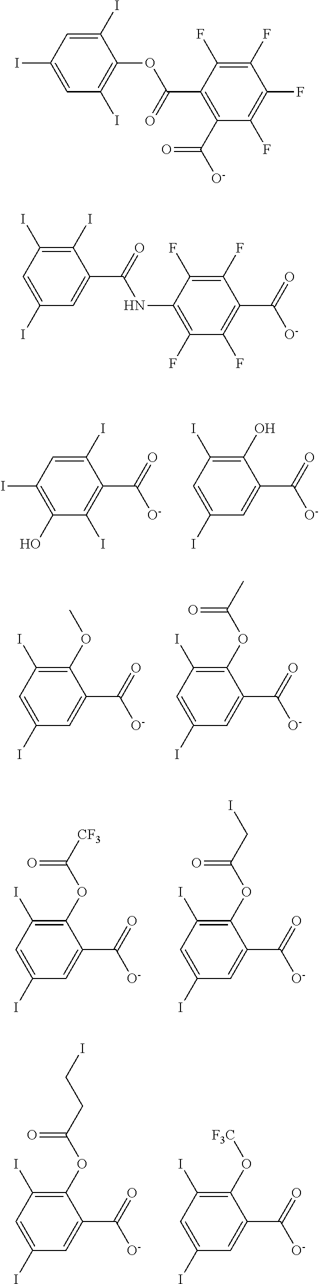

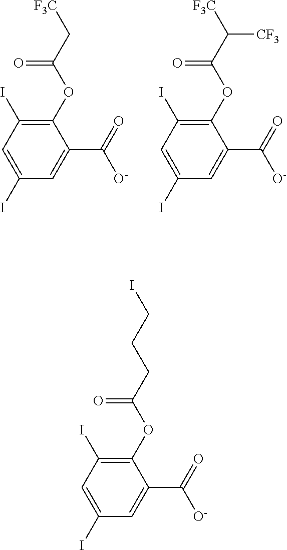 [SMILES: O=C(CC(F)(F)F)Oc1c(I)cc(I)cc1C(=O)[O-] ; O=C([O-])c1cc(I)cc(I)c1OC(=O)C(C(F)(F)F)C(F)(F)F ; O=C(CCCI)Oc1c(I)cc(I)cc1C(=O)[O-]]

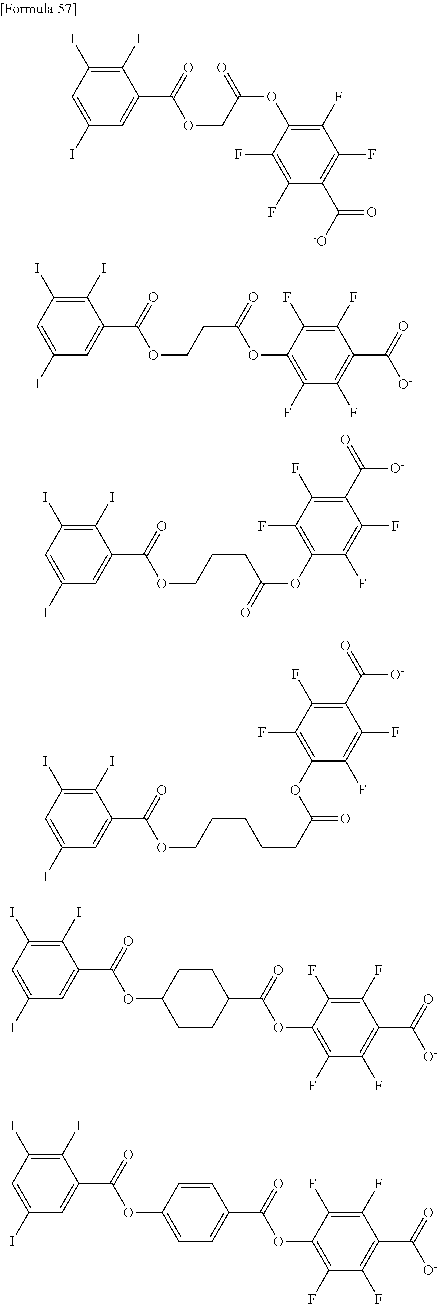

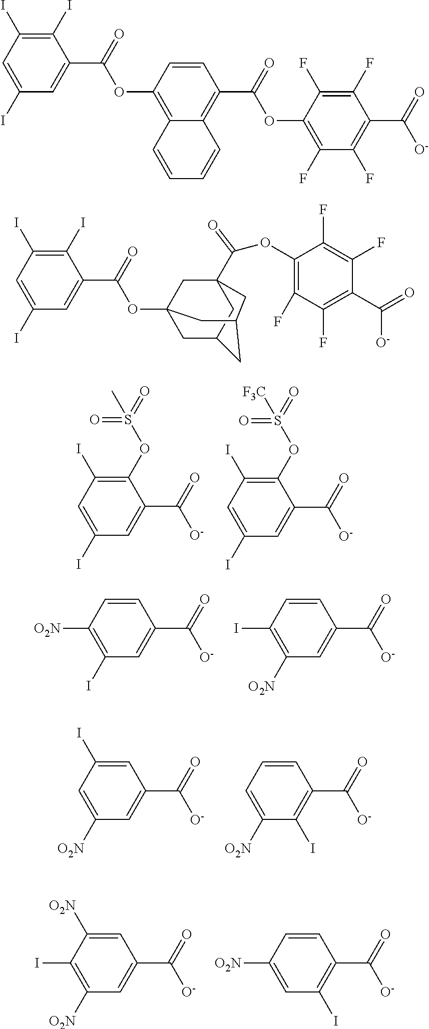

Examples of the sulfonium cation of J⁺ may include an onium cation represented by the formula (1) or the formula (2) of the radiation-sensitive acid generator (B) and a cation not containing a halogen-free electron withdrawing group obtained by removing a halogen-free electron withdrawing group from the cation represented by the formula (1) or the formula (2). That is, a cation in which p1, p2, and p3 in the formula (1) are each independently an integer of 0 to 3 and p1+p2+p3 is 0 or more, and a cation in which p4 and p5 in the formula (2) are each independently an integer of 0 to 3 and p4+p5 is 0 or more can be suitably used.

The third onium cation is preferably an onium cation represented by the formula (1) or the formula (2) from the viewpoint of suppressing development defects.

Specific examples of the third onium cation include the following. The fluorine atom, the iodine atom, and the fluorine atom-containing group in the onium cation described below may be substituted with a hydrogen atom or another substituent.

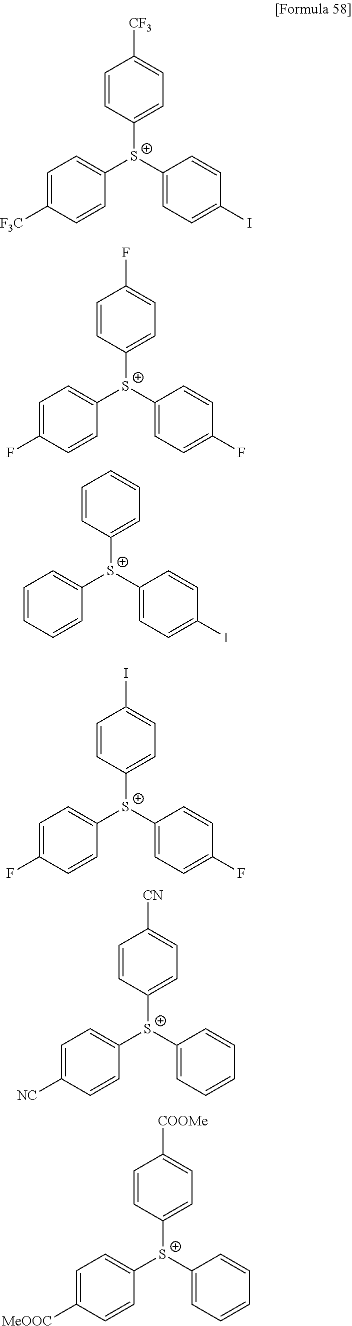

In the formula, Me represents a methyl group.

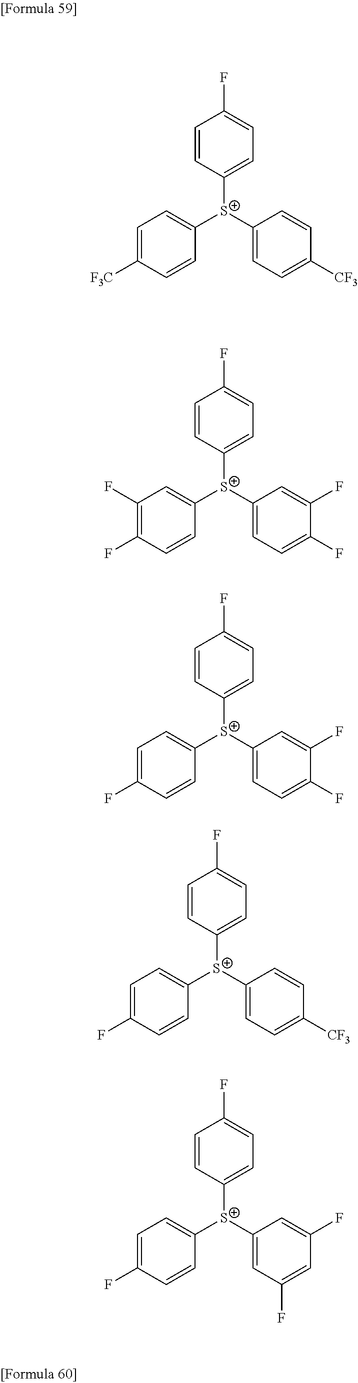 [SMILES: Fc1ccc([S+](c2ccc(C(F)(F)F)cc2)c2ccc(C(F)(F)F)cc2)cc1 ; Fc1ccc([S+](c2ccc(F)c(F)c2)c2ccc(F)c(F)c2)cc1 ; Fc1ccc([S+](c2ccc(F)cc2)c2ccc(F)c(F)c2)cc1 ; Fc1ccc([S+](c2ccc(F)cc2)c2ccc(C(F)(F)F)cc2)cc1 ; Fc1ccc([S+](c2ccc(F)cc2)c2cc(F)cc(F)c2)cc1]

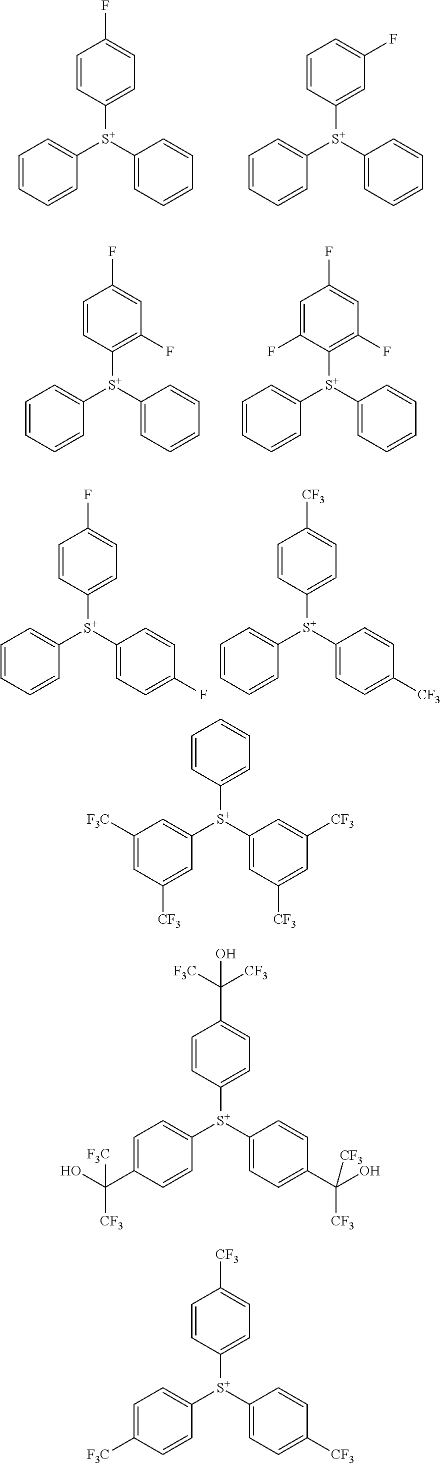

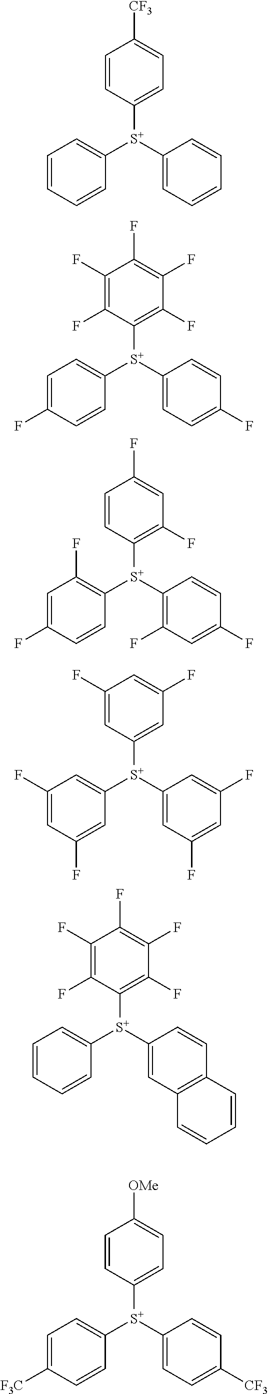 [SMILES: FC(F)(F)c1ccc([S+](c2ccccc2)c2ccccc2)cc1 ; Fc1ccc([S+](c2ccc(F)cc2)c2c(F)c(F)c(F)c(F)c2F)cc1 ; Fc1ccc([S+](c2ccc(F)cc2F)c2ccc(F)cc2F)c(F)c1 ; Fc1cc(F)cc([S+](c2cc(F)cc(F)c2)c2cc(F)cc(F)c2)c1 ; Fc1c(F)c(F)c([S+](c2ccccc2)c2ccc3ccccc3c2)c(F)c1F ; COc1ccc([S+](c2ccc(C(F)(F)F)cc2)c2ccc(C(F)(F)F)cc2)cc1]

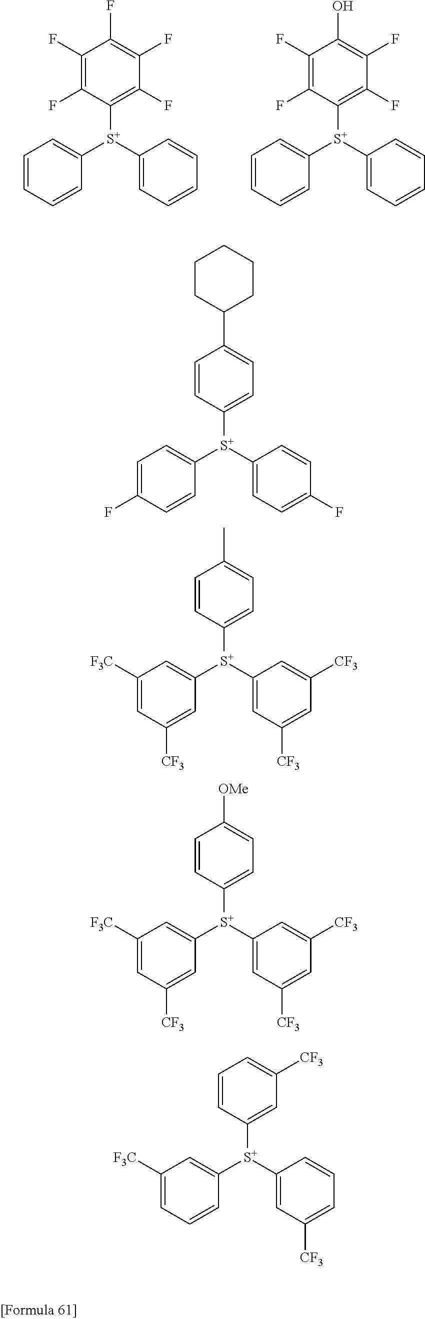 [SMILES: Fc1c(F)c(F)c([S+](c2ccccc2)c2ccccc2)c(F)c1F ; Oc1c(F)c(F)c([S+](c2ccccc2)c2ccccc2)c(F)c1F ; Fc1ccc([S+](c2ccc(F)cc2)c2ccc(C3CCCCC3)cc2)cc1 ; Cc1ccc([S+](c2cc(C(F)(F)F)cc(C(F)(F)F)c2)c2cc(C(F)(F)F)cc(C(F)(F)F)c2)cc1 ; COc1ccc([S+](c2cc(C(F)(F)F)cc(C(F)(F)F)c2)c2cc(C(F)(F)F)cc(C(F)(F)F)c2)cc1 ; FC(F)(F)c1cccc([S+](c2cccc(C(F)(F)F)c2)c2cccc(C(F)(F)F)c2)c1]

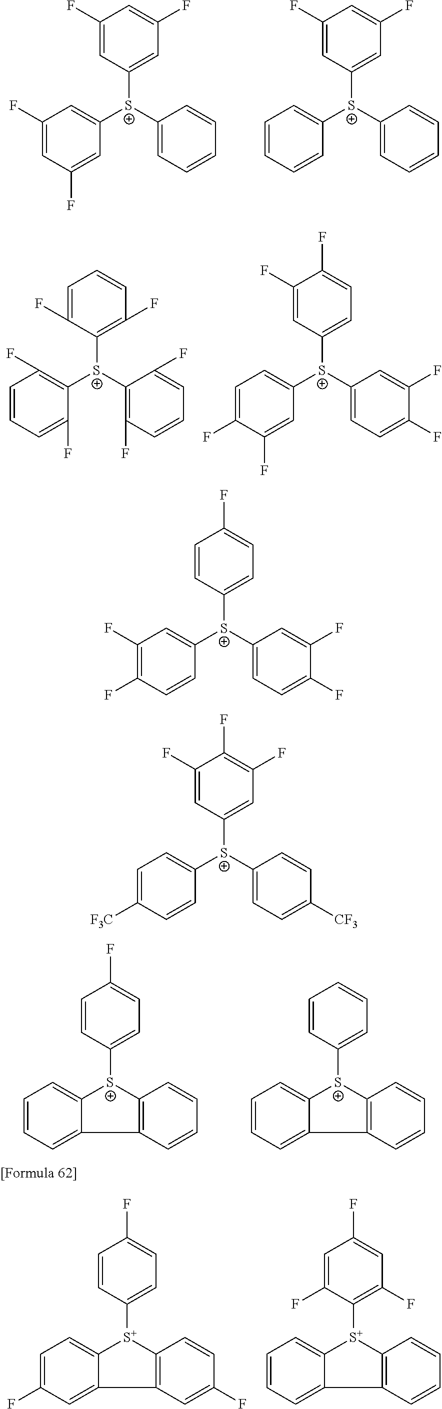

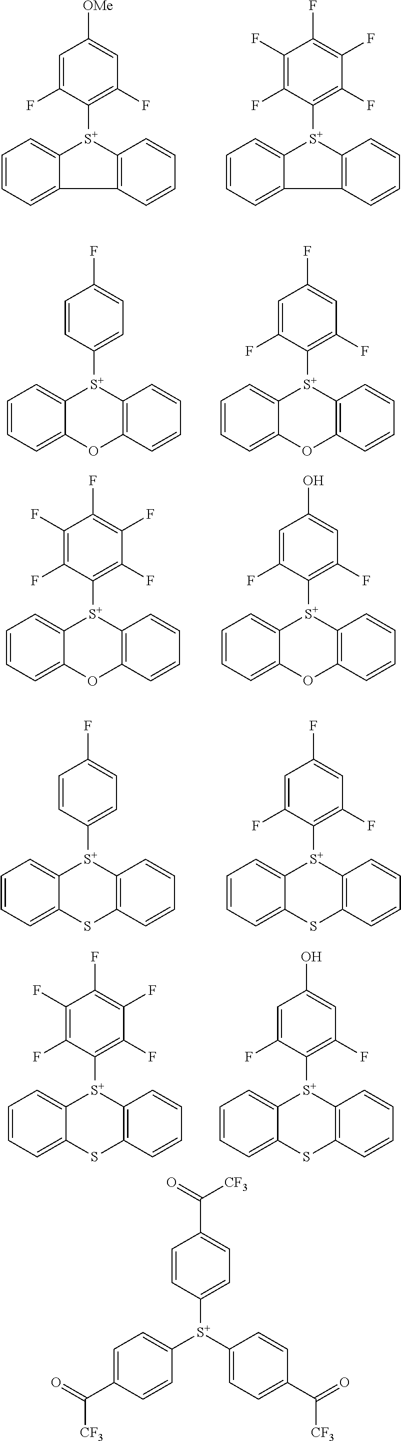

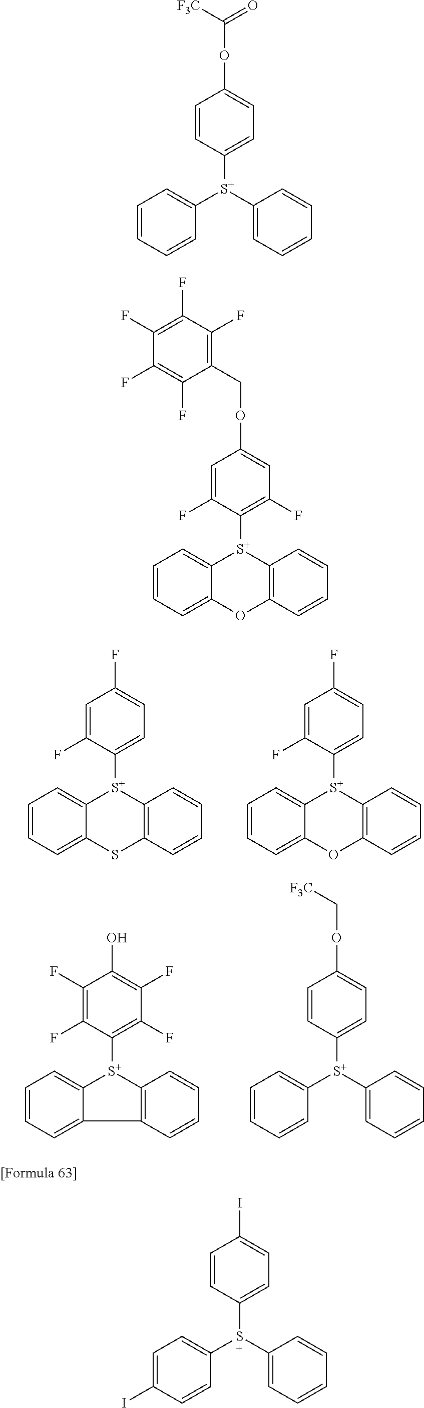

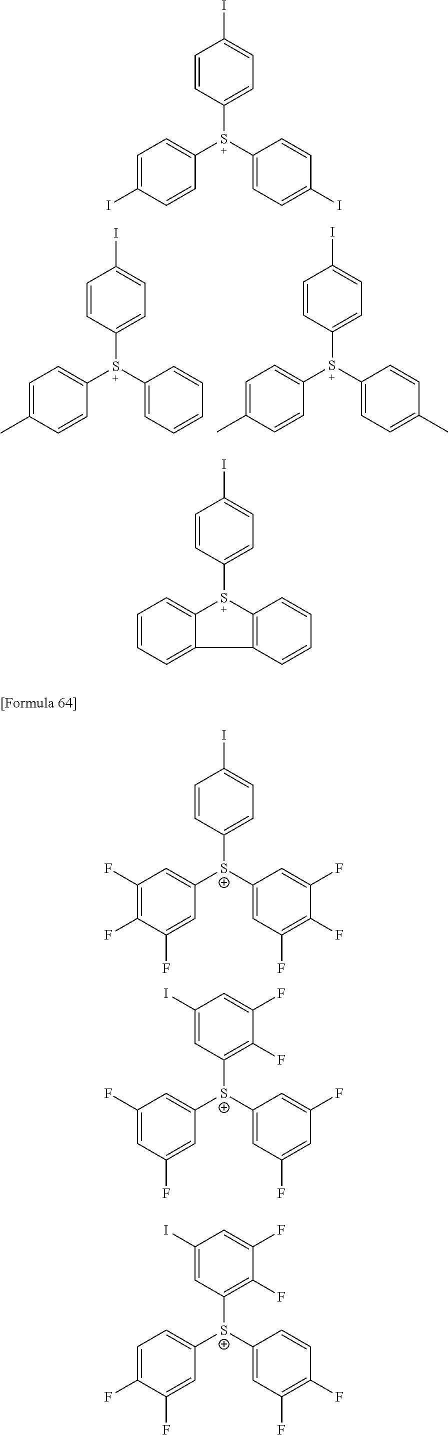

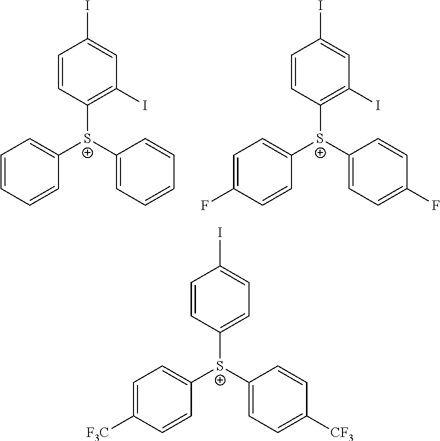 [SMILES: Ic1ccc([S+](c2ccccc2)c2ccccc2)c(I)c1 ; Fc1ccc([S+](c2ccc(F)cc2)c2ccc(I)cc2I)cc1 ; FC(F)(F)c1ccc([S+](c2ccc(I)cc2)c2ccc(C(F)(F)F)cc2)cc1]

Examples of the iodonium cation of U⁺ may include a diaryliodonium cation having one or more fluorine atoms.

The acid diffusion controlling agent (D) can be synthesized by a known method, particularly by a salt exchange reaction. A known acid diffusion controlling agent other than those described above may be used as long as the effect of the present invention is not impaired.

These acid diffusion controlling agent (D) may be used singly, or two or more thereof may be used in combination. The lower limit of the content of the acid diffusion controlling agent (when a plurality of types is contained, the total content thereof is taken) is preferably 15 mol %, more preferably 20 mol %, and still more preferably 25 mol % based on the radiation-sensitive acid generator (B) or the radiation-sensitive acid-generating polymer (A1) (when both are contained, the total content thereof is taken). The upper limit of the content is preferably 100 mol %, more preferably 90 mol %, and still more preferably 80 mol %. This makes it possible to exhibit superior sensitivity or CDU when forming a resist pattern.

### <Other Polymers>

The radiation-sensitive composition according to the present embodiment may contain, as another polymer, a polymer having higher content by mass of fluorine atoms than the above-described base polymer (hereinafter, also referred to as a “high fluorine-content polymer”). When the radiation-sensitive composition includes the high fluorine-content polymer, the high fluorine-content polymer can be localized in the surface layer of a resist film compared to the base polymer, and as a result, the state of the surface of the resist film and the component distribution in the resist film can be controlled to a desired state.

The high fluorine-content polymer preferably has a structural unit represented by the following formula (6) (hereinafter, also referred to as “structural unit (V)”). In addition, for example, the high fluorine-containing polymer may, as necessary, have at least one of the structural units (I) to (III) in the base polymer.

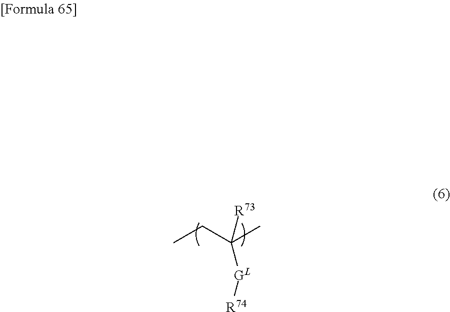

In the above formula (6), R⁷³ is a hydrogen atom, a methyl group, or a trifluoromethyl group. GL is a single bond, an oxygen atom, a sulfur atom, —COO—, —SO₂ONH—, —CONH—, or —OCONH—. R⁷⁴ is a monovalent fluorinated chain hydrocarbon group having 1 to 20 carbon atoms or a monovalent fluorinated alicyclic hydrocarbon group having 3 to 20 carbon atoms.

As R⁷³, a hydrogen atom and a methyl group are preferable from the viewpoint of the copolymerizability of a monomer that affords the structural unit (V), and a methyl group is more preferable.

As the GL, a single bond and —COO— are preferable from the viewpoint of the copolymerizability of a monomer that affords the structural unit (V), and —COO— is more preferable.

Examples of the monovalent fluorinated chain hydrocarbon group having 1 to 20 carbon atoms represented by R⁷⁴ may include monovalent fluorinated chain hydrocarbon groups in which some or all of the hydrogen atoms of a linear or branched chain alkyl group having 1 to 20 carbon atoms are replaced by fluorine atoms.

Examples of the monovalent fluorinated alicyclic hydrocarbon group having 3 to 20 carbon atoms represented by R⁷⁴ may include monovalent fluorinated alicyclic hydrocarbon groups in which some or all of the hydrogen atoms of a mono- or polycyclic hydrocarbon group having 3 to 20 carbon atoms are replaced by fluorine atoms.

As the R⁷⁴, fluorinated chain hydrocarbon groups are preferable, fluorinated alkyl groups are more preferable, and a 2,2,2-trifluoroethyl group, a 1,1,1,3,3,3-hexafluoropropyl group, a 5,5,5-trifluoro-1,1-diethylpentyl group, and a 1,1,1,2,2,3,3-heptafluoro-6-methylheptan-4-yl group are still more preferable.

When the high fluorine-content polymer has the structural unit (V), the lower limit of the content of the structural unit (V) is preferably 50 mol %, more preferably 60 mol %, and still more preferably 70 mol % based on the total amount of all structural units constituting the high fluorine-content polymer. The upper limit of the content is preferably 100 mol %, more preferably 95 mol %, and still more preferably 90 mol %. When the content of the structural unit (V) is adjusted to within the above range, the mass content of fluorine atoms in the high fluorine-content polymer can more appropriately be adjusted and the localization in the surface layer of a resist film can be further promoted.

The lower limit of the Mw of the high fluorine-content polymer is preferably 1,000, more preferably 2,000, still more preferably 3,000, and particularly preferably 5,000. The upper limit of the Mw is preferably 50,000, more preferably 30,000, still more preferably 20,000, and particularly preferably 15,000.

The Mw/Mn of the high fluorine-content polymer is usually 1 or more, and preferably 1.1 or more. The Mw/Mn is usually 5 or less, preferably 3 or less, more preferably 2.5 or less, and still more preferably 2.2 or less.

The lower limit of the content of the high fluorine-content polymer is preferably 0.5 parts by mass, more preferably 1 part by mass, and still more preferably 2 parts by mass based on 100 parts by mass of the polymer (A). The upper limit of the content is preferably 10 parts by mass, more preferably 8 parts by mass, and still more preferably 5 parts by mass. When the content of the high fluorine-content polymer is adjusted to within the above range, the high fluorine-content polymer can be more effectively localized in the surface layer of a resist film, and as a result, the elusion of a top portion of the pattern is suppressed during development and the rectangularity of the pattern can be enhanced. The radiation-sensitive composition may contain one type or two or more types of high fluorine-content polymer.

(Method for synthesizing high fluorine-content polymer) The high fluorine-content polymer can be synthesized by the same method as the method for synthesizing the base polymer described above.

### <Solvent (C)>

The radiation-sensitive composition according to the present embodiment contains a solvent (C). The solvent (C) is not particularly limited as long as it is a solvent capable of dissolving or dispersing the polymer (A), additives contained as desired, and the like.

Examples of the solvent (C) include an alcohol-based solvent, an ether-based solvent, a ketone-based solvent, an amide-based solvent, an ester-based solvent, and a hydrocarbon-based solvent.

Examples of the alcohol-based solvent include:
monoalcohol-based solvents having 1 to 18 carbon atoms, such as iso-propanol, 4-methyl-2-pentanol, 3-methoxybutanol, n-hexanol, 2-ethylhexanol, furfuryl alcohol, cyclohexanol, 3,3,5-trimethylcyclohexanol, diacetone alcohol and methyl 2-hydroxyisobutyrate;
polyhydric alcohol-based solvents having 2 to 18 carbon atoms, such as ethylene glycol, 1,2-propylene glycol, 2-methyl-2,4-pentanediol, 2,5-hexanediol, diethylene glycol, dipropylene glycol, triethylene glycol, and tripropylene glycol; and
partially etherized polyhydric alcohol-based solvents obtained by etherifying some of hydroxy groups of the polyhydric alcohol-based solvent.

In the present embodiment, alcohol acid ester-based solvents such as methyl lactate, ethyl lactate, propyl lactate, butyl lactate, methyl 2-hydroxyisobutyrate, i-propyl 2-hydroxyisobutyrate, i-butyl 2-hydroxyisobutyrate, and n-butyl 2-hydroxyisobutyrate are also included in the alcohol-based solvent.

Examples of the ether-based solvent include:
dialkyl ether-based solvents, such as diethyl ether, dipropyl ether, and dibutyl ether;
cyclic ether-based solvents, such as tetrahydrofuran and tetrahydropyran;
aromatic ring-containing ether-based solvents, such as diphenyl ether and anisole (methyl phenyl ether); and
etherized polyhydric alcohol-based solvents obtained by etherifying a hydroxy group of the polyhydric alcohol-based solvent.

Examples of the ketone-based solvent include:
chain ketone-based solvents, such as acetone, butanone, and methyl-iso-butyl ketone;
cyclic ketone-based solvents, such as cyclopentanone, cyclohexanone, and methylcyclohexanone; and 2,4-pentanedione, acetonylacetone, and acetophenone.

Examples of the amide-based solvent include:
cyclic amide-based solvents, such as N,N′-dimethylimidazolidinone and N-methylpyrrolidone; and
chain amide-based solvents, such as N-methylformamide, N,N-dimethylformamide, N,N-diethylformamide, acetamide, N-methylacetamide, N,N-dimethylacetamide, and N-methylpropionamide.

Examples of the ester-based solvent include:
monocarboxylic acid ester-based solvents, such as n-butyl acetate;
partially etherized polyhydric alcohol acetate-based solvents, such as diethylene glycol mono-n-butyl ether acetate, propylene glycol monomethyl ether acetate, and dipropylene glycol monomethyl ether acetate;
lactone-based solvents, such as Y-butyrolactone and valerolactone;
carbonate-based solvents, such as diethyl carbonate, ethylene carbonate, and propylene carbonate; and
polyvalent carboxylic acid diester-based solvents, such as propylene glycol diacetate, methoxytriglycol acetate, diethyl oxalate, ethyl acetoacetate, and diethyl phthalate.

Examples of the hydrocarbon-based solvent include:
aliphatic hydrocarbon-based solvents, such as n-hexane, cyclohexane, and methylcyclohexane; and
aromatic hydrocarbon-based solvents, such as benzene, toluene, di-iso-propylbenzene, and n-amylnaphthalene.

Among them, an ester-based solvent, a ketone-based solvent, an alcohol-based solvent, and an ether-based solvent are preferable, a partially etherized polyhydric alcohol acetate-based solvent, a cyclic ketone-based solvent, a lactone-based solvent, a alcohol acid ester-based solvent, a partially etherized polyhydric alcohol-based solvent, and a monocarboxylic acid ester-based solvent are more preferable, and propylene glycol monomethyl ether acetate, cyclohexanone, Y-butyrolactone, propylene glycol monomethyl ether, diacetone alcohol, ethyl lactate and methyl 2-hydroxy-2-methylpropionateare are still more preferable. The radiation-sensitive composition may contain one type or two or more types of solvent.

### <Other Optional Components>

The radiation-sensitive composition may contain, in addition to the components, other optional components. Examples of other optional components may include a cross-linking agent, a localization enhancing agent, a surfactant, an alicyclic backbone-containing compound, and a sensitizer. These other optional components may be used singly, or two or more thereof may be used in combination.

### <Method for Preparing Radiation-Sensitive Composition>

The radiation-sensitive composition can be prepared, for example, by mixing the polymer (A) and the solvent (C), and if necessary, the optional component at a prescribed ratio. The radiation-sensitive composition is, after the mixing, preferably filtered through, for example, a filter having a pore size of approximately 0.05 μm to 0.4 μm. The solid matter concentration of the radiation-sensitive composition is usually 0.1% by mass to 50% by mass, preferably 0.5% by mass to 30% by mass, more preferably 1% by mass to 20% by mass.

### <<Pattern Forming Method>>

A pattern forming method according to the present embodiment includes:
a step (1) of applying the radiation-sensitive composition directly or indirectly on a substrate to form a resist film (hereinafter also referred to as “resist film forming step”);
a step (2) of exposing the resist film to light (hereinafter also referred to as “exposure step”); and
a step (3) of developing the exposed resist film with a developer (hereinafter also referred to as “development step”).

According to the pattern forming method, the radiation-sensitive composition capable of forming a resist film excellent in sensitivity, CDU and development defect-suppressing properties is used, and therefore a high-quality resist pattern can be formed. Hereinbelow, each of the steps will be described.

### [Resist Film Forming Step]

In this step (the step (1)), a resist film is formed from the radiation-sensitive composition. Examples of the substrate on which the resist film is formed may include those traditionally known in the art, including a silicon wafer, silicon dioxide, and a wafer coated with aluminum. An organic or inorganic antireflective film disclosed in, for example, JP-B-6-12452 or JP-A-59-93448 may be formed on the substrate. Examples of an applicating method may include a rotary coating (spin coating), flow casting, and roll coating. After the application, prebaking (PB) may be performed to volatilize the solvent in the coating film, as necessary. The temperature of PB is usually from 60° C. to 160° C., preferably from 80° C. to 140° C. The duration of PB is usually from 5 seconds to 600 seconds, preferably from 10 seconds to 300 seconds. The thickness of the resist film formed is preferably from 10 nm to 1,000 nm, more preferably from 10 nm to 500 nm.

When the subsequent exposure step is performed with radiation having a wavelength of 50 nm or less, it is preferable to use a polymer having the structural unit (II) as the base polymer in the composition.

### [Exposure Step]

In this step (the step (2)), the resist film formed in the resist film forming step as the step (1) is exposed by irradiating with radiation through a photomask (possibly through an immersion medium such as water). Examples of the radiation to be used for the exposure may include an electromagnetic wave including visible ray, ultraviolet ray, far ultraviolet ray, extreme ultraviolet ray (EUV), X ray, and γ ray; and charged particle radiation such as an electron beam and α ray, depending on the desired line width of the pattern. Among them, far ultraviolet ray, an electron beam, or EUV is preferable. ArF excimer laser light (wavelength is 193 nm), KrF excimer laser light (wavelength is 248 nm), an electron beam, or EUV is more preferable. An electron beam having a wavelength of 50 nm or less, which is identified as the next generation exposing technology, or EUV is further preferable.

After the exposure, post exposure bake (PEB) is preferably performed to promote the dissociation of the acid-dissociable group of the polymer by an acid generated from the radiation-sensitive acid generator through exposure to light in the exposed part of the resist film. As a result of the PEB, there is generated a difference in solubility into a developer between the exposed area and the unexposed area. The temperature of PEB is usually from 50° C. to 180° C., preferably from 80° C. to 150° C. The duration of PEB is usually from 5 seconds to 600 seconds, preferably from 10 seconds to 300 seconds.

### [Development Step]

In this step (the step (3)), the resist film exposed in the exposure step as the step (2) is developed with a developer. By this step, the predetermined resist pattern can be formed. After the development, the resist pattern is generally washed with a rinse solution such as water or alcohol, and then dried.

Examples of the developer used for the development may include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, 1,5-diazabicyclo-[4.3.0]-5-nonene. Among them, an aqueous TMAH solution is preferable, and a 2.38% by mass aqueous TMAH solution is more preferable.

In the case of organic solvent development, examples of the solvent may include organic solvents such as hydrocarbon-based solvents, ether-based solvents, ester-based solvents, ketone-based solvents, and alcohol-based solvents, and solvents containing an organic solvent. Examples of the organic solvent may include one, two or more solvents listed as the solvent for the radiation-sensitive composition. Among them, ester-based solvents and ketone-based solvents are preferable. As the ester-based solvents, acetate-based solvents are preferable, and n-butyl acetate and amyl acetate are more preferable. As the ketone-based solvents, chain ketones are preferable, and 2-heptanone is more preferable. The content of the organic solvent in a developer is preferably 80% by mass or more, more preferably 90% by mass or more, still more preferably 95% by mass or more, particularly preferably 99% by mass or more. Examples of the component other than the organic solvent in the developer may include water and silicone oil.

Examples of the developing method may include a method including dipping a substrate in a tank filled with a developer for a given time (dipping method); a developing method including raising a developer on the surface of a substrate due to surface tension and leaving the raised developer for a given time (paddling method); a method including spraying a developer on the surface of a substrate (spraying method); and a method including injecting a developer on a substrate rolling at a constant rate while scanning a developer injection nozzle at a constant rate (dynamic dispensing method).

### <<Radiation-Sensitive Acid Generator>>

The radiation-sensitive acid generator according to the present embodiment contains an onium cation containing an electron withdrawing group containing no halogen atom, and a sulfonic acid anion comprising an iodine atom.

As the radiation-sensitive acid generator, the radiation-sensitive acid generator (B) above can be suitably employed.

### EXAMPLES

Hereinafter, the present invention will be specifically described with reference to Synthesis Examples, Examples, and Comparative Examples, but the present invention is not limited to the following Examples. The methods for measuring physical property values are described below.

### [Mw and Mn]

The Mw and the Mn of polymers were measured by Gel Permeation Chromatography (GPC) using GPC columns manufactured by Tosoh Corporation (“G2000HXL” x 2, “G3000HXL” x 1, “G4000HXL” x 1) under the following conditions.
Eluant: tetrahydrofuran (manufactured by Wako Pure Chemical Industries, Ltd.)
Flow rate: 1.0 mL/min
Sample concentration: 1.0% by mass
Sample injection amount: 100 μL
Column temperature: 40° C.
Detector: differential refractometer
Reference material: monodisperse polystyrene

### <Synthesis of Polymer (A)>

Base polymers (A-1) to (A-15) as the polymer (A) were synthesized according to the following method. In the synthesis of the polymer (A), compounds represented by the following formulas (M-1) to (M-16) (hereinafter, also referred to as “monomers (M-1) to (M-16)”) were used. In the following Synthesis Examples, unless otherwise specified, “parts by mass” means a value taken when the total mass of the monomers used is 100 parts by mass, and “mol %” means a value taken when the total number of moles of the monomers used is 100 mol %.

### [Synthesis Examples A-1 to A-15] Synthesis of Polymers (A-1) to (A-15)

The respective monomers were combined and subjected to a copolymerization reaction in a tetrahydrofuran (THF) solvent, followed by isolation and drying to yield base polymers (A-1) to (A-15) having the following compositions. The Mw and the dispersion degree (Mw/Mn) of the base polymers obtained were confirmed by the above-described GPC (solvent: THE, standard: polystyrene). The used amounts of the respective structural units, and the values of Mw and Mw/Mn are shown together in Table 1. For example, “M-2/M-1=25/25” in Synthesis Example A-6 means that M-2 and M-1 are contained in a molar ratio of 25:25, and the total thereof is 50 mol %. Accordingly, the composition of the base polymer (A-6) is represented as M-2/M-1/M-6=25/25/50 (molar ratio). In the table, “-” indicates that the corresponding component was not used.

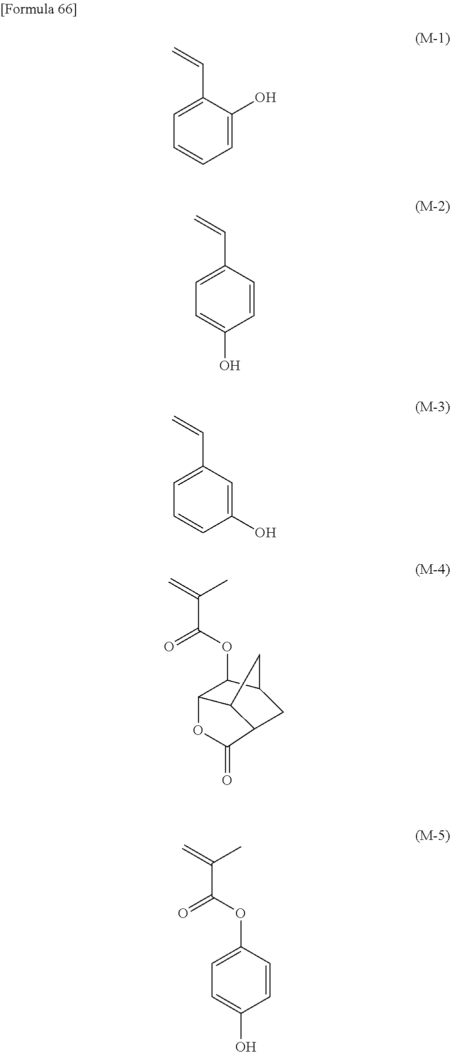

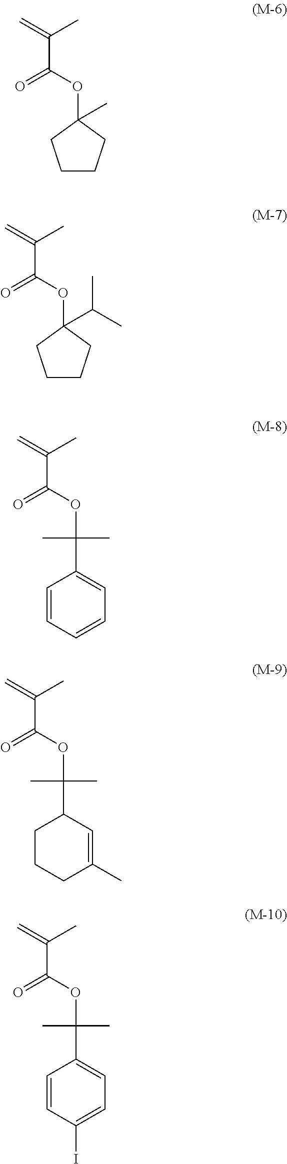

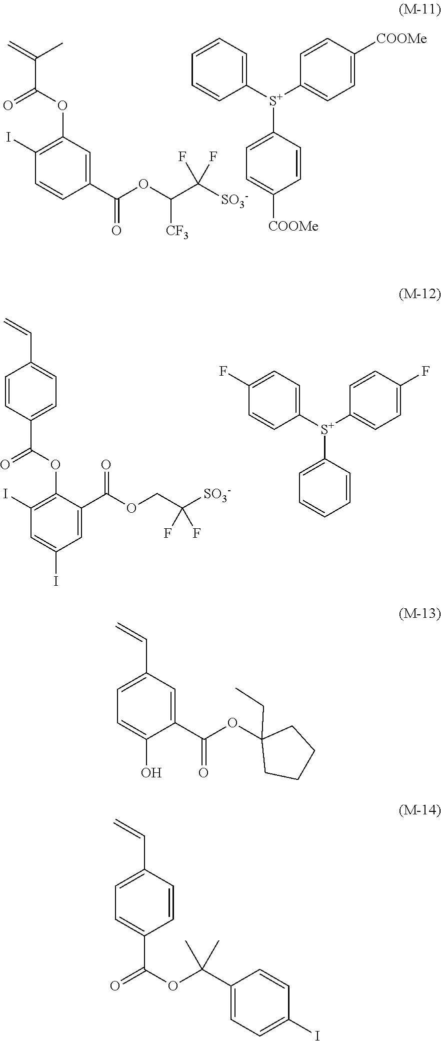

TABLE 1

| | | Structural unit (I) | | Structural unit (II) | | Structural unit (III) or (IV) | | | |
|---|---|---|---|---|---|---|---|---|---|
| | Base | | Used | | Used | | Used | | |
| | polymer | | amount | | amount | | amount | | Mw/ |
| | (A) | Type | (mol %) | Type | (mol %) | Type | (mol %) | Mw | Mn |
| Synthesis | A-1 | M-6 | 50 | M-2 | 50 | — | — | 7,100 | 1.5 |
| Example A-1 | | | | | | | | | |
| Synthesis | A-2 | M-7 | 50 | M-2 | 50 | — | — | 6,400 | 1.5 |
| Example A-2 | | | | | | | | | |
| Synthesis | A-3 | M-8 | 50 | M-2 | 50 | — | — | 5,800 | 1.5 |
| Example A-3 | | | | | | | | | |
| Synthesis | A-4 | M-9 | 50 | M-2 | 50 | — | — | 6,700 | 1.6 |
| Example A-4 | | | | | | | | | |
| Synthesis | A-5 | M-10 | 50 | M-2 | 50 | — | — | 6,400 | 1.5 |
| Example A-5 | | | | | | | | | |
| Synthesis | A-6 | M-6 | 50 | M-2/M-1 | 25/25 | — | — | 5,900 | 1.5 |
| Example A-6 | | | | | | | | | |
| Synthesis | A-7 | M-6 | 50 | M-2/M-3 | 25/25 | — | — | 5,700 | 1.5 |
| Example A-7 | | | | | | | | | |
| Synthesis | A-8 | M-6 | 50 | M-2 | 25 | M-4 | 25 | 7,400 | 1.6 |
| Example A-8 | | | | | | | | | |
| Synthesis | A-9 | M-6 | 50 | M-2/M-5 | 25/25 | — | — | 7,200 | 1.6 |
| Example A-9 | | | | | | | | | |
| Synthesis | A-10 | M-6 | 50 | M-2 | 40 | M-11 | 10 | 6,400 | 1.5 |
| Example A-10 | | | | | | | | | |
| Synthesis | A-11 | M-6 | 50 | M-2 | 40 | M-12 | 10 | 6,100 | 1.4 |
| Example A-11 | | | | | | | | | |
| Synthesis | A-12 | M-13 | 50 | M-2 | 50 | — | — | 6,600 | 1.5 |
| Example A-12 | | | | | | | | | |
| Synthesis | A-13 | M-14 | 50 | M-2 | 50 | — | — | 6,800 | 1.6 |
| Example A-13 | | | | | | | | | |
| Synthesis | A-14 | M-15 | 50 | M-2 | 50 | — | — | 6,500 | 1.5 |
| Example A-14 | | | | | | | | | |
| Synthesis | A-15 | M-16 | 50 | M-2 | 50 | — | — | 6,700 | 1.6 |
| Example A-15 | | | | | | | | | |

### [Synthesis Example B-1] Synthesis of Compound (B-1)

The compound (B-1) was synthesized according to the following reaction scheme.

In a container containing dichloromethane (30 mL) were placed a compound (PPPB-1) (16 mmol) and benzene (80 mmol), followed by ice-cooling. To this was added dropwise trifluoromethanesulfonic anhydride (18 mmol), followed by stirring at room temperature. Ice-cooling was performed, and 100 mL of ultrapure water was added dropwise. After washing with water, the mixture was concentrated to dryness and recrystallized to yield a compound (PPB-1).

QAE Sephadex (registered trademark) manufactured by Sigma-Aldrich was allowed to work on a compound (PPB-1) (10 mmol) in the presence of methanol, and the solvent was distilled off to yield a compound (PB-1).

To a container containing dichloromethane (50 mL) and ultrapure water (50 mL) were added a compound (PB-1) (10 mmol) and a compound (P-1) (10 mmol). The mixture was stirred at room temperature, then washed with water, followed by concentration and drying to yield a compound (B-1).

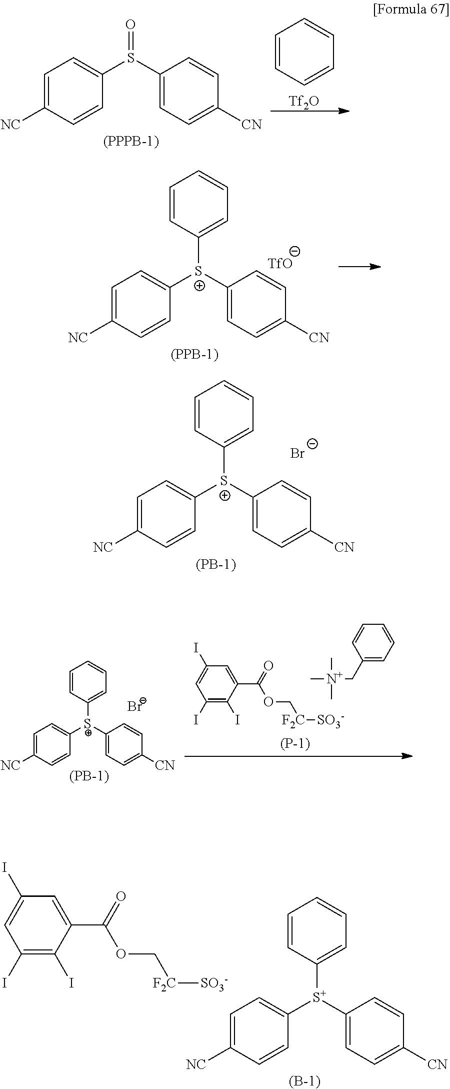

### [Synthesis Examples B-2 to B-17] Synthesis of Compounds (B-2) to (B-17)

Compounds represented by the following formulas (B-2) to (B-17) were synthesized by appropriately selecting a precursor and selecting the same formulation as that for Synthesis Example B-1.

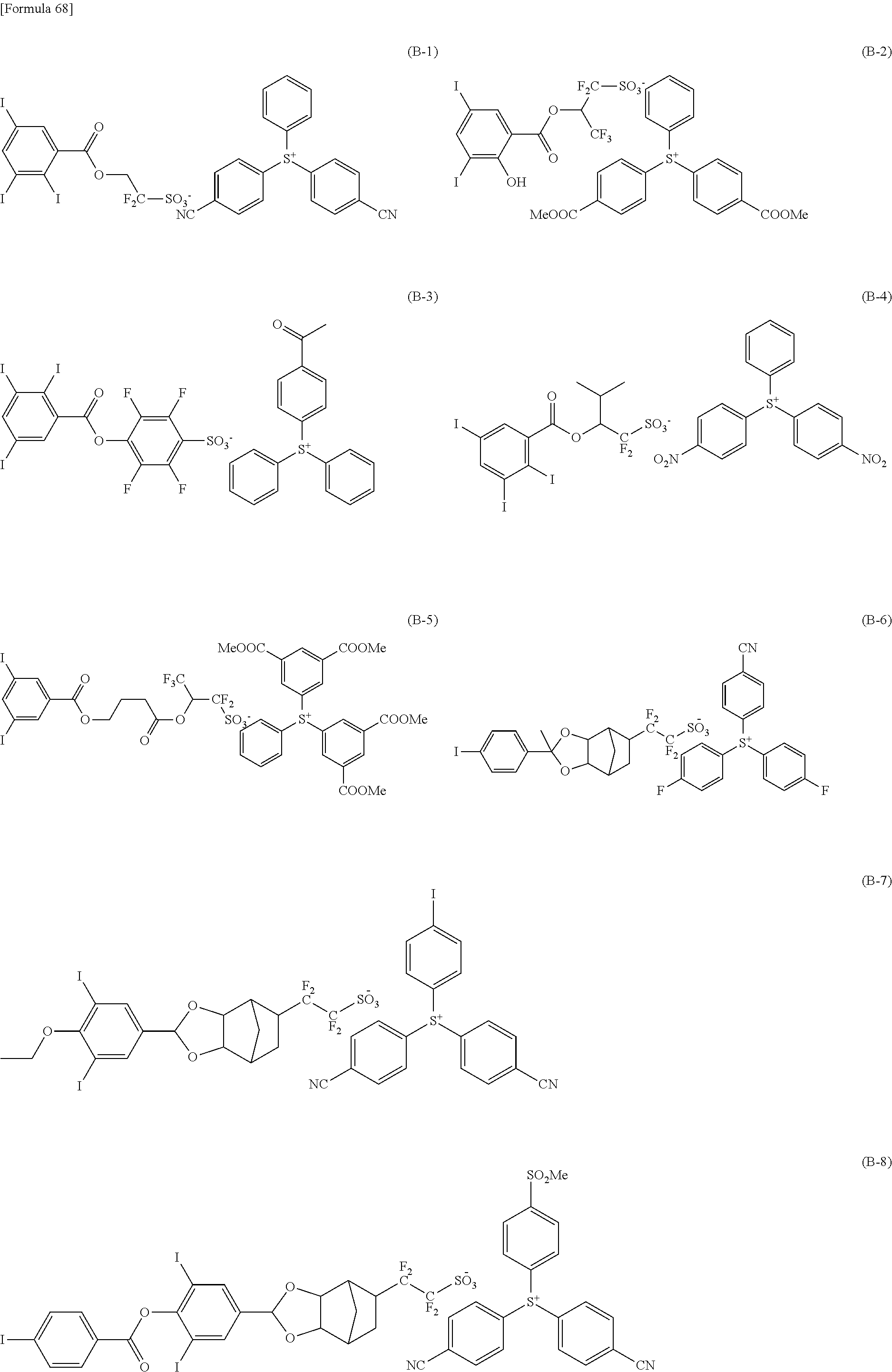

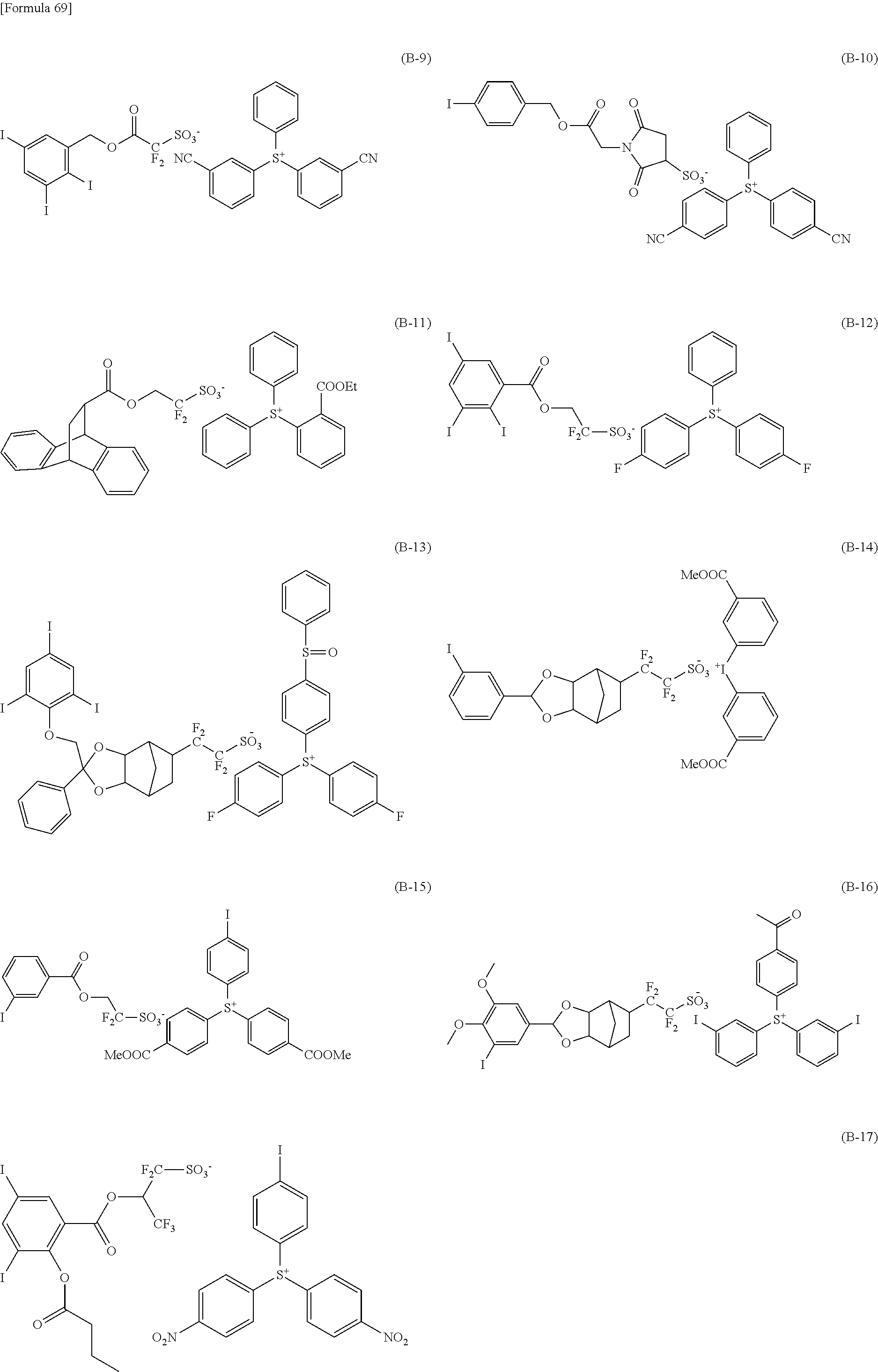

### <Preparation of Radiation-Sensitive Composition>

A polymer (A), a radiation-sensitive acid generator (B), an acid diffusion controlling agent (D), and a solvent (C) used in the preparation of the radiation-sensitive composition are shown below. In the following Examples and Comparative Examples, unless otherwise specified, “parts by mass” means a value when the mass of the polymer (A) used is 100 parts by mass, and “mol %” means a value when the number of moles of the radiation-sensitive acid generator (B) or radiation-sensitive polymers (A-10) and (A-11) used is 100 mol %.

### [Polymer (A)]

The base polymers (A-1) to (A-15) synthesized in Synthesis Examples A-1 to A-15 were used as the polymer (A).

### [Radiation-Sensitive Acid Generator (B)]

The compounds (B-1) to (B-17) synthesized in Synthesis Examples B-1 to B-17 were used as the radiation-sensitive acid generator (B).

### [Acid Diffusion Controlling Agent (D)]

Compounds represented by the following formulas (D-1) to (D-6) were used as the acid diffusion controlling agent (D).

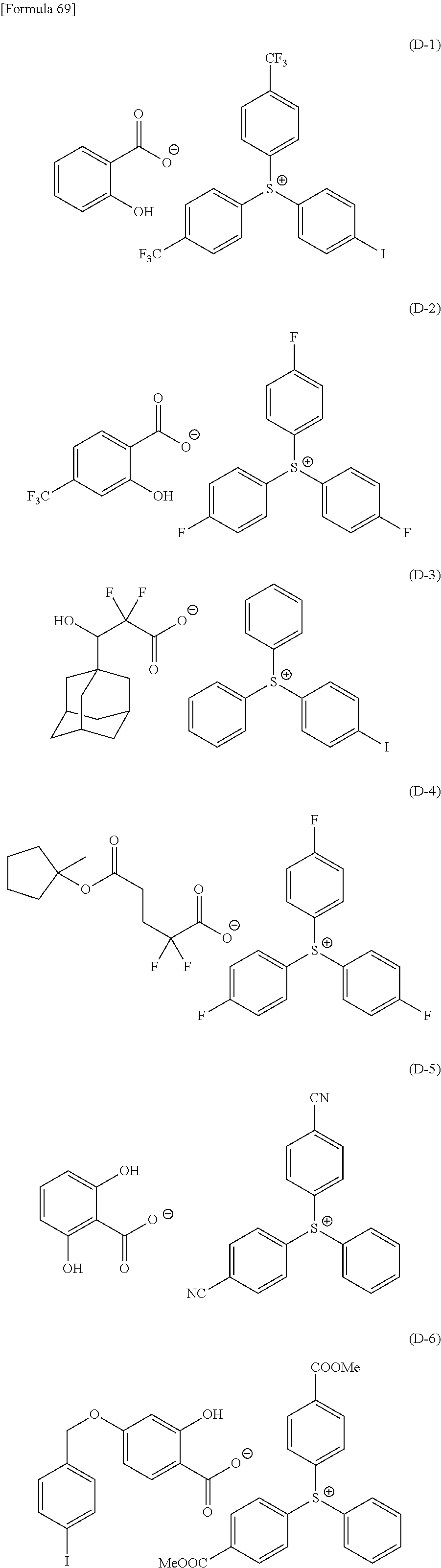

### [Solvent (C)]

As the solvent (C), the following solvents were used.
(C-1): Propylene glycol monomethyl ether acetate
(C-2): Propylene glycol monomethyl ether
(C-3): Diacetone alcohol

### [Example 1] Preparation of Radiation-Sensitive Composition (R-1)

Mixed were 100 parts by mass of (A-1) as the base polymer (A), 60 parts by mass of (B-1) as the radiation-sensitive acid generator (B), 70 mol % of (D-1) as the acid diffusion controlling agent (D) with respect to (B-1), 5,500 parts by mass of (C-1) and 1, 500 parts by mass of (C-2) as the solvent (C). The resulting mixed liquid was filtered through a filter having a pore size of 0.2 μm to prepare a radiation-sensitive composition (R-1).

### [Examples 2 to 35 and Comparative Examples 1 to 3] Preparation of Radiation-Sensitive Compositions (R-2) to (R-35) and (CR-1) to (CR-3)

Radiation-sensitive compositions (R-2) to (R-35) and (CR-1) to (CR-3) were prepared in the same manner as in Example 1 except that the respective components of the types and contents shown in the following Table 2 were used.

TABLE 2

| | | | | Radiation- | | | | | |
|---|---|---|---|---|---|---|---|---|---|
| | | | | sensitive acid | | | | | |
| | | Polymer (A) | | generator (B) | | Acid diffusion | | Solvent (C) | |
| | Radiation- | | Content | | Content | controlling agent (D) | | | Content |
| | sensitive | | (Parts | | (Parts | | Content | | (Parts |
| | composition | Type | by mass) | Type | by mass) | Type | (mol %) | Type | by mass) |
| Example 1 | R-1 | A-1 | 100 | B-1 | 60 | D-1 | 70 | C-1/C-2 | 5500/1500 |
| Example 2 | R-2 | A-2 | 100 | B-1 | 60 | D-1 | 70 | C-1/C-2 | 5500/1500 |
| Example 3 | R-3 | A-3 | 100 | B-1 | 60 | D-1 | 70 | C-1/C-2 | 5500/1500 |
| Example 4 | R-4 | A-4 | 100 | B-1 | 60 | D-1 | 70 | C-1/C-2 | 5500/1500 |
| Example 5 | R-5 | A-5 | 100 | B-1 | 60 | D-1 | 70 | C-1/C-2 | 5500/1500 |
| Example 6 | R-6 | A-6 | 100 | B-1 | 60 | D-1 | 70 | C-1/C-2 | 5500/1500 |
| Example 7 | R-7 | A-7 | 100 | B-1 | 60 | D-1 | 70 | C-1/C-2 | 5500/1500 |
| Example 8 | R-8 | A-8 | 100 | B-1 | 60 | D-1 | 70 | C-1/C-2 | 5500/1500 |
| Example 9 | R-9 | A-9 | 100 | B-1 | 60 | D-1 | 70 | C-1/C-2 | 5500/1500 |
| Example 10 | R-10 | A-10 | 100 | — | — | D-1 | 70 | C-1/C-2 | 5500/1500 |
| Example 11 | R-11 | A-1 | 100 | B-2 | 60 | D-1 | 70 | C-1/C-2 | 5500/1500 |
| Example 12 | R-12 | A-1 | 100 | B-3 | 60 | D-1 | 70 | C-1/C-2 | 5500/1500 |
| Example 13 | R-13 | A-1 | 100 | B-4 | 60 | D-1 | 70 | C-1/C-2 | 5500/1500 |
| Example 14 | R-14 | A-1 | 100 | B-5 | 60 | D-1 | 70 | C-1/C-2 | 5500/1500 |
| Example 15 | R-15 | A-1 | 100 | B-6 | 60 | D-1 | 70 | C-1/C-2 | 5500/1500 |
| Example 16 | R-16 | A-1 | 100 | B-7 | 60 | D-1 | 70 | C-1/C-2 | 5500/1500 |
| Example 17 | R-17 | A-1 | 100 | B-8 | 60 | D-1 | 70 | C-1/C-2 | 5500/1500 |
| Example 18 | R-18 | A-1 | 100 | B-9 | 60 | D-1 | 70 | C-1/C-2 | 5500/1500 |
| Example 19 | R-19 | A-1 | 100 | B-10 | 60 | D-1 | 70 | C-1/C-2 | 5500/1500 |
| Example 20 | R-20 | A-1 | 100 | B-1 | 60 | D-2 | 70 | C-1/C-2 | 5500/1500 |
| Example 21 | R-21 | A-1 | 100 | B-1 | 60 | D-3 | 70 | C-1/C-2 | 5500/1500 |
| Example 22 | R-22 | A-1 | 100 | B-1 | 60 | D-4 | 70 | C-1/C-2 | 5500/1500 |
| Example 23 | R-23 | A-1 | 100 | B-1 | 60 | D-5 | 70 | C-1/C-2 | 5500/1500 |
| Example 24 | R-24 | A-1 | 100 | B-1 | 60 | D-6 | 70 | C-1/C-2 | 5500/1500 |
| Example 25 | R-25 | A-1 | 100 | B-13 | 60 | D-6 | 70 | C-1/C-2 | 5500/1500 |
| Example 26 | R-26 | A-12 | 100 | B-1 | 60 | D-1 | 70 | C-1/C-2 | 5500/1500 |
| Example 27 | R-27 | A-13 | 100 | B-1 | 60 | D-1 | 70 | C-1/C-2 | 5500/1500 |
| Example 28 | R-28 | A-14 | 100 | B-1 | 60 | D-1 | 70 | C-1/C-2 | 5500/1500 |
| Example 29 | R-29 | A-15 | 100 | B-1 | 60 | D-1 | 70 | C-1/C-2 | 5500/1500 |
| Example 30 | R-30 | A-1 | 100 | B-14 | 60 | D-5 | 70 | C-1/C-2 | 5500/1500 |
| Example 31 | R-31 | A-1 | 100 | B-1/B-12 | 30/30 | D-1 | 70 | C-1/C-2 | 5500/1500 |
| Example 32 | R-32 | A-1 | 100 | B-15 | 60 | D-1 | 70 | C-1/C-2 | 5500/1500 |
| Example 33 | R-33 | A-1 | 100 | B-16 | 60 | D-1 | 70 | C-1/C-2 | 5500/1500 |
| Example 34 | R-34 | A-1 | 100 | B-17 | 60 | D-1 | 70 | C-1/C-2 | 5500/1500 |
| Example 35 | R-35 | A-1 | 100 | B-1 | 60 | D-1 | 70 | C-1/C-2/C-3 | 4500/1500/1000 |
| Comparative | CR-1 | A-11 | 100 | — | — | D-1 | 70 | C-1/C-2 | 5500/1500 |
| Example 1 | | | | | | | | | |
| Comparative | CR-2 | A-1 | 100 | B-11 | 60 | D-1 | 70 | C-1/C-2 | 5500/1500 |
| Example 2 | | | | | | | | | |
| Comparative | CR-3 | A-1 | 100 | B-12 | 60 | D-1 | 70 | C-1/C-2 | 5500/1500 |
| Example 3 | | | | | | | | | |

### <Evaluation>

Using the radiation-sensitive composition prepared above, the sensitivity, CDU, and the number of development defects were evaluated according to the following method. The evaluation results are shown in the following Table 3.

### [Sensitivity]

A composition for forming an antireflective film (“ARC66” manufactured by Brewer Science, Inc.) was applied onto a 12-inch silicon wafer using a spin coater (“CLEAN TRACK ACT12” manufactured by Tokyo Electron Limited), and then heated at 205° C. for 60 seconds to form an underlayer antireflective film having an average thickness of 105 nm. Each radiation-sensitive composition shown in Table 2 was applied onto the underlayer antireflection film using the spin coater, followed by performing postbaking (PB) at 130° C. for 60 seconds. Thereafter, cooling was performed at 23° C. for 30 seconds to form a resist film having an average thickness of 45 nm. This resist film was exposed to light using an EUV scanner (“NXE3300” (NA 0.33, σ 0.9/0.6, quadrupole illumination, hole pattern mask with a pitch of 50 nm on wafer and a bias of +20%) manufactured by ASML). PEB was performed on a hot plate at 100° C. for 60 seconds, and development was performed with a 2.38% by mass aqueous tetramethylammonium hydroxide (TMAH) solution for 30 seconds to form a resist pattern with a 25 nm hole and a 50 nm pitch (hereinafter also referred to as “25 nm-contact hole pattern”)). The exposure dose at which the 25 nm-contact hole pattern was formed was defined as an optimum exposure dose (Eop), and the optimum exposure dose was defined as sensitivity (mJ/cm²). The smaller the value is, the better the sensitivity is. The sensitivity was evaluated as “A” (extremely good) when the optimum exposure amount was less than 60 mJ/cm², “B” (good) when the optimum exposure amount was not less than 60 mJ/cm² and not more than 63 mJ/cm², and “C” (poor) when the optimum exposure amount was more than 63 mJ/cm².

### [CDU]

A 25 nm contact hole pattern was formed in the same manner as described above through irradiation with the optimum exposure amount determined in the section of [Sensitivity] described above. A 25 nm contact hole pattern was observed from the top of the formed resist pattern using a scanning electron microscope (“CG-5000” manufactured by Hitachi High-Tech Corporation), and a total of 800 hole diameters were measured at arbitrary points. The dimensional variation (30) was determined and taken as CDU (unit: nm). The CDU indicates that the smaller the value of the CDU is, the smaller the variation in hole diameter in the long period is and the better the performance is. The CDU was evaluated as “A” (extremely good) in the case of less than 3.3 nm, “B” (good) in the case of 3.3 nm or more and less than 3.6 nm, and “C” (poor) in the case of 3.6 nm or more.

### [Number of Development Defects]

The resist film was exposed to light at the optimum exposure amount and then developed to form a 25 nm contact hole pattern. The number of defects on the wafer was measured using a defect inspection device (“KLA2810” manufactured by KLA-Tencor Corporation). Among the defects measured, defects having a diameter of 0.5 μm or less were determined to be derived from the resist film. The number of development defects was determined as “A” (extremely good) when the number of defects determined to be derived from the resist film was less than 30, “B” (good) when the number was 30 ore more and 50 or less, and “C” (poor) when the number was more than 50.

TABLE 3

| | Radiation- | | | Development |
|---|---|---|---|---|
| | sensitive | Sensitivity | CDU | defects |
| | composition | (mJ/cm²) | (nm) | (defects) |
| Example 1 | R-1 | B | A | A |
| Example 2 | R-2 | A | A | A |
| Example 3 | R-3 | A | A | A |
| Example 4 | R-4 | A | A | A |
| Example 5 | R-5 | A | A | A |
| Example 6 | R-6 | B | A | B |
| Example 7 | R-7 | B | A | A |
| Example 8 | R-8 | B | A | A |
| Example 9 | R-9 | B | A | A |
| Example 10 | R-10 | A | A | B |
| Example 11 | R-11 | B | A | A |
| Example 12 | R-12 | B | A | A |
| Example 13 | R-13 | B | A | A |
| Example 14 | R-14 | A | A | A |
| Example 15 | R-15 | B | A | B |
| Example 16 | R-16 | B | A | B |
| Example 17 | R-17 | B | A | B |
| Example 18 | R-18 | B | A | A |
| Example 19 | R-19 | B | B | B |
| Example 20 | R-20 | B | A | A |
| Example 21 | R-21 | B | A | A |
| Example 22 | R-22 | B | A | A |
| Example 23 | R-23 | A | A | A |
| Example 24 | R-24 | A | A | A |
| Example 25 | R-25 | B | A | B |
| Example 26 | R-26 | A | B | A |
| Example 27 | R-27 | A | A | A |
| Example 28 | R-28 | A | A | A |
| Example 29 | R-29 | B | A | A |
| Example 30 | R-30 | A | A | A |
| Example 31 | R-31 | B | B | B |
| Example 32 | R-32 | A | A | A |
| Example 33 | R-33 | A | A | A |
| Example 34 | R-34 | A | A | A |
| Example 35 | R-35 | B | A | A |
| Comparative | CR-1 | B | B | C |
| Example 1 | | | | |
| Comparative | CR-2 | C | C | B |
| Example 2 | | | | |
| Comparative | CR-3 | B | C | C |
| Example 3 | | | | |

As a result of evaluating the resist pattern formed through the EUV exposure, the radiation-sensitive compositions of Examples had favorable sensitivity and CDU, and the number of development defects was small.

According to the radiation-sensitive composition and the resist pattern forming method described above, a resist pattern having good sensitivity to exposure light, excellent CDU, and few development defects can be formed. Therefore, these composition and method can suitably be used for a machining process and the like of a semiconductor device that is expected to be further miniaturized in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A radiation-sensitive composition comprising:
a polymer (A) comprising a structural unit (I) which comprises an acid-dissociable group; and
a solvent (C),
wherein the radiation-sensitive composition satisfies at least one of a following (i) or (ii):
(i) the radiation-sensitive composition comprises a radiation-sensitive acid generator (B) comprising a first organic acid anion and a first onium cation, in which the first onium cation is an onium cation comprising a halogen-free electron withdrawing group containing no halogen atom, and the first organic acid anion is a sulfonic acid anion comprising an iodine atom,
(ii) the polymer (A) is a radiation-sensitive acid-generating polymer (A1) further comprising a structural unit (IV) which comprises a second organic acid anion and a second onium cation, in which the second onium cation is an onium cation comprising a halogen-free electron withdrawing group containing no halogen atom, and the second organic acid anion is a sulfonic acid anion comprising an iodine atom.

2. The radiation-sensitive composition according to claim 1,
wherein the halogen-free electron withdrawing group is at least one electron withdrawing group selected from the group consisting of CN, COOR¹¹, NO₂, COR¹², SOR¹³, and SO₂R¹⁴, wherein R¹¹ to R¹⁴ are each independently a hydrogen atom or a monovalent hydrocarbon group having 1 to 12 carbon atoms.

3. The radiation-sensitive composition according to claim 1,
wherein the halogen-free electron withdrawing group is at least one electron withdrawing group selected from the group consisting of CN, COOR¹¹, NO₂, COR¹², SOR¹³, and SO₂R¹⁴, wherein R¹¹ to R¹³ are each independently a hydrogen atom or a monovalent hydrocarbon group having 1 to 12 carbon atoms, and R¹⁴ is a chain hydrocarbon group having 1 to 12 carbon atoms.

4. The radiation-sensitive composition according to claim 1,
wherein the halogen-free electron withdrawing group is at least one electron withdrawing group selected from the group consisting of CN, COOR¹¹, NO₂, COR¹², and SO₂R¹⁴, wherein R¹¹, R¹² and R¹⁴ are each independently an alkyl group having 1 to 6 carbon atoms.

5. The radiation-sensitive composition according to claim 1,
wherein a number of the halogen-free electron withdrawing groups in the first onium cation or the second onium cation is 1 to 5.

6. The radiation-sensitive composition according to claim 1,
wherein the first onium cation or the second onium cation is a sulfonium cation or an iodonium cation.

7. The radiation-sensitive composition according to claim 1,
further comprising an acid diffusion controlling agent (D) that comprises a third organic acid anion and a third onium cation, and generates an acid having a pKa higher than a pKa of an acid generated from the radiation-sensitive acid generator (B) or the radiation-sensitive acid-generating polymer (A1) through irradiation with radiation.

8. The radiation-sensitive composition according to claim 7,
wherein the third onium cation is an onium cation comprising the halogen-free electron withdrawing group.

9. The radiation-sensitive composition according to claim 1,
wherein the onium cation is represented by formula (1) or formula (2): 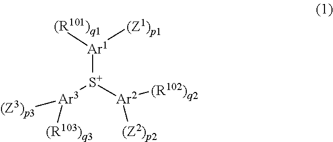
wherein in the formula (1),
Ar¹, Ar², and Ar³ are each independently a monovalent aromatic hydrocarbon group having 6 to 20 carbon atoms,
Z¹, Z², and Z³ are each independently the halogen-free electron withdrawing group, when there is a plurality of Z¹s, Z²s, and Z³s, the plurality of Z¹s, Z²s, and Z³s are each the same as or different from each other,
R¹⁰¹, R¹⁰², and R¹⁰³ are each independently a monovalent organic group other than a halogen-free electron withdrawing group, a halogen atom, a hydroxy group, or an amino group, and optionally two of R¹⁰¹, R¹⁰², and R¹⁰³ taken together represent a ring structure, when there is a plurality of R¹⁰¹s, R¹⁰²s, and R¹⁰³s, the plurality of R¹⁰¹s, R¹⁰²s, and R¹⁰³s are each the same as or different from each other,
p1, p2, and p3 are each independently an integer of 0 to 3, provided that p1+p2+p3 is 1 or more,
q1, q2, and q3 are each independently an integer of 0 to 2, and
p1+q1, p2+q2, and p3+q3 are each 5 or less, 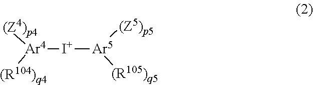
wherein in the formula (2),
Ar⁴ and Ar⁵ are each independently a monovalent aromatic hydrocarbon group having 6 to 20 carbon atoms,
Z⁴ and Z⁵ are each independently the halogen-free electron withdrawing group, when there is a plurality of Z⁴s and Z⁵s, the plurality of Z⁴s and Zos are each the same as or different from each other,
R¹⁰⁴ and R¹⁰⁵ are each independently a monovalent organic group other than a halogen-free electron withdrawing group, a halogen atom, a hydroxy group, or an amino group, when there is a plurality of R¹⁰⁴s and R¹⁰⁵s, the plurality of R¹⁰⁴s and R¹⁰⁵s are each the same as or different from each other;
p4 and p5 are each independently an integer of 0 to 3; provided that p4+p5 is 1 or more,
q4 and q5 are each independently an integer of 0 to 2, and
p4+q4 and p5+q5 are each 5 or less.

10. The radiation-sensitive composition according to claim 7,
wherein the third organic acid anion has at least one anion selected from the group consisting of a sulfonic acid anion, a carboxylate anion, and a sulfonimide anion.

11. The radiation-sensitive composition according to claim 1,
wherein the first organic acid anion or the second organic acid anion comprises an iodine-substituted aromatic ring structure.

12. The radiation-sensitive composition according to claim 1,
wherein the polymer (A) comprises a structural unit (II) having a phenolic hydroxyl group.

13. The radiation-sensitive composition according to claim 1,
wherein the polymer (A) comprises an iodine atom.

14. A pattern forming method, comprising:
directly or indirectly applying the radiation-sensitive composition according to claim 1 to a substrate to form a resist film;
exposing the resist film to light; and
developing the exposed resist film with a developer.

15. The pattern forming method according to claim 14,
wherein exposing comprises exposing the resist film to extreme ultraviolet ray or an electron beam.

16. A radiation-sensitive acid generator, comprising:
an onium cation comprising an electron withdrawing group containing no halogen atom; and
a sulfonic acid anion comprising an iodine atom.
